(19) United States
(12) Patent Application Publication
(10) Pub. No.: US 2026/0347574 A1
(43) Pub. Date: Nov. 5, 2026

(54) THERMOPLASMONICALLY-INDUCED PHASE SEPARATION MATERIAL FABRICATION AND COMPOSITIONS THEREOF

(71) Applicant: ARIZONA BOARD OF REGENTS ON BEHALF OF ARIZONA STATE UNIVERSITY, Scottsdale, AZ (US)

(72) Inventors: Soyoung Seo, Phoenix, AZ (US); Jordy Sarmas Farfan, Tempe, AZ (US)

(21) Appl. No.: 19/660,116

(22) Filed: Apr. 27, 2026

Related U.S. Application Data
(60) Provisional application No. 63/795,043, filed on Apr. 25, 2025.

(51) Int. Cl. C08K 9/04; B33Y 10/00; B33Y 70/10; G03F 7/00; G03F 7/20

(52) U.S. Cl. CPC C08K 9/04; B33Y 10/00; B33Y 70/10; G03F 7/0037; G03F 7/20; C08K 2201/011

(57) ABSTRACT

Described in the disclosure are methods of self-assembly-driven photolithography and 3D printing as well as polymeric materials using methods described herein. The polymer nanocomposite materials are photothermally generated using thermoplasmonic heating. Polymer nanocomposite materials comprising thermoplasmonic nanoparticles and thermoresponsive polymers can be synthesized by activating the resin formation by light to generate heat which induces phase separation. Phase separation in these polymers or polymeric composites combined with chain end crosslinking can trigger irreversible self-assembly of thermoresponsive polymers. Techniques described herein utilizing this photothermal self-assembly can include additive manufacturing techniques including microlithography.

This application claims priority to U.S. Provisional Application No. 63/795,043 filed on Apr. 25, 2025, the entire contents of which are incorporated herein by reference.

### GOVERNMENT SUPPORT

This invention was made with government support under DE-SC0025488 from the Department of Energy. The government has certain rights in the invention.

All patents, patent applications and publications cited herein are hereby incorporated by reference in their entirety. The disclosures of these publications in their entireties are hereby incorporated by reference into this application in order to more fully describe the state of the art as known to those skilled therein as of the date of the invention described and claimed herein.

This patent disclosure contains material that is subject to copyright protection. The copyright owner has no objection to the facsimile reproduction by anyone of the patent document or the patent disclosure as it appears in the U.S. Patent and Trademark Office patent file or records but otherwise reserves any and all copyright rights.

### FIELD OF THE INVENTION

The present disclosure encompasses a new additive manufacturing and photolithography technique and compositions produced from the same.

### BACKGROUND OF THE INVENTION

Stereolithography is a form of 3D printing that involves the polymerization of monomers or oligomers through photoinitiated chemical reactions. Although this technique is well developed, there are some operational limitations.

### SUMMARY OF THE INVENTION

Aspects of the disclosure are drawn towards a self-assembly, near-infrared (NIR) resin comprising: a plurality of thermoplasmonic nanoparticles, wherein the nanoparticles comprise at least one hydrogen-bond-forming ligand; and a polymer solution comprising at least one thermoresponsive polymer with a lower critical solution temperature (LCST) of about 20 °C to about 65 °C. In embodiments, the thermoplasmonic nanoparticle has a photothermal conversion efficiency of at least 60%. In embodiments, the thermoplasmonic nanoparticle has a localized surface plasmon resonance (LSPR) peak at about 700 nm to about 2500 nm. In embodiments, the resin further comprises a crosslinker, a thermal initiator, a co-initiator, or any combination thereof. In embodiments, the thermoresponsive polymer is present in about 8 wt./v % to about 30.0 wt./v % of the resin. In embodiments, the thermoplasmonic nanoparticle is present in a concentration of about 0.0005 wt./v % to about 0.01 wt./v %. In embodiments, the crosslinker is selected from the group consisting of poly(ethylene glycol) dimethacrylate, poly(ethylene glycol) diacrylate (PEGDA), N,N′-methylenebisacrylamide (MBAA), ethylene glycol dimethacrylate (EGDMA), di(ethylene glycol) diacrylate (DEGDA), or a combination thereof. In embodiments, the crosslinker is present in a concentration of about 8 wt./v % to about 20 wt./v %. In embodiments, the thermoresponsive polymer comprises at least one monomer residue selected from the group consisting of a poly(N-isopropyl acrylamide) (PNIPAM) residue, a butyl acrylate residue, an N,N-dimethylacrylamide residue, a poly(N-vinylcaprolactan) (PNVCL) residue, a poly(2-(diethylamine)ethyl methacrylate) (PDMAEMA) residue, a poly(vinyl methyl ether) residue, a poly(propylene glycol) (PPG) residue, a methyl acrylate residue, a poly(ethylene glycol) methyl ether acrylate (PEGMEA) residue, a gelatin monomer, a hydroxypropyl cellulose residue, or a copolymer thereof. In embodiments, the thermoresponsive polymer is selected from a poly(N-isopropyl acrylamide) (PNIPAM) homopolymer or a copolymer of a PNIPAM monomer residue and at least one comonomer residue, wherein the copolymer comprises the PNIPAM monomer residue in about 10 mol. % to about 90 mol. % of the thermoresponsive polymer. In some embodiments, the thermoresponsive polymer is poly(N-isopropylacrylamide-ran-butyl acrylate) or poly(N-isopropylacrylamide-ran-N,N-dimethylacrylamide). In embodiments, the polymer solution further comprises at least one additional thermoresponsive polymer, wherein the additional thermoresponsive polymer has an LCST greater than or less than the LCST of the first thermoresponsive polymer. In embodiments, the thermoplasmonic nanoparticle comprises a material selected from the group consisting of a metal, a metal oxide, a metal alloy, a metal oxide alloy, or a combination thereof. In embodiments, the thermoplasmonic nanoparticle has a nanostructure selected from the group consisting of a nanorod, a core-shell, a nanodisk, a nanocage, a nanostar, a nanosphere, or a triangular nanoprism. In embodiments, the thermoplasmonic nanoparticle has a size of about 5 nm to about 100 nm. In embodiments, the thermoplasmonic nanoparticle is a gold nanorod. In embodiments, the at least one hydrogen-bond-forming ligand is present in a surface density of about 1 ligand/mm2 to about 10 ligand/mm2. In embodiments, the at least one hydrogen-bond-forming ligand comprises a terminal moiety selected from the group consisting of a carboxylic acid, an amine, an amide, or an alcohol.

Aspects of the disclosure are drawn towards a near-infrared material fabrication method comprising exposing a self-assembling resin to near-infrared (NIR) irradiation for a period of time, thereby producing a cured resin. In embodiments, the self-assembling resin comprises a plurality of thermoplasmonic nanoparticles, wherein the nanoparticles comprise at least one hydrogen-bond-forming ligand; and a polymer solution comprising at least one thermoresponsive polymer with a lower critical solution temperature (LCST) of about 20 °C to about 65 °C. In embodiments, the exposure to NIR light comprises a continuous light application, a pulsed light application, or a combination thereof. In embodiments, the material fabrication method is an additive manufacturing method or a photolithography method. In embodiments, the period of time comprises about 1 second to about 45 minutes. In embodiments, the thermoresponsive polymer is present in about 8 wt./v % to about 30.0 wt./v % of the resin. In embodiments, the thermoplasmonic nanoparticle is present in a concentration of about 0.0005 wt./v % to about 0.01 wt./v %. In embodiments, the method further comprises a crosslinker, a thermal initiator, a co-initiator, or any combination thereof. In embodiments, the thermoresponsive polymer comprises at least one monomer residue selected from the group consisting of a poly(N-isopropyl acrylamide) (PNIPAM) residue, a butyl acrylate residue, an N,N-dimethylacrylamide residue, a poly(N-vinylcaprolactan) (PNVCL) residue, a poly(2-(diethylamine)ethyl methacrylate) (PDMAEMA) residue, a poly(vinyl methyl ether) residue, a poly(propylene glycol) (PPG) residue, a methyl acrylate residue, a poly(ethylene glycol) methyl ether acrylate (PEGMEA) residue, a gelatin monomer, a hydroxypropyl cellulose residue, or a copolymer thereof. In embodiments, the polymer solution further comprises at least one additional thermoresponsive polymer, wherein the additional thermoresponsive polymer has an LCST greater than or less than the LCST of the first thermoresponsive polymer.

Aspects of the disclosure are drawn towards a material produced by the methods described herein.

Other objects and advantages of this invention will become readily apparent from the ensuing description.

### BRIEF DESCRIPTION OF THE FIGURES

FIG. 1A shows non-limiting, exemplary schematics of Vat Polymerization (VP) via chemical crosslinking (conventional VP) and self-assembly (current disclosure).

FIG. 1B shows schematic illustrations of excitation of localized surface plasmon resonance (LSPR), relaxation of excited LSPR, and release of thermal energy to the surrounding medium.

FIG. 1C shows microlithography driven by self-assembly and mild crosslinking upon irradiation with NIR light. The excitation wavelength is controlled by nanoparticle shape, size, and composition, indicating that this technology is not limited to near Infrared (NIR) light.

FIG. 1D shows interfacial interaction strength between polymers and nanoparticles are tunable by altering surface ligands tethered on nanoparticle surfaces.

FIG. 2A shows a non-limiting, exemplary UV-Vis-NIR spectrum of as-synthesized gold nanorods (AuNRs) in aqueous solution. The dashed line in the spectra corresponds to the laser operational wavelength.

FIG. 2B shows a non-limiting, exemplary graph illustrating the effects of laser power with a constant AuNR loading of 0.001 wt./v %. The shaded region corresponds to the time the laser was on.

FIG. 2C shows a non-limiting, exemplary graph illustrating the effects of AuNR concentration at a fixed laser power of 300 mW on photothermal conversion. The shaded region corresponds to the time the laser was on.

FIG. 3A shows non-limiting, exemplary chemical structures of polymers, under an embodiment.

FIG. 3B shows a non-limiting, exemplary graph of the influence of PNIPAM molecular weight on cloud point (T_{cp}). Error bars indicate the standard deviation (n=3) that are smaller than the data point symbols.

FIG. 3C shows a non-limiting, exemplary graph of the influence of copolymer composition on Top. Error bars indicate the standard deviation (n=3) that are smaller than the data point symbols.

FIG. 4A shows a non-limiting, exemplary illustration scheme of interfacial interaction between poly (N-isopropylacrylamide) (PNIPAM) and surface functionalized AuNRs with the following ligands: dodecanethiol (DDT), cysteamine (C), 3-mercaptopropionic acid (MPA), and 11-mercaptoundecanoic acid (MUA).

FIG. 4B shows a non-limiting, exemplary graph showing the effect of surface ligands on T_{cp} and flocculation behavior at 70 °C, where a heating rate of 1 °C/min was employed.

FIG. 4C shows a non-limiting, exemplary graph showing the effect of surface ligands on shear storage moduli of gels synthesized with 10 wt./v % PNIPAM (126 kg/mol) and 0.002 wt./v % AuNRs.

FIG. 5A shows a non-limiting, exemplary graph demonstrating the influence of copolymer design on thermally induced self-assembly behavior with varying surface ligands, where the co-polymer contained 5 mol % butyl acrylate (BA) and 95 mol % NIPAM (119 kg/mol). The polymer concentration was 10 wt./v %, and the concentration of AuNR was 0.002 wt./v %. For the turbidity tests, a heating rate of 1 °C/min was employed.

FIG. 5B shows a non-limiting, exemplary graph demonstrating the influence of copolymer design on shear storage moduli with varying surface ligands, where the co-polymer contained 5 mol % BA and 95 mol % NIPAM (119 kg/mol). The polymer concentration was 10 wt./v %, and the concentration of AuNR was 0.002 wt./v %.

FIG. 5C shows a non-limiting, exemplary graph demonstrating the influence of copolymer design on thermally induced self-assembly behavior with varying surface ligands, where the co-polymer contained 5 mol % N, N-dimethyl acrylamide (DMA) and 95 mol % NIPAM (114 kg/mol). The polymer concentration was 10 wt./v %, and the concentration of AuNR was 0.002 wt./v %. For the turbidity tests, a heating rate of 1 °C/min was employed.

FIG. 5D shows a non-limiting, exemplary graph demonstrating the influence of copolymer design on shear storage moduli with varying surface ligands, where the co-polymer contained 5 mol % DMA and 95 mol % NIPAM (114 kg/mol). The polymer concentration was 10 wt./v %, and the concentration of AuNR was 0.002 wt./v %.

FIG. 6A shows a non-limiting exemplary graph demonstrating the effect of pH on assembly behavior and transmittance values from turbidity tests of a solution containing 5 wt./v % PNIPAM (126 kg/mol) and 0.001 wt./v % surface-functionalized AuNRs at the pH of 2 and 6-7 (as synthesized) above T_{cp} (70 °C).

FIG. 6B shows a non-limiting exemplary graph demonstrating the effect of pH on assembly behavior and UV-Vis-NIR spectra of a solution containing 5 wt./v % PNIPAM (126 kg/mol) and 0.001 wt./v % MUA-functionalized AuNRs at the pH of 2 and 7 and room temperature.

FIG. 6C shows a non-limiting exemplary graph demonstrating the effect of pH on assembly behavior and DLS results of a solution containing 1 wt./v % PNIPAM (126 kg/mol) and 0.0002 wt./v % MUA-functionalized AuNRs at the pH of 2 and 7 and room temperature. Samples for dynamic light scattering (DLS) were diluted 5× to avoid a multi-scattering effect.

FIG. 7A shows a non-limiting, exemplary self-assembly-driven microlithography of polymer nanocomposites using NIR light and reaction scheme of the crosslinking reaction.

FIG. 7B shows a non-limiting, exemplary self-assembly-driven microlithography of polymer nanocomposites using NIR light and images of Arizona Saguaro printed using PNIPAM phase separation induced by thermoplasmonic heat.

FIG. 8 shows a non-limiting, exemplary schematic of an embodiment of the present disclosure.

FIG. 9 shows a non-limiting, exemplary TEM image of the synthesized nanorods with an average size of 32 nm×8 nm. The size was estimated using ImageJ by averaging measurements from 100 nanoparticles.

FIG. 10 shows a non-limiting, exemplary NMR spectrum taken before NIPAM polymerization started (bottom) and after 1 h of exposure of UV light (top). The solvent was deuterated chloroform.

FIG. 11A shows non-limiting, exemplary graph of elution times of PNIPAM with different molecular weights. The fluid flow rate was 1 mL/min. The solvent used was DMF with 10 mM LiBr.

FIG. 11B shows non-limiting, exemplary graph of Elution times for PNIPAM homopolymer (average molecular weight=126 kg/mol) and copolymers with BA, (average molecular weight=119 kg/mol), and DMA (Mₙ molecular weight=114 kg/mol). The fluid flow rate was 1 mL/min. The solvent used was dimethylformamide (DMF) with 10 mM LiBr.

FIG. 12A shows non-limiting, exemplary images and graph of estimation of Top of PNIPAM polymers with different molecular weights using UV-Vis spectroscopy. The solutions were prepared at concentrations of 5 wt./v %. Absorbance was measured at a wavelength of 400 nm, with a heating rate of 1 °C/min.

FIG. 12B shows a non-limiting, exemplary graph of estimation of Top of PNIPAM polymers with different molecular weights using UV-Vis spectroscopy. The solutions were prepared at concentrations of 5 wt./v %. Absorbance was measured at a wavelength of 400 nm, with a heating rate of 1 °C/min. Moduli values were collected at a frequency of 1 Hz.

FIG. 12C shows a non-limiting, exemplary graph of rheological temperature ramps for PNIPAM solutions with different molecular weights at concentrations of 10 wt./v %. Moduli values were collected at a frequency of 1 Hz.

FIG. 12D shows a non-limiting, exemplary graph of temperature ramps for PNIPAM solutions of 126 kg/mol at different concentrations. The heating rate was 3 °C/min, and the geometry consisted of parallel plates with a diameter of 20 mm. Moduli values were collected at a frequency of 1 Hz.

FIG. 13 shows a non-limiting, exemplary graph of flocculation tests of a NIPAM-BA copolymer (molar ratio 95/5) at a polymer concentration of 5 wt./v %, and AuNR concentration of 0.001 wt./v %.

FIG. 14A shows a non-limiting, exemplary graph of temperature ramp rheological test of a 10 wt/v % PNIPAM solution (Mₙ=126 kDa). The storage modulus (G′) and loss modulus (G″) were measured at a constant frequency of 1 Hz and a strain of 0.1%. The temperature was increased at a heating rate of 3 °C/min. The measurements were taken at a temperature of 50 °C (gel state) and a frequency of 1 Hz.

FIG. 14B shows a non-limiting, exemplary graph of amplitude sweeps in shear rheology. The samples correspond to composite solutions of polymer PNIPAM (Mₙ=126 kg/mol) at 10 wt./v % and functionalized nanoparticles at a concentration of 0.002 wt./v %. The measurements were taken at a temperature of 50 °C (gel state) and a frequency of 1 Hz.

FIG. 15A shows a non-limiting, exemplary graph of the effect of pH on polymer solutions (PNIPAM; Mₙ=126 kg/mol) with gold nanospheres capped with MUA measured using UV-Vis-NIR spectroscopy.

FIG. 15B shows a non-limiting, exemplary graph of the effect of pH on polymer solutions (PNIPAM; Mₙ=126 kg/mol) with gold nanospheres capped with MUA measured using dynamic light scattering.

FIG. 16 shows a non-limiting, exemplary NMR spectra of the initial resin and the liquid left after chemical crosslinking. The solvent used was deuterium oxide.

FIG. 17 shows a non-limiting, exemplary FTIR spectrum of the obtained gels using PEGDMA and PNIPAM of different molecular weights.

FIG. 18 shows a non-limiting, exemplary UV-Vis-NIR spectrum of gels using PEGDMA and PNIPAM of different molecular weights.

FIG. 19 shows non-limiting, exemplary differential scanning calorimetry (DSC) thermograms of the polymer (PNIPAM; Mₙ=126 kg/mol kDa) before (uncrosslinked) and after (crosslinked) printing. The heating rate was 10 °C min⁻¹. Three heating and cooling cycles were performed; the data shown corresponds to the third cycle.

FIG. 20 shows a non-limiting, exemplary image of a printed object using NIR light, under an embodiment.

FIG. 21 shows non-limiting, exemplary still images taken at various reaction time points of a polymerization without crosslinker, under an embodiment. Mesoglobule solubilization starts immediately compromising the printing.

FIG. 22-FIG. 25 show non-limiting, exemplary still images taken at various reaction time points of polymerization systems with crosslinker, under an embodiment. Printability is not compromised by solubilization effects.

FIG. 26 shows non-limiting, exemplary images of printed objects using NIR light of systems with crosslinker.

FIG. 27A shows a non-limiting, exemplary reaction schematic for chemical reactions used for the synthesis of thermoresponsive polymers with distinct mechanical properties.

FIG. 27B shows a non-limiting, exemplary illustration of how laser power can be used to generate different temperatures, enabling sequential control over phase separation of polymers in the mixture.

FIG. 27C shows a non-limiting, exemplary illustration of how laser wavelength can be used to generate different temperatures, enabling sequential control over phase separation of polymers in the mixture.

FIG. 28A shows non-limiting, exemplary graph of dynamic mechanical analysis (DMA) used to characterize the materials, under an embodiment. DMA results indicate that the polymers exhibit distinct mechanical properties. N40M50P10 corresponds to a polymer with a molar composition of 40% NIPAM, 50% methyl acrylate (MA), and 10% poly(ethylene glycol) methyl ether acrylate (PEGMEA). N50D50 corresponds to a polymer with a molar composition of 50% NIPAM and 50% DMA.

FIG. 28B shows non-limiting, exemplary graph of UV-Vis spectroscopy used to characterize the materials, under an embodiment. UV-Vis analysis shows that phase separation occurs at different temperatures for each polymer, indicating that differential heating can be used to selectively separate them. N40M50P10 corresponds to a polymer with a molar composition of 40% NIPAM, 50% MA, and 10% PEGMEA. N50D50 corresponds to a polymer with a molar composition of 50% NIPAM and 50% DMA.

FIG. 29A shows a non-limiting, exemplary graph of UV-Vis spectroscopy of individual polymers in solution and their 50:50 wt. % mixtures. Note that this dataset was obtained at a different concentration than in FIG. 28B, which, without wishing to be bound, explains the shift in transition temperatures and differences in transition sharpness.

FIG. 29B shows a non-limiting, exemplary graph of temperature ramp rheology measurements of individual polymer solutions and their 50:50 wt. % mixtures. A clear double transition is observed, consistent with the spectroscopy results.

FIG. 29C shows a non-limiting, exemplary graph of strain sweep rheology tests confirming that the polymers exhibit different mechanical properties at different temperatures.

FIG. 29D shows a non-limiting, exemplary graph of temperature ramp rheology of 50:50 wt. % mixtures at varying total concentrations. These results indicate an operating window for observing a double transition; at concentrations above 14 wt. %, both transitions merge into a single one.

FIG. 30A shows a non-limiting, exemplary schematic illustration of polymers analyzed, under an embodiment.

FIG. 30B shows non-limiting, exemplary graph and data of FTIR spectroscopy of precipitated phases (sediment) collected at 50 °C and 70 °C, showing that they differ in composition. This compositional variation was quantified and is summarized in the table.

FIG. 31A shows a non-limiting, exemplary graph of DSC of polymers prior to their incorporation into the printing resin.

FIG. 31B shows a non-limiting, exemplary graph of DSC of polymers after printing at different temperatures. These results demonstrate that printing temperature—here controlled via laser-induced heating—directly affects material properties. Samples printed at 40 °C exhibit a single transition associated with the softer polymer, whereas samples printed at 60 °C show a clear double transition.

FIG. 32 shows non-limiting, exemplary images of a system curing without crosslinker. Images represent frames from separate time points of a video and shows the solution rapidly separating within seconds.

### DETAILED DESCRIPTION OF THE INVENTION

Detailed descriptions of one or more embodiments are provided herein. It is to be understood, however, that the present invention can be embodied in various forms. Therefore, specific details disclosed herein are not to be interpreted as limiting, but rather as a basis for the claims and as a representative basis for teaching one skilled in the art to employ the present invention in any appropriate manner.

The singular forms “a”, “an” and “the” include plural reference unless the context clearly dictates otherwise. The use of the word “a” or “an” when used in conjunction with the term “comprising” in the claims and/or the specification can refer to “one,” but it is also consistent with “one or more,” “at least one,” and “one or more than one.”

Wherever any of the phrases “for example,” “such as,” “including” and the like are used herein, the phrase “and without limitation” is understood to follow unless explicitly stated otherwise. Similarly, “an example,” “exemplary” and the like are understood to be nonlimiting.

The term “substantially” allows for deviations from the descriptor that do not negatively impact the intended purpose. Descriptive terms are understood to be modified by the term “substantially” even if the word “substantially” is not explicitly recited.

The terms “comprising” and “including” and “having” and “involving” (and similarly “comprises”, “includes,” “has,” and “involves”) and the like are used interchangeably. Specifically, each of the terms is defined consistent with the common United States patent law definition of “comprising” and is therefore interpreted to be an open term meaning “at least the following,” and is also interpreted not to exclude additional features, limitations, aspects, etc. Thus, for example, “a process involving steps a, b, and c” can refer to a process that includes at least steps a, b and c. Wherever the terms “a” or “an” are used, “one or more” is understood, unless such interpretation is nonsensical in context.

As used herein, the term “about” can refer to approximately, roughly, around, or in the region of. When the term “about” is used in conjunction with a numerical range, it modifies that range by extending the boundaries above and below the numerical values set forth. In general, the term “about” is used herein to modify a numerical value above and below the stated value by a variance of 20 percent up or down (higher or lower).

As used herein, the term “substantially the same” or “substantially” can refer to variability typical for a particular method is taken into account.

The terms “sufficient” and “effective”, as used interchangeably herein, can refer to an amount (e.g., mass, volume, dosage, concentration, and/or time period) needed to achieve one or more desired result(s).

Before explaining at least one embodiment of the disclosure in detail, the disclosure is not necessarily limited in its application to the details set forth in the following description or exemplified by the examples. The disclosure is capable of other embodiments or of being practiced or carried out in various ways. Other compositions, compounds, methods, features, and advantages of the present disclosure will be or become apparent to one having ordinary skill in the art upon examination of the following drawings, detailed description, and examples. All such additional compositions, compounds, methods, features, and advantages can be included within this description, and be within the scope of the present disclosure.

Aspects of the disclosure are drawn towards low energy light to print composites. The low energy lights can have higher penetration depth compared to high energy light such as UV. The printing combines thermally induced self-assembly and chemical crosslinking. The self-assembly is modulated at a relatively low temperature induced by light. Without wishing to be bound by theory, the technology described herein can be used, for example, in additive manufacturing for biomedical applications and materials in general.

Aspects of the technology are drawn towards a new 3D printing technique. Stereolithography is a form of 3D printing that involves the polymerization of monomers or oligomers through photoinitiated chemical reactions. However, this technique has operational limitations. To address these limitations, Thermoplasmonically Induced Phase Separation Additive Manufacturing (TIPSAM) is disclosed herein. TIPSAM is a bottom-up 3D printing technique that assembles structures through the stimulus-responsive behavior of its components. This invention uses low energy light to print composites, which has higher penetration depth compared to high energy light such as UV. The printing combines thermally induced self-assembly and chemical crosslinking. The self-assembly is modulated at a relatively low temperature induced by light thus this technology has the potential to achieve additive manufacturing for biomedical applications and materials in general.

In embodiments, the operational wavelength of light to induce phase separation or self-assembly can be tuned by selecting different thermoplasmonic materials.

Aspects of the disclosure are drawn towards a self-assembling, near-infrared (NIR) resin.

As used herein, the term “self-assembly” or “self-assembling” can refer to the spontaneous organization of molecular or supramolecular components into ordered or structured arrangements driven by non-covalent interactions.

As used herein, the term “near-infrared” can refer to electromagnetic radiation having wavelengths in the range of approximately 700 nm to 2500 nm.

As used herein the term “photopolymerizable” can refer to a material capable of undergoing polymerization or crosslinking upon exposure to electromagnetic radiation, including ultraviolet (UV), visible, or infrared light.

As used herein the term “resin” can refer to a curable composition comprising one or more monomers, oligomers, or prepolymers. In some embodiments, resins can comprise additives such as photoinitiators, crosslinking agents, fillers, stabilizers, or other functional components, which can be converted into a polymeric solid or gel-like material upon curing.

In embodiments, the self-assembling, near-infrared (NIR) resin comprises a plurality of thermoplasmonic nanoparticles comprising at least one hydrogen-bond-forming ligand and a polymer solution comprising at least one thermoresponsive polymer with a lower critical solution temperature (LCST) of about 20 °C to about 65 °C.

As used herein, the term “hydrogen-bond-forming ligand” can refer to a ligand that participates in hydrogen bonding i.e., is a hydrogen bond donor or acceptor. The selection of the hydrogen-bond-forming ligand can be guided by its ability to establish reversible, non-covalent interactions with complementary functional groups present in the polymer matrix. Suitable ligands can include moieties containing hydrogen bond donor and/or acceptor groups such as hydroxyl, amine, amide, carboxylic acid, urea, or urethane functionalities. In embodiments, hydrogen bonding between the nanoparticles and the polymers plays a synergistic role in the process where the temperature in which induces self-assembly is tunable and the final mechanical properties can be tuned by one of ordinary skill in the art by the interfacial interactions between nanoparticles and polymers.

As used herein, the term “thermoplasmonic” can refer to the generation and control of heat using plasmonic nanostructures (e.g. metal nanoparticles) when they are illuminated by light. As described herein, a material possessing the ability to exhibit thermoplasmonics, typically comprising plasmonic nanostructures, is capable of converting incident electromagnetic radiation into localized heat through plasmonic excitation, such as localized surface plasmon resonance (LSPR).

In embodiments, the operational wavelength of light to induce phase separation or self-assembly driven lithography or 3D printing can be tuned by selecting different thermoplasmonic materials.

As used herein, the term “thermoresponsive” can refer to a phenomenon exhibited by a material or system that exhibits a change in one or more physical, chemical, or structural properties in response to a change in temperature.

As used herein, the term “lower critical solution temperature” can refer to the temperature below which a material, such as a polymer or polymer-containing system, is soluble or miscible in a given solvent, and above which the material undergoes phase separation. This phase transition can be associated with a decrease in polymer-solvent interactions and can result in aggregation, precipitation, or self-assembly of the material.

For example, the LCST of PNVCL is about 25-50 °C, the LCST of hydroxypropyl cellulose is about 45 °C, the LCST of poly(vinyl methyl ether) is about 33-37 °C, the LCST of cellulose-based polymers is about 30-60 °C and is tunable depending on substitution and composition, and the LCST of PDMAEMA is 40-60 °C (depending on pH and molecular characteristics which can be determined by one of ordinary skill in the art by methods known in the art).

The compositions and methods described herein relate to dynamic systems where the substitution of the thermoresponsive polymer can influence the formulation parameters. However, the formulation parameters can be determined by one of ordinary skill in the art through methods known in the art. This approach can include: (i) identifying the LOST or phase transition behavior of the selected polymer under relevant conditions, (ii) determining the concentration range required to achieve gelation above the entanglement threshold, and (iii) evaluating polymer-nanoparticle interactions to ensure colloidal stability and desired network formation. Properties such as the lower critical solution temperature (LCST), hydrophilic-hydrophobic balance, and intermolecular interactions can impact gelation behavior, required polymer concentration, and sensitivity to environmental factors such as pH and ionic strength. For example, the critical gelation concentration is not a fixed value but depends strongly on the polymer's molecular weight and its relation to the entanglement threshold. In many thermoresponsive systems, gelation is observed in the approximate range of 5-15 wt./v % for polymers above the entanglement molecular weight, although this range may shift depending on the specific polymer and formulation conditions.

In some embodiments, the resin can contain a copolymer comprising segments with varying LCST values. This ability to incorporate segments with different LCST values allows fine control over the effective transition temperature and the breadth of the thermal response of the copolymer. In particular, the LCST can be adjusted to match the desired processing or operating conditions of the system.

This tunability is desirable because it allows the thermoresponsive behavior of the resin to be optimized for specific applications, such that the material responds within a targeted temperature window. For example, the LCST can be selected to ensure that thermal transition occurs under mild conditions compatible with biological applications.

The thermoresponsive polymer is present in the resin at a concentration of at least 8 wt./v % to about 30 wt./v % of the resin. In some embodiments, the thermoresponsive polymer is present in an amount of about 8 wt./v % to about 20 wt./v % of the resin.

In some embodiments, the thermoresponsive polymer is present in an amount of about 10 wt./v % to about 18 wt./v % of the resin.

In some embodiments, the thermoresponsive polymer is present in an amount of about 10 wt./v % to about 15 wt./v % of the resin. For example, the thermoresponsive polymer can be present in about 8 wt./v %, about 9 wt./v %, about 10 wt./v %, about 11 wt./v %, about 12 wt./v %, about 13 wt./v %, about 14 wt./v %, about 15 wt./v %, about 16 wt./v %, about 17 wt./v %, about 18 wt./v %, about 19 wt./v %, about 20 wt./v %, about 21 wt./v %, about 22 wt./v %, about 23 wt./v %, about 24 wt./v %, about 25 wt./v %, about 26 wt./v %, about 27 wt./v %, about 28 wt./v %, about 29 wt./v %, or about 30 wt./v % . . . . The lower limit is defined by the critical gelation concentration, while the upper limit is governed by the solubility limit of the polymer in the solvent system. In some exemplary embodiments, the polymer is present in about 10 wt./v %.

In embodiments, the pH range of the solution spans from neutral (approximately pH 7) to acidic conditions (approximately pH 2) to increase the protonation of the groups involved in the interactions. Higher pH can be used to induce phase separation of thermoresponsive (co) polymers at an elevated temperature. For example, the pH can be about 2, about 3, about 4, about 5, about 6, or about 7.

In embodiments, the thermoresponsive polymer has a molecular weight of about 10 kDa to about 1 MDa. In some embodiments, the thermoresponsive polymer has a molecular weight about 10 kDa to about 200 kDa. In some embodiments the thermoresponsive polymer has a molecular weight of about 20 kDa to about 100 kDa. The molecular weight of the thermoresponsive polymer described herein is above the entanglement threshold while still allowing good processing and network formation (e.g. crosslinking). For example, the thermoresponsive polymer described herein can have a molecular weight of about 10 kDa, about 15 kDa, about 20 kDa, about 25 kDa, about 30 kDa, about 40 kDa, about 50 kDa, about 60 kDa, about 75 kDa, about 90 kDa, about 100 kDa, about 105 kDa, about 110 kDa, about 115 kDa, about 120 kDa, about 125 kDa, about 130 kDa, about 135 kDa, about 140 kDa, about 145 kDa, about 150 kDa, about 155 kDa, about 160 kDa, about 165 kDa, about 175 kDa, about 180 kDa, about 185 kDa, about 190 kDa, about 195 kDa, about 200 kDa, about 210 kDa, about 220 kDa, about 230 kDa, about 240 kDa, about 250 kDa, about 260 kDa, about 270 kDa, about 280 kDa, about 290 kDa, about 300 kDa, about 310 kDa, about 320 kDa, about 330 kDa, about 340 kDa, about 350 kDa, about 360 kDa, about 370 kDa, about 380 kDa, about 390 kDa, about 400 kDa, about 410 kDa, about 420 kDa, about 430 kDa, about 440 kDa, about 450 kDa, about 460 kDa, about 470 kDa, about 480 kDa, about 490 kDa, about 500 kDa, about 510 kDa, about 520 kDa, about 530 kDa, about 540 kDa, about 550 kDa, about 560 kDa, about 570 kDa, about 580 kDa, about 590 kDa, about 600 kDa, about 610 kDa, about 620 kDa, about 630 kDa, about 640 kDa, about 650 kDa, about 660 kDa, about 670 kDa, about 680 kDa, about 690 kDa, about 700 kDa, about 710 kDa, about 720 kDa, about 730 kDa, about 740 kDa, about 750 kDa, about 760 kDa, about 770 kDa, about 780 kDa, about 790 kDa, about 800 kDa, about 810 kDa, about 820 kDa, about 830 kDa, about 840 kDa, about 850 kDa, about 860 kDa, about 870 kDa, about 880 kDa, about 890 kDa, about 900 kDa, about 910 kDa, about 920 kDa, about 930 kDa, about 940 kDa, about 950 kDa, about 960 kDa, about 970 kDa, about 980 kDa, about 990 kDa, or about 1 MDa.

In embodiments, the thermoplasmonic nanoparticle is present in a concentration of at least 0.0005 wt./v %. In some embodiments, the thermoplasmonic nanoparticle is present in a concentration of about 0.0005 wt./v % to about 0.01 wt./v %. For example, the thermoplasmonic nanoparticle can be present in a concentration of about 0.0005 wt./v %, about 0.0007 wt./v %, about 0.001 wt./v %, about 0.0015 wt./v %, about 0.002 wt./v %, about 0.0025 wt./v %, about 0.003 wt./v %, about 0.0035 wt./v %, about 0.004 wt./v %, about 0.0045 wt./v %, about 0.005 wt./v %, about 0.0055 wt./v %, about 0.006 wt./v %, about 0.0065 wt./v %, about 0.007 wt./v %, about 0.0075 wt./v %, about 0.008 wt./v %, about 0.0085 wt./v %, about 0.009 wt./v %, about 0.0095 wt./v %, or about 0.01 wt./v %. In some embodiments, the thermoplasmonic nanoparticle is present in a concentration of about 0.001 wt./v % to about 0.005 wt./v %.

In some embodiments, the thermoplasmonic nanoparticle is present in a concentration of about 0.0015 wt./v % to about 0.003 wt./v %.

In some embodiments, the thermoplasmonic nanoparticle is present in a concentration of about 0.002 wt./v % to about 0.004 wt./v %. In some embodiments, the thermoplasmonic nanoparticle concentration may be selected within the ranges described herein to provide sufficient photothermal heating to induce localized phase separation of the thermoresponsive resin.

In embodiments, the resin further comprising a crosslinker, a thermal initiator, a co-initiator, or any combination thereof. In some embodiments the crosslinker can be selected from the group consisting of poly(ethylene glycol dimethacrylate), poly(ethylene glycol) diacrylate (PEGDA), N,N′-methylenebisacrylamide (MBAA), ethylene glycol dimethacrylate (EGDMA), di(ethylene glycol) diacrylate (DEGDA), or a combination thereof, and can present in a concentration of about 10 wt. % to about 20 wt. %. For example, the crosslinker can be present in a concentration of about 10 wt. %, about 11 wt. %, about 12 wt. %, about 13 wt. %, about 14 wt. %, about 15 wt. %, about 16 wt. %, about 17 wt. %, about 18 wt. %, about 19 wt. %, or about 20 wt. %. In some embodiments, the crosslinker can be any water soluble diacrylate, diacrylamide, or dimethacrylate. For example, the crosslinker can be di(ethylene glycol) diacrylate (DEGDA), tri(ethylene glycol) diacrylate (TrEGDA), tetra(ethylene glycol) diacrylate (TEGDA), N,N′-ethylenebisacrylamide, N,N′-hexamethylenebisacrylamide, ethylene glycol dimethacrylate (EGDMA), Di (ethylene glycol) dimethacrylate (DEGDMA), or any water-soluble crosslinker that exhibits enhanced compatibility with thermally induced phase separation of the thermoresponsive polymer.

In some embodiments, the thermal initiator can be selected from the group consisting of potassium persulfate, tert-butyl hydroperoxide (TBHP), 2,2′-azobis[2-(2-imidazolin-2-yl)propane]dihydrochloride, benzoyl peroxide (BPO), ammonium persulfate (APS), 2,2′-azobis(2-amidinopropane) dihydrochloride (AAPH), 4,4′-azobis(4-cyanopentanoic acid) (ACVA), 2,2′-azobis[2-(2-imidazolin-2-yl)propane] or a combination thereof, and can be present in a concentration of about 0.01 wt. % to about 0.10 wt. %. For example, the thermal initiator can be present in a concentration of about 0.01 wt. %, about 0.012 wt. %, about 0.014 wt. %, about 0.016 wt. %, about 0.018 wt. %, about 0.02 wt. %, about 0.025 wt. %, about 0.03 wt. %, about 0.035 wt. %, about 0.04 wt. %, about 0.045 wt. %, about 0.05 wt. %, about 0.055 wt. %, about 0.06 wt. %, about 0.065 wt. %, about 0.07 wt. %, about 0.075 wt. %, about 0.08 wt. %, about 0.085 wt. %, about 0.09 wt. %, about 0.095 wt. %, or about 0.10 wt. %.

In some embodiments, the co-initiator can be selected from the group consisting of ascorbic acid, N-[(3-dimethylamino)-propyl] acrylamide (DMAPAA), N-[(3-dimethylamino)-propyl] methacrylamide (DMAPMA), sodium bisulfite, N,N,N′,N′-tetramethylethylenediamine (TEMED), or a combination thereof, and can be present in a concentration of about 0.01 wt. % to about 0.1 wt. %. For example, the co-initiator can be present in a concentration of about 0.01 wt. %, about 0.012 wt. %, about 0.014 wt. %, about 0.016 wt. %, about 0.018 wt. %, about 0.02 wt. %, about 0.025 wt. %, about 0.03 wt. %, about 0.035 wt. %, about 0.04 wt. %, about 0.045 wt. %, about 0.05 wt. %, about 0.055 wt. %, about 0.06 wt. %, about 0.065 wt. %, about 0.07 wt. %, about 0.075 wt. %, about 0.08 wt. %, about 0.085 wt. %, about 0.09 wt. %, about 0.095 wt. %, or about 0.10 wt. %. In some embodiments, the system can function without the use of a co-initiator. In some embodiments, the co-initiator can be used to reduce the activation temperature of the thermal initiator (e.g. potassium persulfate) and to facilitate radical generation under milder conditions (e.g. lower temperatures). The effectiveness and necessity of a co-initiator depend on the specific initiator system being used. For example, redox pairs (e.g. persulfate based initiators) can benefit from co-initiators to enhance initiation efficiency, whereas other thermal initiators (e.g., BPO) may not require them.

In embodiments, the thermoresponsive polymer comprises at least one monomer residue selected from the group consisting of a poly(N-isopropyl acrylamide) (PNIPAM) residue, a butyl acrylate residue, an N,N-dimethylacrylamide residue, a poly(N-vinylcaprolactan) (PNVCL) residue, a poly(2-(diethylamine)ethyl methacrylate) (PDMAEMA) residue, a poly(vinyl methyl ether) residue, a poly(propylene glycol) (PPG) residue, a methyl acrylate residue, a poly(ethylene glycol) methyl ether acrylate (PEGMEA) residue, a gelatin monomer, a hydroxypropyl cellulose residue, or a copolymer thereof.

In some embodiments, the thermoresponsive polymer is a poly(N-isopropyl acrylamide) (PNIPAM) homopolymer.

In some embodiments, the thermoresponsive polymer is a copolymer of a PNIPAM monomer residue and at least one comonomer residue, wherein the PNIPAM monomer residue is present in about 40 mol. % to about 90 mol. % of the thermoresponsive copolymer. For example, the PNIPAM monomer residue can be present in about 20 mol. %, about 25 mol. %, about 30 mol. %, about 35 mol. %, about 40 mol. %, about 45 mol. %, about 50 mol. %, about 55 mol. %, about 60 mol. %, about 65 mol. %, about 70 mol. %, about 75 mol. %, about 80 mol. %, about 85 mol. %, about 90 mol. %, about 95 mol. %, about 98 mol. %, or about 99 mol. % of the copolymer.

In some embodiments, the thermoresponsive polymer is poly(N-isopropylacrylamide-ran-butyl acrylate) or poly(N-isopropylacrylamide-ran-N,N-dimethylacrylamide).

In some embodiments, the polymer solution further comprises at least one additional thermoresponsive polymer. The additional thermoresponsive polymer can have an LCST greater than or less than the LCST of the first thermoresponsive polymer. In some embodiments, the LCSTs between the polymers will vary by at least about 3 °C. In some embodiments, the LCSTs between the polymers will vary by at least about 10 °C. For example, in some non-limiting formulations, the soft polymer will have a T_{CP} above room temperature. The difference between the T_{CP} of the soft and rigid polymers is based on how well-defined the respective transitions are and on the quality of thermal control during photothermal conversion. In some embodiments, the T_{CP} of the first thermoresponsive polymer can be greater than 10 °C of the second thermoresponsive polymer. In some embodiments, the transitions can still exhibit independence in systems where the difference in T_{CP} is smaller than 10 °C.

For example, in a non-limiting, exemplary formulation for multicomponent printing, a soft polymer and a rigid polymer can be combined. For example, the soft polymer (e.g. N40M50P10) can be composed of 40 mol. % of NIPAM, 50 mol. % of MA, and 10 mol. % PEGMEA and the rigid polymer (e.g., N50D50) can be composed of 50 mol % NIPAM and 50 mol % N,N-dimethylacrylamide. In some non-limiting, exemplary formulations the soft polymer can be composed of about 20 mol. % to about 60 mol. % of NIPAM, about 20 mol. % to about 60 mol. % MA, and about 5 mol. % to about 20 mol. % PEGMEA, such that the total mol. % equals 100 mol. %. In some non-limiting, exemplary formulations the rigid polymer can be composed of about 30 mol. % to about 60 mol. % NIPAM and about 30 mol. % to about 60 mol. % N,N-dimethylacrylamide, such that the total mol. % equals 100 mol. %. In the multicomponent resin, the rigid and soft polymers can be present at mass concentrations of 5 wt./v % for each polymer. For example, 50 mg of the soft polymer plus 50 mg of the rigid polymer in 1 ml of total solution. In some non-limiting, exemplary multicomponent resin formulations, the rigid and soft polymers can be present at mass concentration of about 1 wt./v % to about 10 wt./v % for each polymer.

In embodiments, the thermoplasmonic nanoparticle has a localized surface plasmon resonance (LSPR) peak at about 700 nm to about 2500 nm. This parameter can be determined by one of ordinary skill in the art using methods known in the art, e.g., UV-Vis-NIR spectroscopy. The LSPR corresponds to the maximum absorbance observed in the visible-NIR range.

In embodiments, the size, material and shape of the thermoplasmonic nanoparticle can be selected and tuned by one of ordinary skill in the art by methods known in the art. For example, the size, material, and shape of the thermoplasmonic nanoparticle can be selected and tuned using established synthetic methods. For example, nanoparticle size and shape can be controlled through reaction parameters such as precursor concentration, reducing agent strength, temperature, and reaction time, as well as through the use of surfactants or capping agents that direct anisotropic growth.

Seed-mediated growth methods can be used to obtain anisotropic nanostructures, such as nanorods, nanostars, or nanoplates, while spherical nanoparticles can be obtained under isotropic growth conditions. The choice of material, including gold, silver, copper, etc, can be selected based on the desired plasmonic absorption properties and target operational wavelength.

In embodiments, the nanoparticle material can be selected based upon photothermal conversion efficiency. As used herein, the term, “photothermal conversion efficiency” can refer to the ability of a material, typically a nanoparticle, to convert absorbed electromagnetic radiation into heat through non-radiative relaxation processes following optical excitation.

In embodiments, the thermoplasmonic nanoparticle has a photothermal conversion efficiency of at least 60%. In some embodiments, the thermoplasmonic nanoparticle has a photothermal conversion efficiency of about 30% to about 60%. In some embodiments, the thermoplasmonic nanoparticle has a photothermal conversion efficient of about 60% to about 90%. For example, the thermoplasmonic nanoparticle has a photothermal conversion efficiency of about 30%, about 32%, about 34%, about 36%, about 38%, about 40%, about 42%, about 44%, about 46%, about 48%, about 50%, about 52%, about 54%, about 56%, about 58%, about 60%, about 62%, about 64%, about 66%, about 68%, about 70%, about 72%, about 74%, about 76%, about 78%, about 80%, about 82%, about 84%, about 86%, about 88%, or about 90%. In some embodiments, noble metal-based nanoparticles (e.g. gold and silver nanostructures optimized for plasmonic resonance in the NIR) are used due to their moderate to high photothermal conversion efficiencies, typically ranging from about 30% to about 90% in optimized nanostructures like nanorods. Some nanoparticle geometries of the present disclosure described herein can fall in the lower portion of this range.

In embodiments, the material can be selected from the group consisting of a metal, a metal oxide, a metal alloy, a metal oxide alloy, an MXene, or a combination thereof. For example, the metal can be selected from the group consisting of gold, silver, nickel, copper, titanium, tin, zinc, or aluminum. For example, the metal oxide can be selected from the group consisting of iron oxide, indium oxide, tin oxide, zinc oxide, cesium, and tungsten. For example, the metal alloy material is selected from the group consisting of Au—Ag, Au—Cu, Au—Ag—Cu, Au—Al, Au—Sn, Ti—N, and Ni—Co. In some embodiments, the metal oxide is modified or doped to enhance optical properties. For example, the metal oxide alloy material can be selected from the group consisting of indium doped tin oxide (ITO), aluminum doped zinc oxide (AZO), or a combination thereof. In metallic systems, plasmonic behavior is intrinsic, and compositional tuning (e.g. alloying, or doping) can be used to modulate resonance properties (e.g. absorption wavelength, damping, and photothermal conversion efficiency). In conductive metal oxides, plasmonic response is not intrinsic and must be induced through modification (e.g. doping to increase free carrier concentration).

In embodiments, the nanostructure of the nanoparticle can be selected from the group consisting of a nanorod, a core-shell, a nanodisk, a nanocage, a nanostar, a nanosphere, or a triangular nanoprism. In embodiments, the nanorod or nanodisk can have an aspect ratio of about 2 to about 6. In embodiments, the nanostructures can comprise a size of about 5 nm to about 100 nm. In some exemplary embodiments, the thermoplasmonic nanoparticle is a gold nanorod.

The selection of nanoparticle structure, including nanorods, core-shell structures, nanodisks, nanostars, nanospheres, or triangular nanoprisms, is based on the ability of each geometry to tune the surface plasmon resonance (SPR) and, consequently, the photothermal response of the material. Different nanostructures exhibit distinct optical absorption profiles. For example, anisotropic structures such as nanorods, nanodisks, and nanostars can support tunable longitudinal plasmon modes that are sensitive to aspect ratio and geometry, enabling absorption to be shifted across UV, visible, and NIR regions. In contrast, more symmetric structures such as nanospheres typically exhibit fixed resonance frequencies determined primarily by size and material composition. Core-shell and nanocage structures provide additional degrees of freedom for tuning plasmonic behavior through shell thickness and core dimensions. Structural parameters can be tuned using well-established colloidal synthesis methods, including seed-med mediated growth, surfactant-directed anisotropic growth, and controlled reduction conditions. Key synthetic variables such as precursor concentration, reducing agent strength and concentration, temperature, growth time, and surfactant composition can be systematically varied to control nanoparticle shape, size, and aspect ratio, thereby achieving the desired photothermal conversion properties.

In some embodiments, the at least one hydrogen-bond-forming ligand can be present in about at a surface density of about 1 ligand/mm² to about 10 ligand/mm². For example, the ligand can be present in about 1 ligand/mm², about 2 ligand/mm², about 3 ligand/mm², about 4 ligand/mm², about 5 ligand/mm², about 6 ligand/mm², about 7 ligand/mm², about 8 ligand/mm², about 9 ligand/mm², about 10 ligand/mm², about 11 ligand/mm², about 12 ligand/mm², or about 13 ligand/mm².

In embodiments, the at least one hydrogen-bond-forming ligand comprises a terminal moiety selected from the group consisting of a carboxylic acid, an amine, an amide, or an alcohol. In some embodiments, the hydrogen-bond-forming ligand comprises a thiol. In some embodiments, the hydrogen-bond-forming ligand can be selected from the group consisting of a mercapto carboxylic acid, an amino thiol, an aromatic thiol-amine, an aliphatic thiol-amine, an aliphatic thiol-alcohol, a PEGylated thiol containing a hydroxyl end group, a PEGylated thiol containing an amino end group, and other Hydrogen-bonding moieties. Some non-limiting examples of hydrogen-bond-forming ligands can include but are not limited to 3-mercaptopropionic acid, 11-mercaptodecanoic acid, cysteamine, mercaptoethanol, 6-mercaptohexanol, 4-aminothiophenol, 1-(tert-butyl)-3-((11-mercapto-undecyl)oxy) urea, or a combination thereof.

Aspects of the disclosure are drawn towards a near-infrared material fabrication method comprising: exposing a self-assembling resin to near-infrared (NIR) irradiation for a period of time, thereby producing a cured resin. In embodiments the self-assembling resin comprises a plurality of thermoplasmonic nanoparticles and a polymer solution. In some embodiments, the nanoparticles comprise at least one hydrogen-bond-forming ligand. In some embodiments, a polymer solution comprises at least one thermoresponsive polymer with a lower critical solution temperature (LCST) of about 20 °C to about 65 °C. The LCST range can be selected to match the intended operational window of the irradiation conditions. In some embodiments, the material fabrication method is an additive manufacturing method. In some embodiments, the material fabrication method is a photolithography method.

In embodiments, the near-infrared method can be a microlithography method comprising exposing a substrate of the resin described herein to near-infrared irradiation under conditions sufficient to induce localized photothermal heating by the thermoplasmonic nanoparticles. The absorbed NIR light is converted into heat, which triggers a spatially confined physicochemical response of the thermoresponsive polymer, such as phase transition, gelation, or crosslinking, thereby enabling the formation of patterned microstructures.

In some embodiments, the NIR irradiation may be applied as continuous or pulsed light, using a uniform flood exposure or spatially patterned illumination (e.g., via photomasks or laser scanning). The wavelength may generally range from about 700 nm to about 1600 nm, with intensity and exposure time adjusted depending on the nanoparticle loading and desired feature resolution. The process may be performed under ambient or controlled temperature conditions and in aqueous or mixed solvent environments depending on LCST behavior of polymer.

In embodiments, the exposure time can be about 1 second to about 45 minutes. In some embodiments, the exposure time is about 1 second to about 45 minutes. In some embodiments, the exposure time is about 1 second to about 5 minutes. In some embodiments, the exposure time is about 5 seconds to about 2 minutes. In some embodiments, the exposure time is about 1 minute to about 30 minutes. For example, the exposure time can be about 1 second, about 2 seconds, about 3 seconds, about 5 seconds, about 10 seconds, about 15 seconds, about 20 seconds, about 30 seconds, about 45 seconds, about 1 minute, about 90 seconds, about 2 minutes, about 3 minutes, about 5 minutes, about 7 minutes, about 10 minutes, about 15 minutes, about 20 minutes, about 30 minutes, about 40 minutes, or about 45 minutes. The exposure time is sufficient to induce localized phase separation and can be tuned based on the components of the self-assembling resin system.

Aspects of the disclosure are drawn towards a polymer composite material produced by the methods described herein. For example, copolymerization allows for simultaneous tuning of both the LOST and the Tg, thereby providing access to materials with a broad range of thermomechanical properties. This dual tunability allows for the design of systems with independently thermal responsiveness and mechanical behavior, ranging from soft, highly deformable materials to more rigid and structurally robust polymer networks. Contemplated applications of these materials include advanced additive manufacturing, for example NIR-assisted or light-assisted printing. Additional applications include stimuli-responsive coatings, adaptive or reconfigurable materials, soft robotics, and photothermal actuation systems.

### EXAMPLES

Examples are provided herein to facilitate a more complete understanding of the invention. The following examples illustrate the exemplary modes of making and practicing the invention. However, the scope of the invention is not limited to specific embodiments disclosed in these Examples, which are for purposes of illustration only, since alternative methods can be utilized to obtain similar results.

### Example 1

### Thermoplasmonically Induced Phase Separation Additive Manufacturing (TIPSAM)

TIPSAM is a bottom-up 3D printing technique that allows for assembly of structures through the stimulus-responsive behavior of its components. An advantage of this technique is addressing the limitations present in conventional 3D printing methods, such as stereolithography. These limitations include the limited availability of photoinitiators that operate in certain solvents and short wavelengths, the toxicity of resin components, and the need for post-processing. This limits its application to non-biomedical areas (e.g. in situ suture using light).

Stereolithography is a form of 3D printing that involves the polymerization of monomers or oligomers through photoinitiated chemical reactions. However, this technique presents some operational limitations, among which the limited availability of photoinitiators for aqueous media at wavelengths longer than UV stands out. An alternative to this problem is the incorporation of light-responsive materials that can guide the printing process, such as thermoplasmonic nanoparticles. Gold nanoparticles can be used as nanoscale heat generators to induce phase separation in thermoresponsive polymers, for example poly(N-isopropylacrylamide) (PNIPAM). However, the use of this system in the context of 3D printing has not been reported. This is likely due to the weak interfacial interactions between the polymer and the nanoparticles that condition the phase separation. With the technique described herein, we enhance those interactions and introduce a new way of doing 3D printing, offering high tunability of the operational conditions defined by the characteristics of each component.

### The Process Comprises Two Stages:

1. Resin preparation. The components can be selected based on the operating conditions and the desired properties of the final product. The polymer can be water-soluble and reversibly gel-forming under thermal stimuli. For example, an aqueous solution of poly(N-isopropylacrylamide), PNIPAM, or its copolymers, with a high molecular weight (>100 kDa) at concentrations above the entanglement (>10 wt./v %) can be used. The selection of thermoplasmonic materials will determine the operational wavelength of the system. The use of gold nanorods with an aspect ratio of 4 (at concentrations around 0.002 wt./v %) functionalized with 11-mercaptoundecanoic acid, for example, can be used due to their high photothermal conversion efficiency in the near-infrared (808 nm) and their ability to form hydrogen bonds with the polymer, which is crucial for the phase separation and flocculation of polymer nanocomposites. This is an exciting, surprising aspect of the disclosure. Additionally, potassium persulfate and ascorbic acid can be added as a thermal initiator and co-initiator pair for a crosslinking reaction between PNIPAM and polyethylene glycol dimethacrylate, which prevents the resolubilization of the structure once formed.
2. Phase separation and chemical crosslinking. If the described resin described in step 1 is selected, the light irradiance can be greater than 1 W/cm² to achieve temperatures above 50 °C, for the phase transition of PNIPAM and the subsequent crosslinking reaction. While phase separation occurs immediately after the light is activated, as indicated by the turbidity in the area irradiated by the light, the light irradiation can be prolonged to extend the chemical reaction. For example, in some embodiments, the light irradiation can be prolonged to ensure the chemical reaction occurs to the desired extent as determined by one of ordinary skill in the art using methods known in the art. For example, in some embodiments, the light irradiation can be prolonged for at least about 15 minutes.

Although there are bottom-up 3D printing techniques, this technique is new and provides advantages over existing techniques. For example, the way nanoscale structures are assembled is an advantage over existing techniques. In this system, not only is the heat from the thermoplasmonic materials used to induce phase transitions in the surrounding polymers, but hydrogen bonding between the nanoparticles and the polymers also plays a synergistic role in the process where the temperature in which induces self-assembly is tunable and the final mechanical properties are also impacted by the interfacial interactions between nanoparticles and polymers. Printing composites using light is also another new, exciting aspect of this disclosure.

### Non-Limiting, Exemplary Advantages of the Disclosure

This technique offers advantages over other conventional 3D printing techniques such as stereolithography. For example, the operational wavelength of light can be tuned by selecting different thermoplasmonic materials, which eliminates the limited availability of photoinitiators at wavelengths longer than UV. The wavelength can be tuned by one of ordinary skill in the art by methods known in the art. Also, light absorption in the near-infrared range allows for printing with high light penetration. This aspect can be especially useful in living tissue applications. In addition, since the resin is composed of preformed polymers, the toxicity associated with photo-activated monomers is eliminated. Finally, the material obtained after phase separation is a polymer composite that requires no further post-processing other than water removal.

### Non-Limiting, Exemplary Applications

The techniques and compositions described herein can be used, for example, in-situ printing for biomedical applications (cell-friendly, in-body printing), composite 3D printing with light, multi-material 3D printing where different wavelengths are used to selectively cure different materials, and 3D printing with lower energy consumption.

### Example 2

### Thermoplasmonic Driven Assembly for Additive Manufacturing

Stimuli responsive polymers are materials that in response to external stimuli such as light, temperature, magnetism, pH changes, etc., can experience changes in its shape, size, conformation and other properties. This nature seen behavior of responding to the surroundings makes this class of materials useful for the elaboration of sensors, actuators and other biomimetic applications.

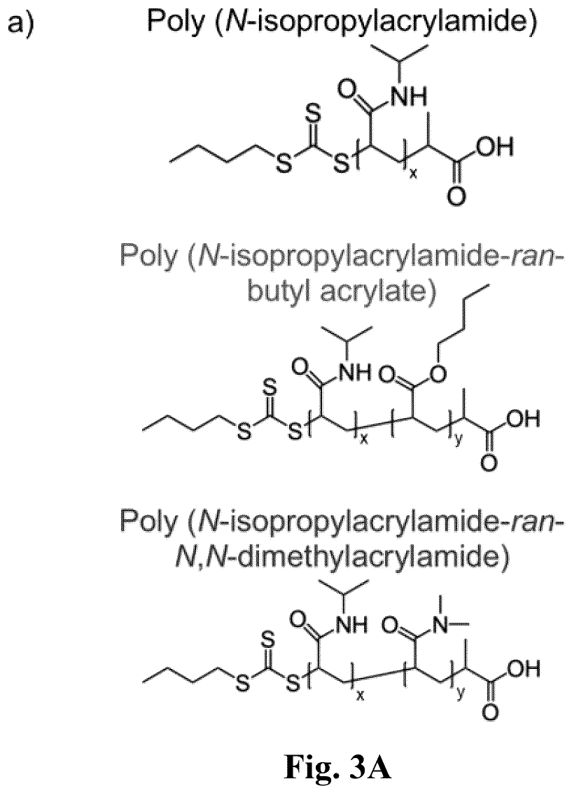

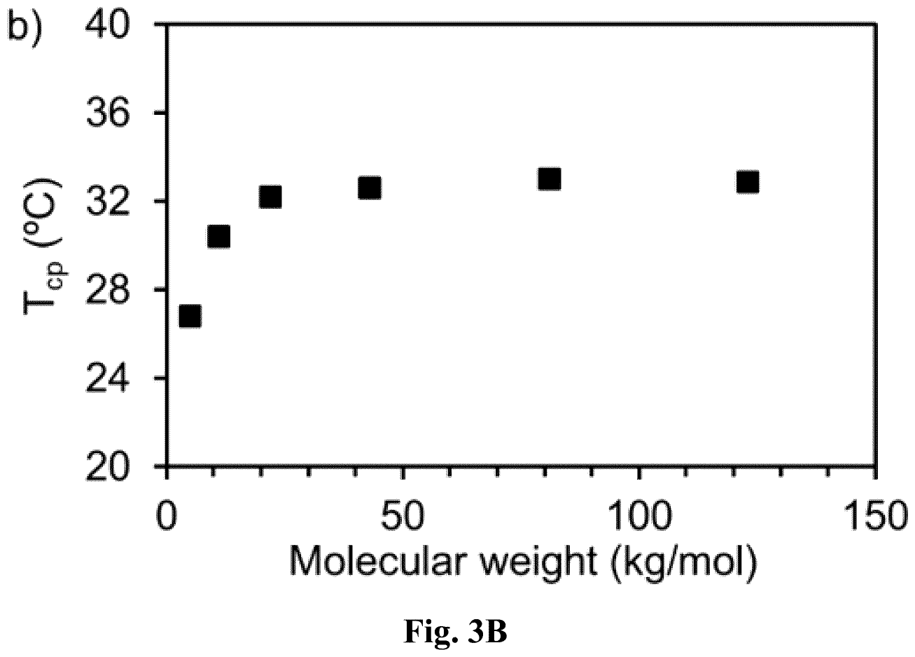

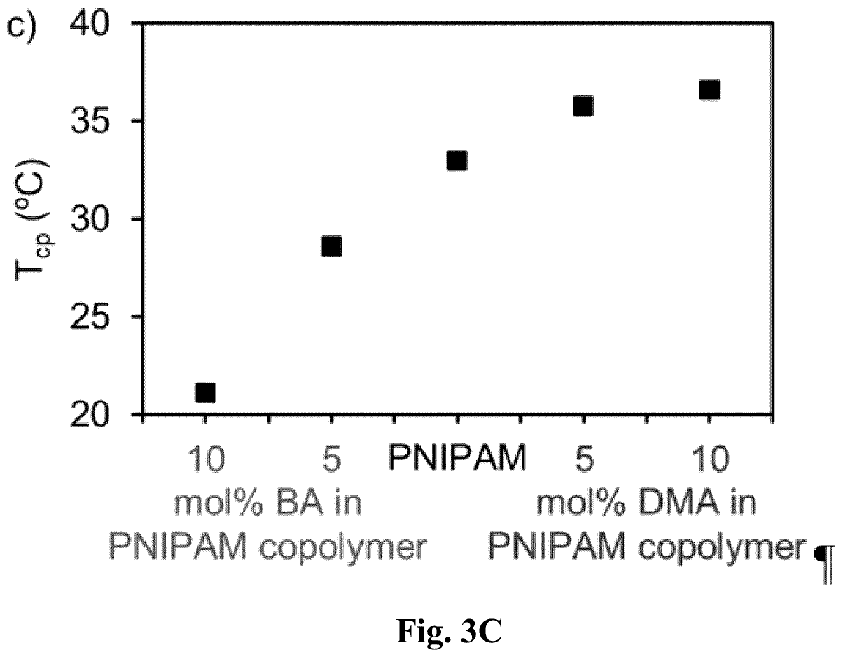

In some embodiments, phase transitions can be controlled by means of polymer architecture. FIG. 3B shows that the cloud point can be influenced by the molecular weight of the polymer used in the stimuli-responsive composition, under an embodiment. FIG. 3C shows the cloud point can be influenced by the co-polymer composition, under an embodiment. FIG. 3A shows exemplary chemical structures of polymers and co-polymers used under an embodiment.

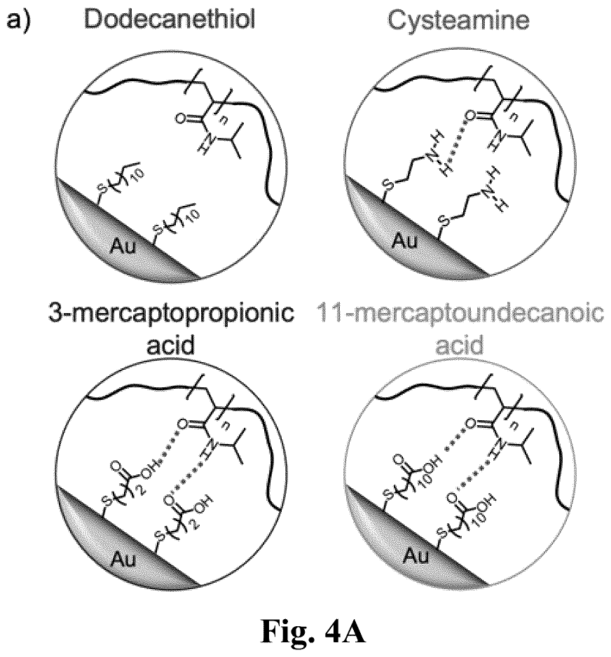

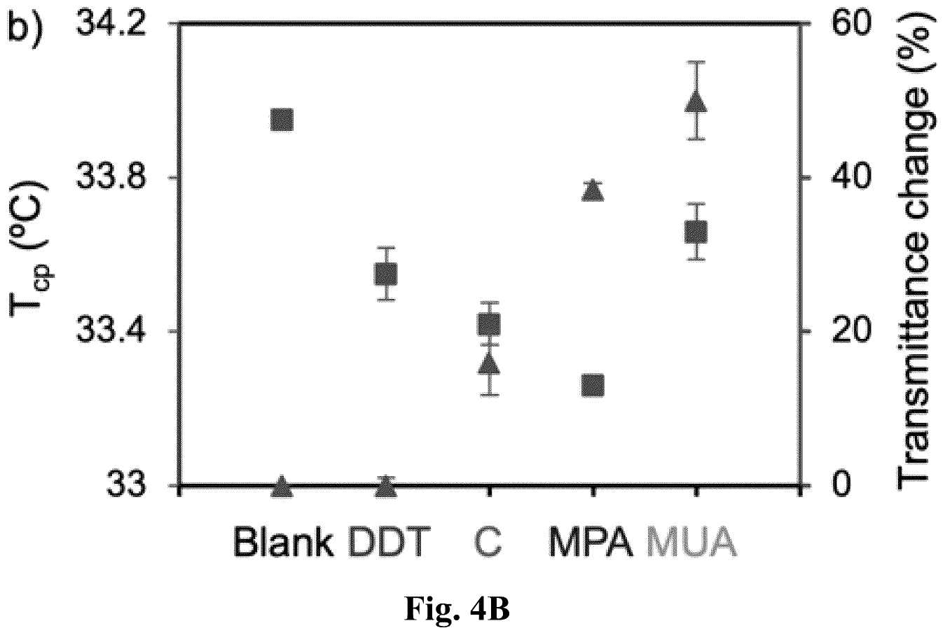

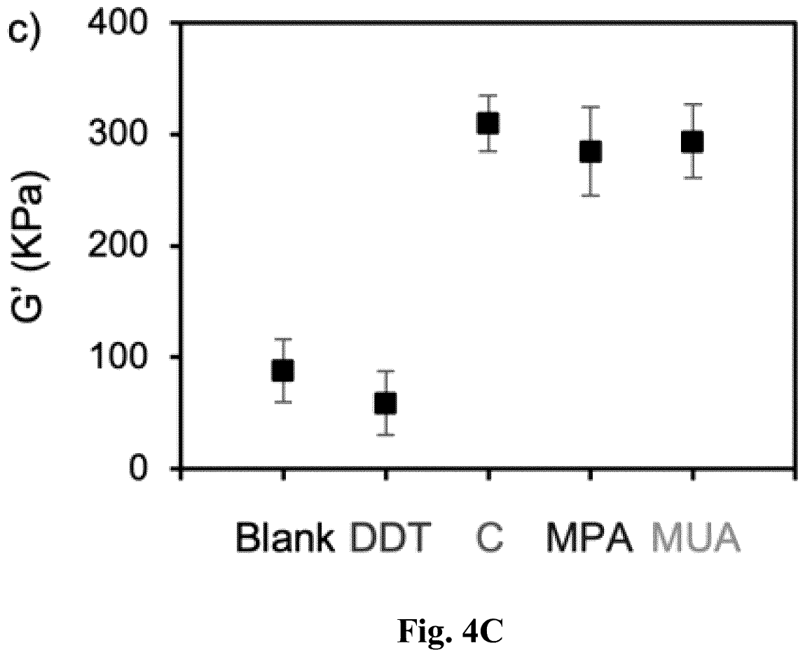

In some embodiments, polymer/nanoparticle interface interactions can influence system properties. FIG. 4A shows the interface interactions between an exemplary polymer and an exemplary nanoparticle with various surface modifying ligands, under an embodiment. FIGS. 4C and 4B show influence of surface modification on storage moduli and flocculation, respectively.

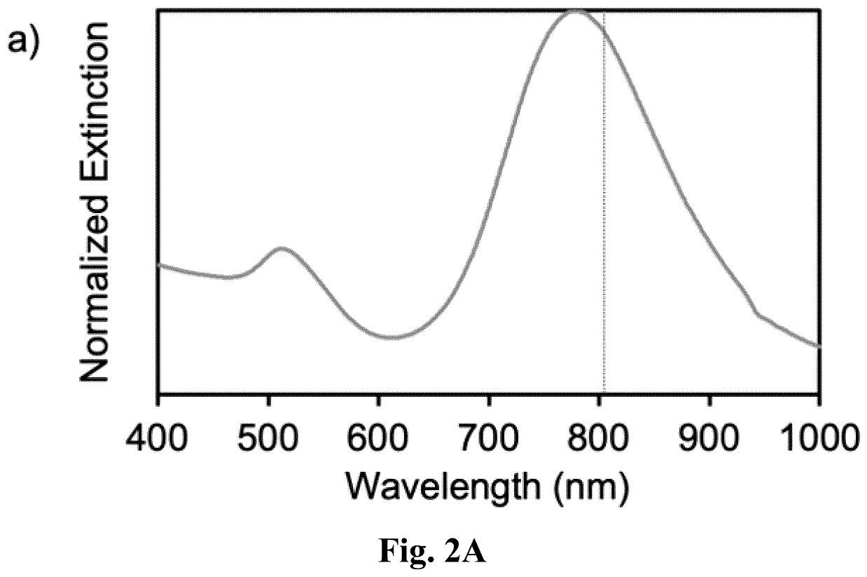

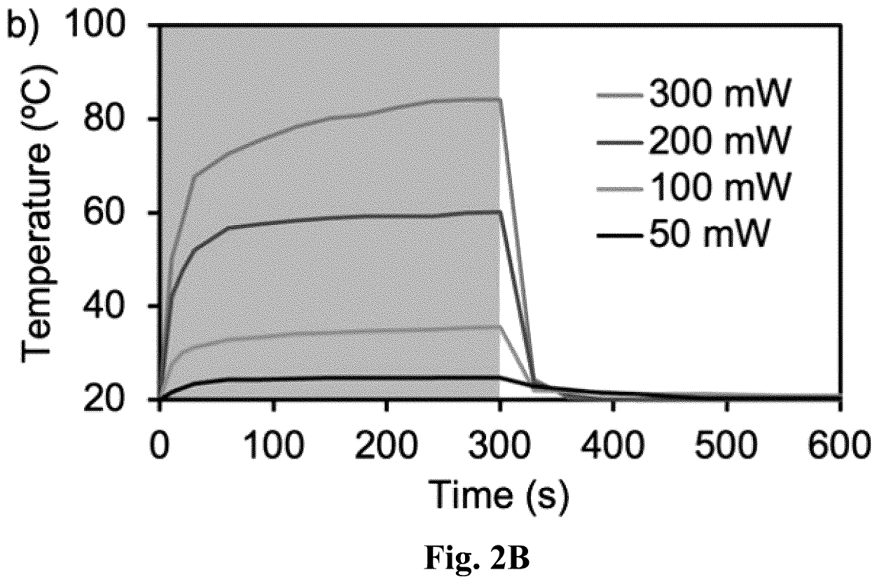

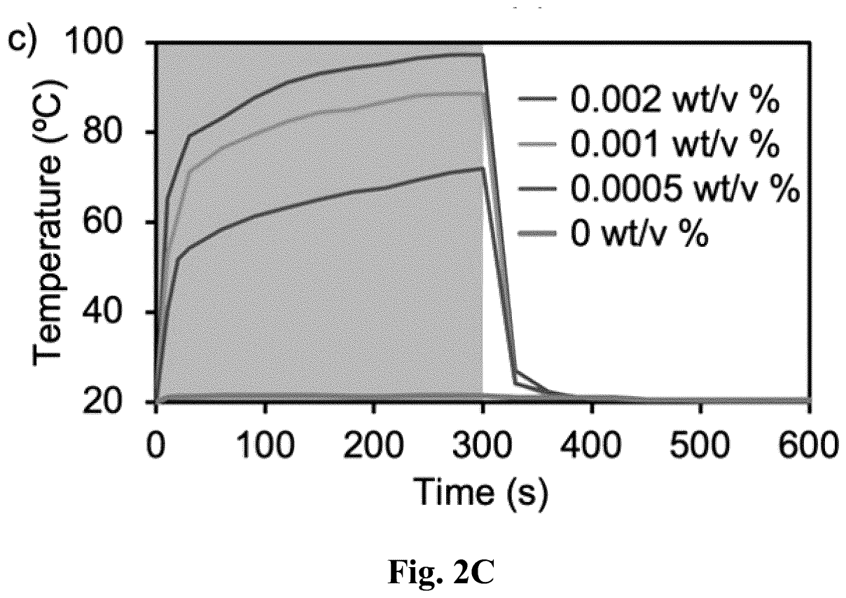

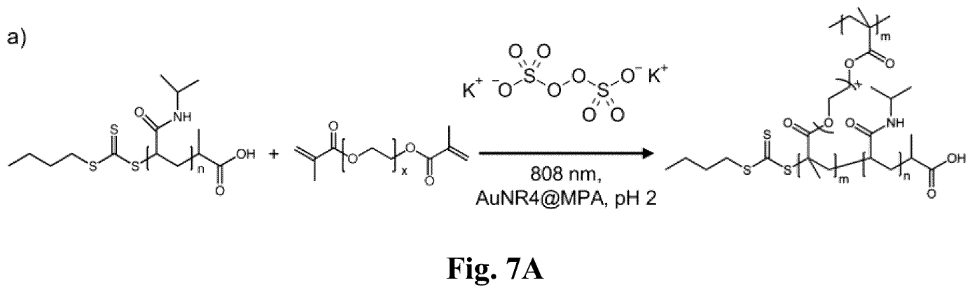

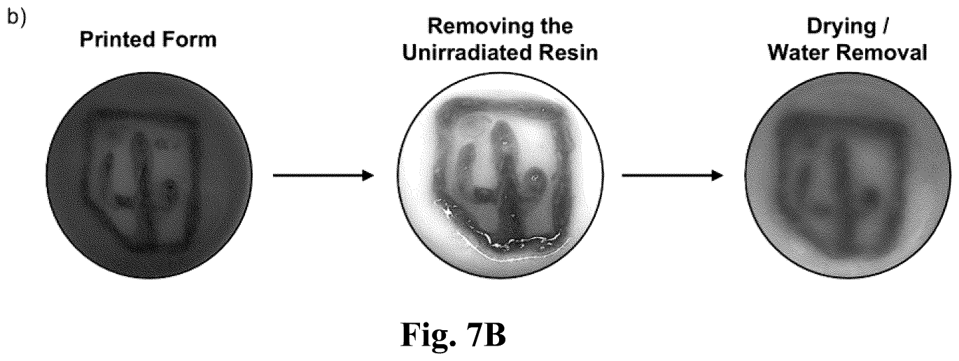

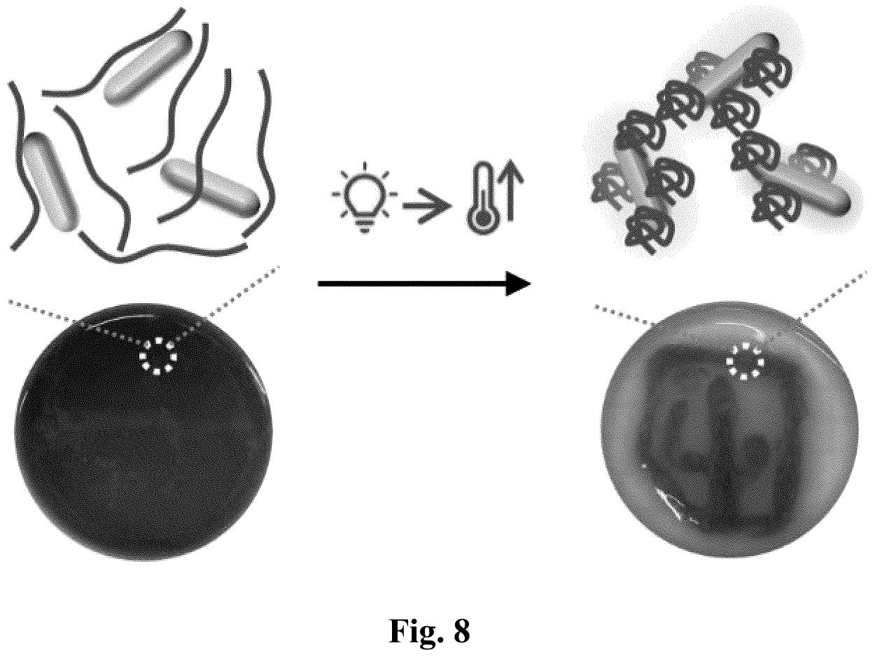

In embodiments, the polymer nanocomposites of the present disclosure can be used in additive manufacturing using NIR. FIG. 7A shows an exemplary reaction scheme of the polymerization with a nanoparticle and a crosslinker, under an embodiment. FIG. 2A shows the localized surface plasmon resonance, and the transverse surface plasmon resonance of a nanoparticle, under an embodiment. FIG. 2C shows the effects of Gold Nanorod (AuNR) concentration at a fixed laser power on photothermal conversion, under an embodiment. FIG. 2B shows an image of laser power of an exemplary system, under an embodiment.

### REFERENCE CITED HEREIN

Sarmas-Farfan, J. Yu, J. Gonzalez-Calvo, T. Self, J. Seo, S. ACS Appl. Polym. Mater. 2026, 8, 4822-4832.
1. Nat. Commun. 2024, 15:3925.
2. J. Phys. Chem. C 2016, 120, 1 7745-17752.

### Example 3

### Self-Assembly Driven Microlithography Via NIR Light Activation

Current vat photopolymerization (VP) relies on UV or visible light to initiate the rapid crosslinking of liquid photocurable resins into 3D-printed structures. Here, we develop a self-assembly-driven photopatterning approach to photothermally generate polymeric solids by combining thermoplasmonic nanoparticles and thermoresponsive polymers, in which near-infrared (NIR) light activates thermoplasmonic heating of nanoparticles, triggering the irreversible self-assembly of thermoresponsive polymers into insoluble mesoglobules. A small amount of thermal initiator and crosslinker leads to irreversible self-assembly of polymer nanocomposites. NIR light offers deeper penetration and reduced scattering compared to UV, enabling more uniform curing of thicker or filled materials and expanded process control for composites or opaque systems. Thermoplasmonic heat generation is achieved using surface-modified gold nanorods (AuNRs) with a longitudinal localized surface plasmon resonance peak in the NIR region. Key variables such as polymer composition, molecular weight, physical interactions at the nanoparticle-polymer interface, which can be tuned by surface functionalization, AuNR concentration, and pH can be used to tailor the assembly behavior of these systems, including photothermal effect, flocculation, and cloud point temperature, and the mechanical properties of the final structures. Collectively, these results highlight a platform for photothermally-driven microlithography of polymer solids with diverse, tunable macroscopic properties, enabled by low-energy NIR light-activated self-assembly.

### INTRODUCTION

Three-dimensional polymeric solids can be fabricated with high spatial resolution, smooth surface finishes, and fast curing using light-directed approaches such as vat photopolymerization (VP).¹ For example, VP transforms a photoreactive liquid resin into a precisely defined solid structure at the microscale through patterned light irradiation. During the VP process, UV or visible light initiates polymerization of the photocurable resin, and subsequent chemical crosslinking converts the liquid resin into a solid, forming a highly crosslinked thermoset polymer network. Conventional VP techniques are limited by their reliance on cytotoxic monomers and photoinitiators, the use of high-energy UV-visible light with relatively low penetration depth, the need for post-curing to achieve target mechanical properties, and poor compatibility with fillers or bioactive components.²⁻⁵ Photopolymerization under near-infrared (NIR) light is safer than UV light and allows for deeper light penetration, resulting in more complete curing of thicker materials, even with the addition of fillers. However, it is challenging to use in 3D printing due to the low energy of absorbed photons.² Additionally, highly crosslinked thermosets produced by VP are challenging to reprocess or recycle, raising concerns about their long-term sustainability. A milder fabrication approach that preserves the spatial precision of VP while expanding material diversity and sustainability would be ideal.

Thermally responsive polymers such as poly(N-isopropylacrylamide) (PNIPAM) and poly(vinyl methyl ether) are attractive candidates for light-directed fabrication and patterning because they offer rapid assembly kinetics above their lower critical solution temperature (LCST), avoid the use of reactive radicals and cationic species for crosslinking, and provide broadly tunable processing conditions that can be tailored to photopatterning approaches. Above the LCST, polymer-solvent interactions are disrupted and polymer-polymer associations are favored, leading to a sol-gel transition from a miscible liquid state to a phase-separated solid state.⁶ Thermally responsive polymers can be leveraged in a wide range of smart and adaptive materials, including controlled drug delivery, sensors, soft actuators, and 3D-printed structures.⁷-10 This phase transition of PNIPAM microgels has been used for extrusion-based 3D printing of polymeric structures and composites, leveraging temperature and salting-out effects as stimuli to induce phase transformation.^{11,12} This leveraging of temperature and salting-out effects as stimuli to induce phase transformation is a uniform bulk approach and does not allow for localized tailored control of these phase transitions. In contrast, this disclosure utilizes localized tunable control of thermal equilibration via the incorporation of NIR-induced photothermal heating via embedded thermoplasmonic nanoparticles. This allows for spatially and temporally controlled activation. This, combined with tunable LCST behavior and interfacial polymer-nanoparticle interactions, allows self-assembly and curing that is advantageous not accomplished in uniform bulk approaches. Instead of chemical crosslinking through the generation of reactive radicals or cationic species, liquid resin can be transformed into an insoluble solid by inducing phase separation via thermally driven physical changes in polymer properties. Despite these advantages, one of the requirements for exploiting the rapid self-assembly kinetics of thermally responsive polymers in light-directed fabrication technologies is photoactivation.

Light energy (i.e., photons) can be converted into thermal energy (i.e., heat) via optical heating of plasmonic nanoparticles, enabling broader wavelength tunability across the UV-visible-IR range. Incident light produces collective oscillations of conduction electrons (surface plasmons), and their non-radiative damping through electron-phonon and phonon-phonon interactions result in sharp, nanoscale temperature rises around the particle. More importantly, the light wavelength to activate the thermoplasmonic effect is tunable through several parameters, including nanoparticle shape (i.e., gold nanorod (AuNR), λ=520, 800 nm; gold sphere, λ=520 nm; gold triangular nanoprism, λ=500-800 nm), composition (i.e., silver sphere, λ=350-450 nm; quantum dot, UV to IR), spatial orientation, and the presence of surface coatings.¹³⁻¹⁷ Because the heating is induced by light, the photothermal effect is highly localized and underpins laser heating, photothermal therapy, and optothermal actuation of soft materials.¹⁸⁻²² For example, heating at a patterned photothermal (macroscopic) plate can be used for 3D printing via thermally initiated photopolymerization.²³ Magdassi and coworkers reported NIR-induced 3D printing using thermoplasmonic heating to thermally initiate free-radical polymerization within a vat-based system.²⁴ While effective for rapid curing, vat photopolymerization based on chemical crosslinking typically operates near the gel point at relatively low monomer conversion and thus requires post-curing steps to achieve target mechanical performance.²⁵ Therefore, analogous vat-based strategies that enable the printing of preformed polymers with high molecular weights through alternative solidification mechanisms are desirable. Lear and Fortenbaugh reported photothermal curing (i.e., chemical crosslinking) of silicone resin with gold nanoparticles under 532 nm laser light.²⁶ Alternatively and surprisingly, this disclosure describes localized NIR-induced photothermal heating in combination with thermoresponsive and interfacially engineered polymer systems to produce physical, LCST-driven phase transitions and structural reorganization allows for solidification of high molecular weight polymer systems that do not rely on chemical crosslinking mechanisms and that do not require post-curing.

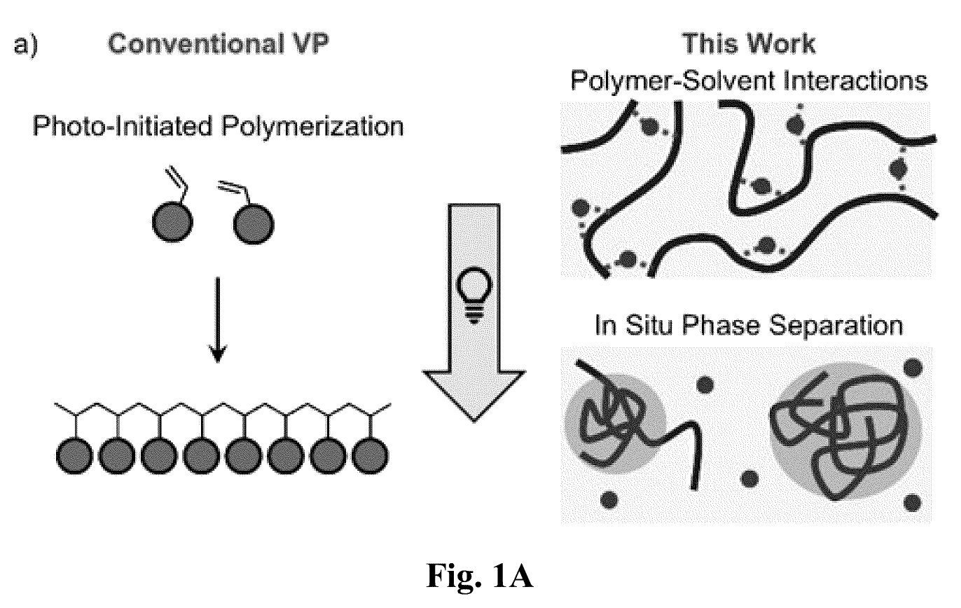

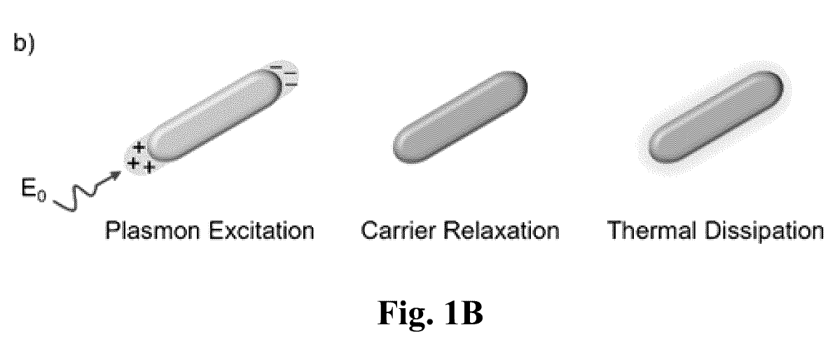

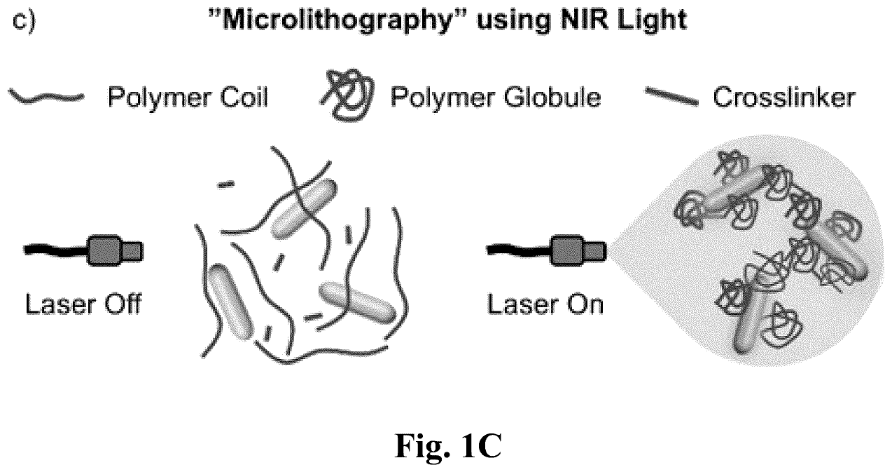

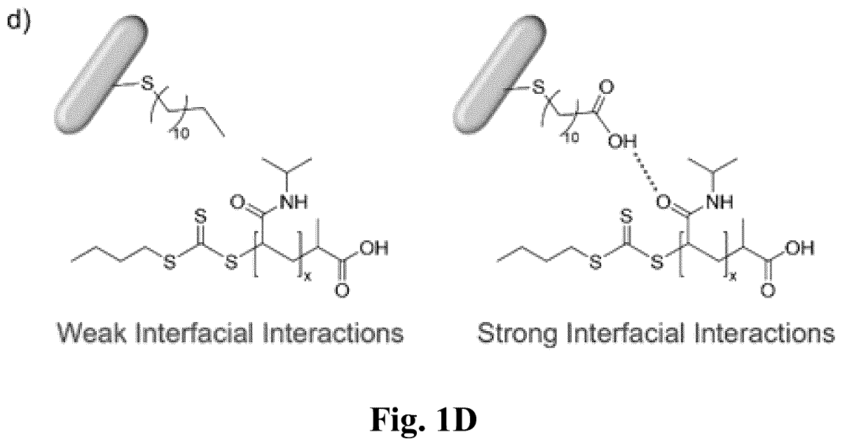

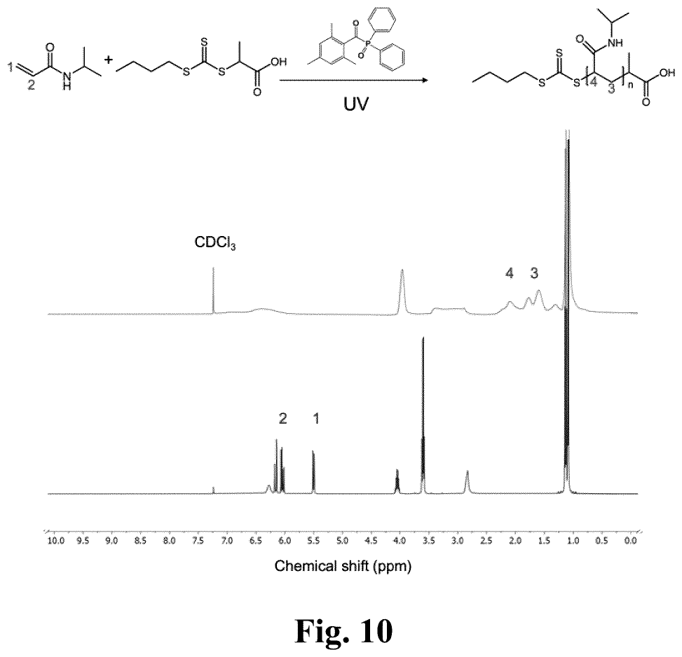

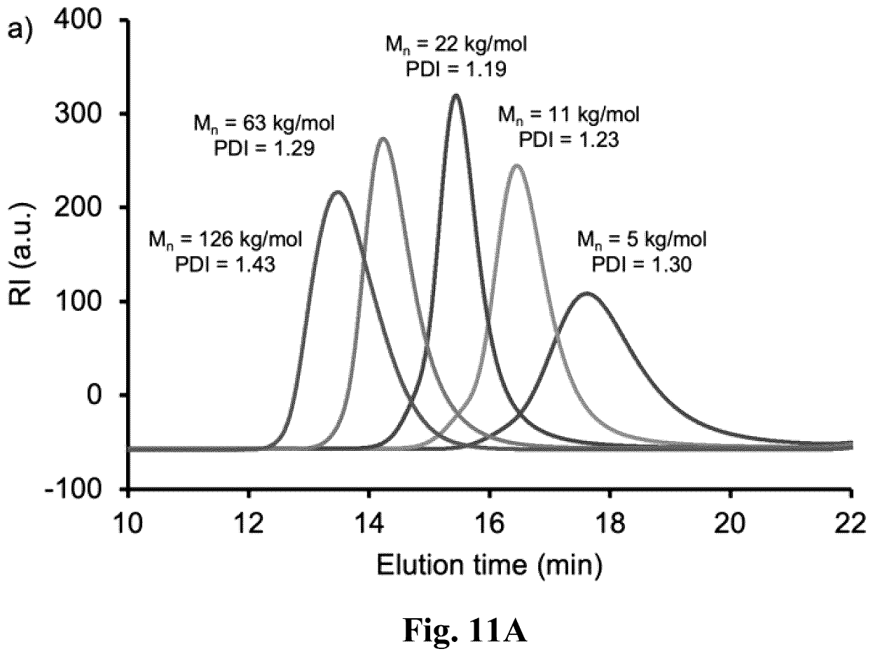

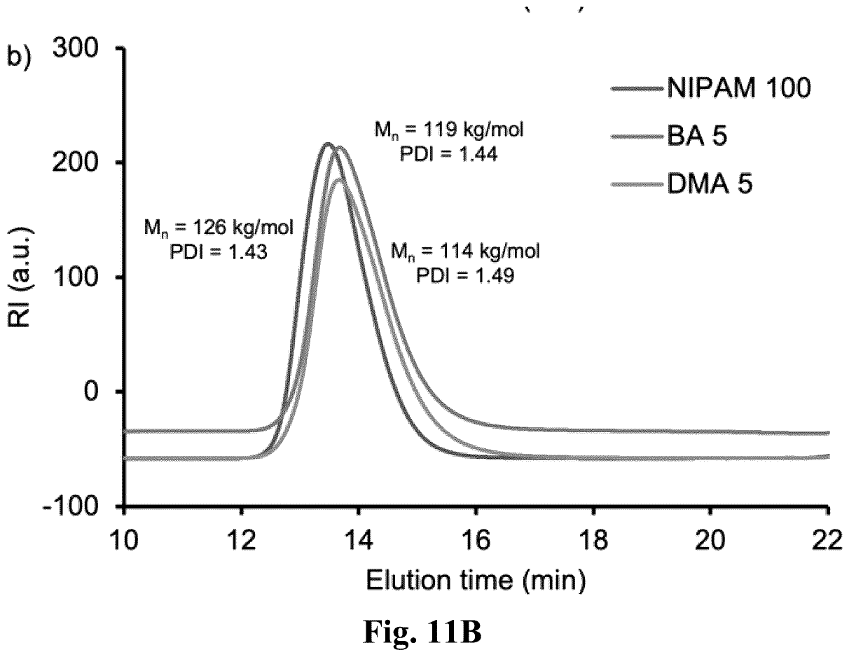

Described herein, we combine thermoresponsive polymers and thermoplasmonic nanoparticles to drive the self-assembly of polymers in a spatially controlled manner via NIR light (FIG. 1). PNIPAM homo- and copolymers were synthesized via photoinduced electron transfer-reversible addition fragmentation chain transfer (PET-RAFT) polymerization using diphenyl(2,4,6-trimethylbenzoyl)phosphine oxide as the photoinitiator and 2-(n-butyltrithiocarbonate) propionic acid (BTPA) as the chain transfer agent (FIG. 10 and FIG. 11A-11B). AuNRs are used because their localized surface plasmon resonance (LSPR) peak lies in the NIR region around 780 nm, with a significantly deeper penetration depth than UV (FIG. 1). UV light has a penetration depth of less than 300 μm, whereas NIR light, with its photothermal effects, penetrates much deeper (on the mm to cm scale) due to its lower absorption and scattering in resins.²⁷ We employ AuNR with dimensions of 8×32 nm as thermoplasmonic transducers under NIR irradiation. These dimensions ensure that the nanorods operate within the dipolar limit of Mie theory, as their characteristic size is significantly smaller than the excitation wavelength (r<<A). In this regime, the nanoparticle polarizability scales with volume (α∝r³), leading to an absorption cross-section that scales as r³, whereas the scattering cross-section scales as r⁶. Consequently, radiative scattering becomes negligible relative to absorption for sufficiently small nanostructures, maximizing non-radiative energy dissipation and photothermal conversion efficiency.^{28,29} This photothermal effect from AuNRs is harnessed to drive thermally-induced phase separation and mild chemical crosslinking to render the phase-separation irreversible and spatially fixed after NIR exposure (FIG. 1). We investigate how polymer molecular weight and copolymer composition affect thermal transitions and assembly behavior; how nanoparticle concentration and laser irradiance influence heat generation; and how nanoparticle surface functionality regulates phase separation and final properties. To evaluate the role of interfacial interactions, we functionalize nanoparticle surfaces with hydrogen-bond-forming ligands of varying binding affinities, including cysteamine (C), 3-mercaptopropionic acid (MPA), and 11-mercaptoundecanoic acid (MUA), and a non-interacting ligand, dodecanethiol (DDT), which serves as a control (FIG. 1).

### Results and Discussion

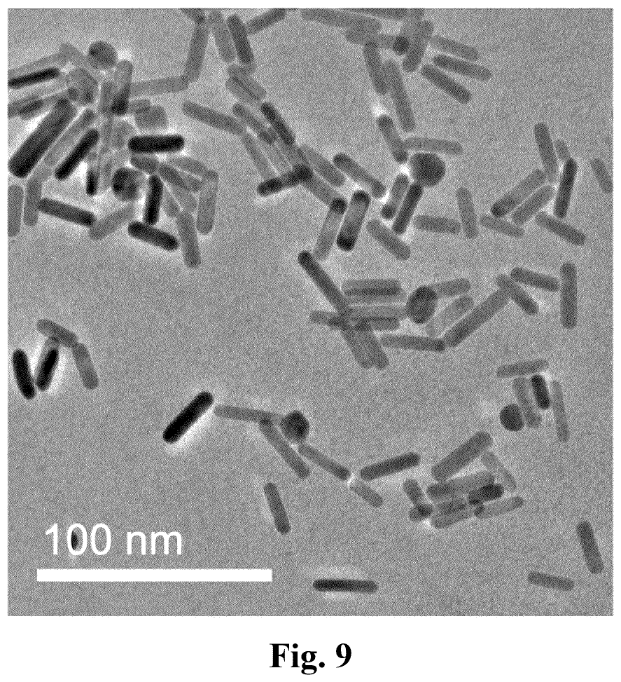

To test the photothermal effect of AuNRs in a polymer solution, a solution of as-synthesized AuNRs (FIG. 9), 10 wt. % PNIPAM (FIG. 10), ~90 wt. % water was combined, irradiated with an 808 nm laser for 5 min, and the temperature change of the solution was screened using a thermal camera. AuNRs with an aspect ratio of 4 were synthesized as their longitudinal LSPR peak is at 780 nm, which exhibits 92% absorption at the laser wavelength of 808 nm (FIG. 2A).³⁰ The extent of photothermal effect can be adjusted by varying the NIR laser power and nanoparticle loading (i.e., concentration) (FIG. 2B-2C). Upon irradiation, the solution temperature increases rapidly within 30 s and continues to increase gradually. Heat dissipation proceeds relatively fast when the laser is turned off. The photothermal effect is enhanced with increasing laser power, as evidenced by the higher temperature reached within the same time frame (FIG. 2B). At a constant laser power of 300 mW, with higher concentrations of AuNRs, the solution temperature increases more rapidly and reaches a higher maximum value within the same response time (FIG. 2C). More importantly, when the temperature goes above its LCST (~35 °C), a reduction in the solvation of water molecules around the polymer occurs due to the disruption of hydrogen bonding. This leads to increased interactions between polymer molecules, causing the structure to collapse and phase-separate from the solution.^{31,32}

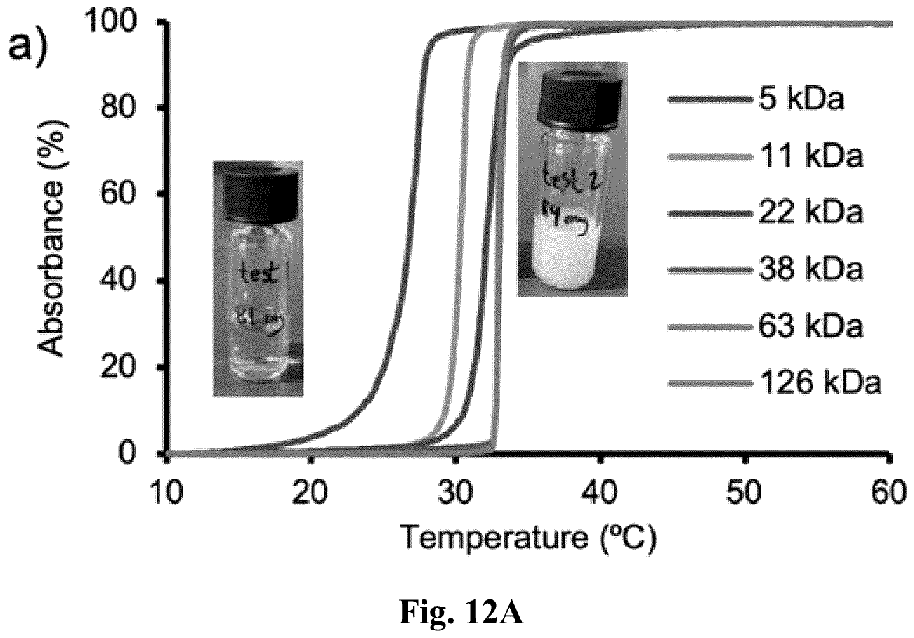

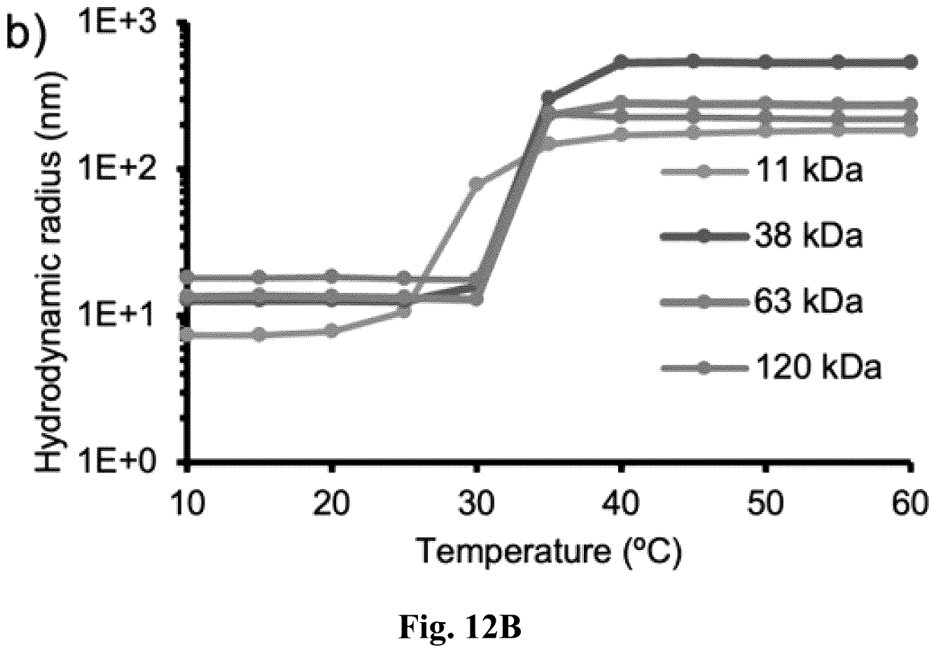

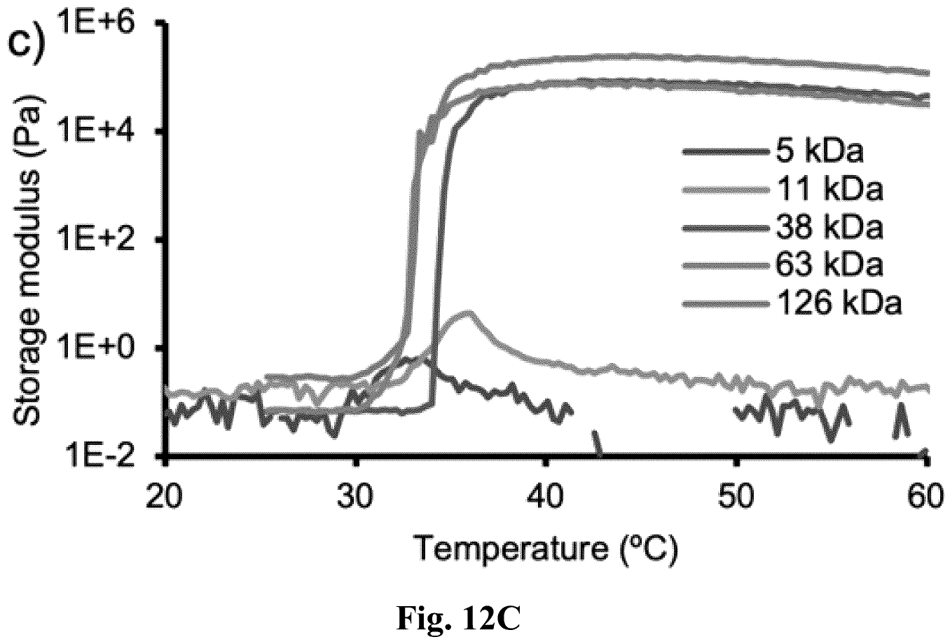

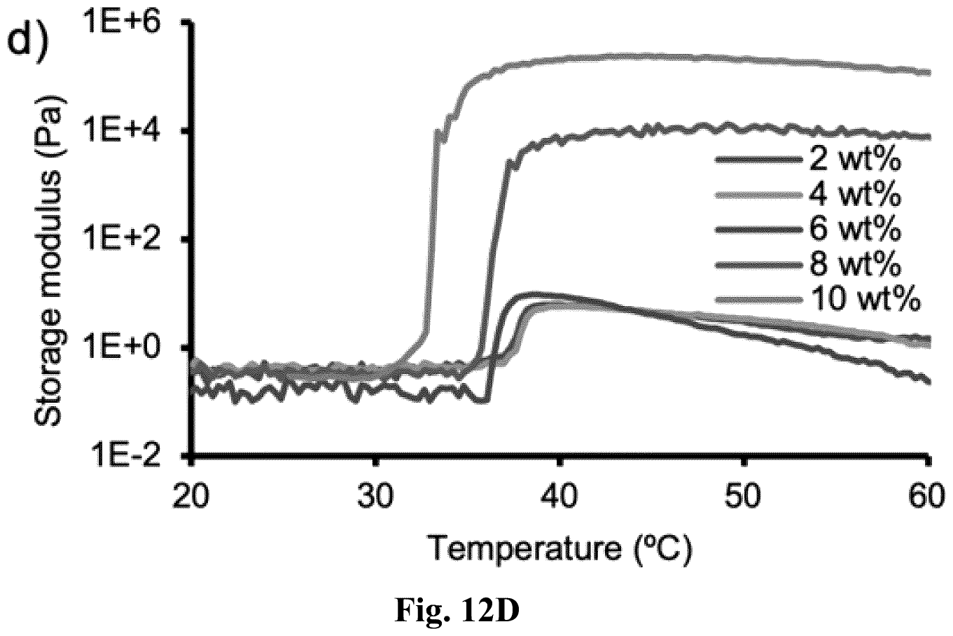

The size and composition of polymers impact thermal phase transitions, including the cloud point (T_{cp}), which signifies the coil-to-globule transition of polymers and is closely related to LCST behavior. T_{cp} is defined as the temperature at which half of the maximum absorbance (i.e., 50% transmittance) is reached. Three different polymers were studied: PNIPAM with a range of molecular weights from 5 to 126 kg/mol, PNIPAM-butyl acrylate (BA) random copolymer, and PNIPAM-N, N-dimethyl acrylamide (DMA) random copolymer (FIG. 3A and FIG. 11A-11B). These transitions were investigated using UV-Vis spectroscopy, where absorbance was screened at a fixed wavelength (400 nm) as a function of temperature from 10 to 70 °C. With increasing molecular weight of PNIPAM, T_{cp} increases, approaching an asymptotic value of 33 °C (FIG. 3B and FIG. 12A). This indicates that once a molecular weight threshold is reached, increasing the polymer chain length no longer affects T_{cp}. Additionally, the coil-to-globule transition of PNIPAM is investigated using dynamic light scattering (DLS) and rheological measurements.³³⁻³⁵ First, DLS is used to characterize the hydrodynamic radius of polymers as a function of temperature. A significant increase in size was observed at the phase transition temperature, consistent with UV-Vis data (FIG. 12A-12B). Although a decrease in the size of the PNIPAM chain at the LCST is expected due to dehydration,^{36,37} the observed increase in hydrodynamic radius is attributed to the association of multiple polymer chains, forming insoluble aggregates. Although higher molecular weight polymers exhibit a larger hydrodynamic radius below LCST, this trend no longer follows in the globular state. There seems to be an optimal molecular weight that provides a balance between intramolecular (i.e., entanglement, which defines the volume of each coil) and intermolecular interactions (i.e., association of multiple coils, determined by available surface area) to reach a large globular state (FIG. 12B).³⁸ Another way to alter T_{cp} is by copolymerizing NIPAM with hydrophobic BA and hydrophilic DMA, where BA and DMA have different affinities for water, being more hydrophobic and hydrophilic than NIPAM, respectively. The incorporation of hydrophobic polymers facilitates phase separation from the aqueous solution at lower temperatures. In contrast, more hydrophilic polymers have the opposite effect, although to a lesser extent (FIG. 3C). Relative to the T_{cp} of PNIPAM (34 °C), a random copolymer with 5 mol % BA exhibits a lower Top of 27 °C, and one with 5 mol % DMA exhibits a higher value of 36 °C (FIG. 3C). Increasing the mol % of BA and DMA lowers and increases the T_{cp} to a larger extent, respectively.

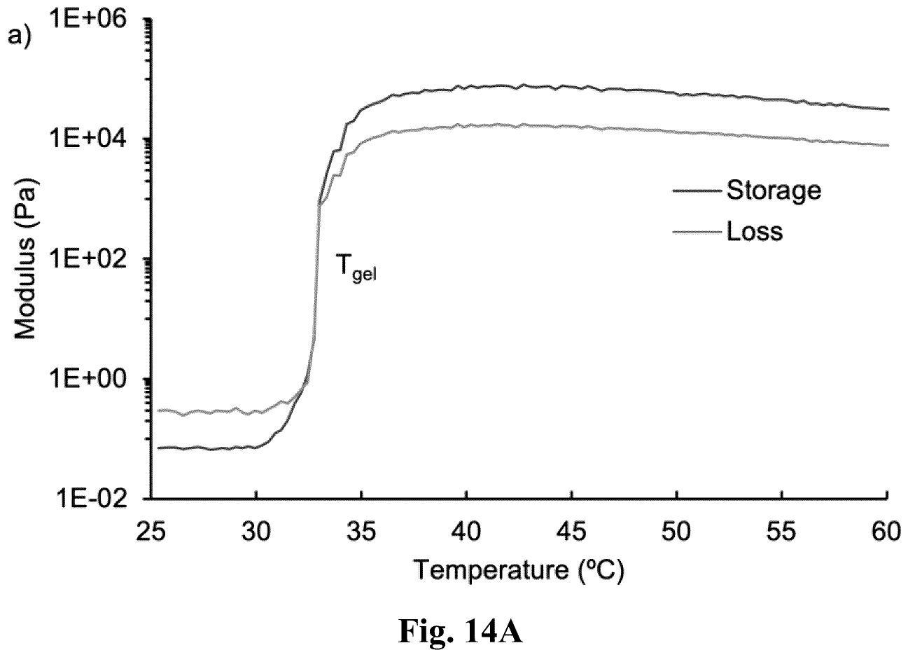

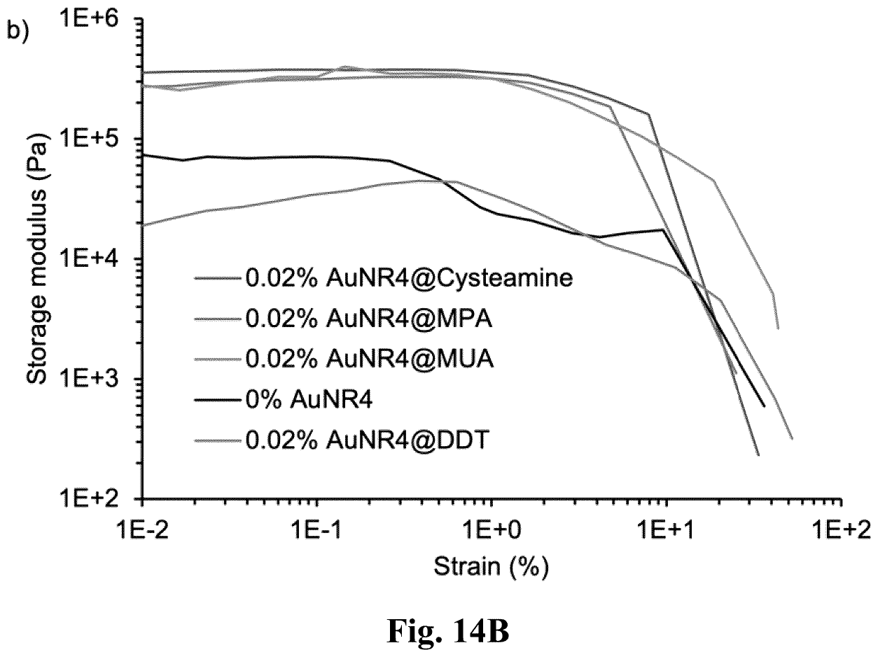

Another important variable to understand is the gelation behavior of polymer nanocomposites. PNIPAM phase transition induced by heat from thermoplasmonic nanoparticles forms mesoglobular aggregates around nanoparticles, which then gelate into an extended network, due to Marangoni convective flows.³⁹⁻⁴¹ The gelation temperature (T_{gel}) is determined from rheological measurements as the point at which the storage and loss moduli intersect.⁴² Additionally, the mechanical properties of gels synthesized from PNIPAMs with different molecular weights and concentrations were investigated (FIG. 12C and FIG. 14A). For the molecular weight study, the concentrations of PNIPAM solutions were kept at 10 wt./v %, meaning the total number of polymer chains in solution depends on molecular weight (i.e., a smaller number of longer chains were contained in the 10 wt./v % solution compared to shorter chains). As the longer PNIPAM chains (above 38 kg/mol) can form more entanglements, they assembled into a gel with a higher storage modulus (126 kg/mol: 212 kPa; 63 kg/mol: 57 kPa; 38 kg/mol: 53 kPa) (FIG. 12C). Below the entanglement molecular weight reported between 15 and 30 kg/mol,⁴³ the physical gels formed were very weak, with storage moduli below 1 Pa (11 kg/mol: 0.3 Pa; 5 kg/mol: 0.08 Pa), demonstrating that entanglement is important to print stand-alone structures (FIG. 12C). The solution concentration should be above a threshold to form a gel, as high water content also makes the chains diffuse and lowers the possibility of intermolecular entanglements. Consistent with previous results about the entanglement concentration of PNIPAM,^{44,45} a concentration of at least 8 wt./v % is necessary to induce gelation, as demonstrated by the storage modulus value (FIG. 12D).

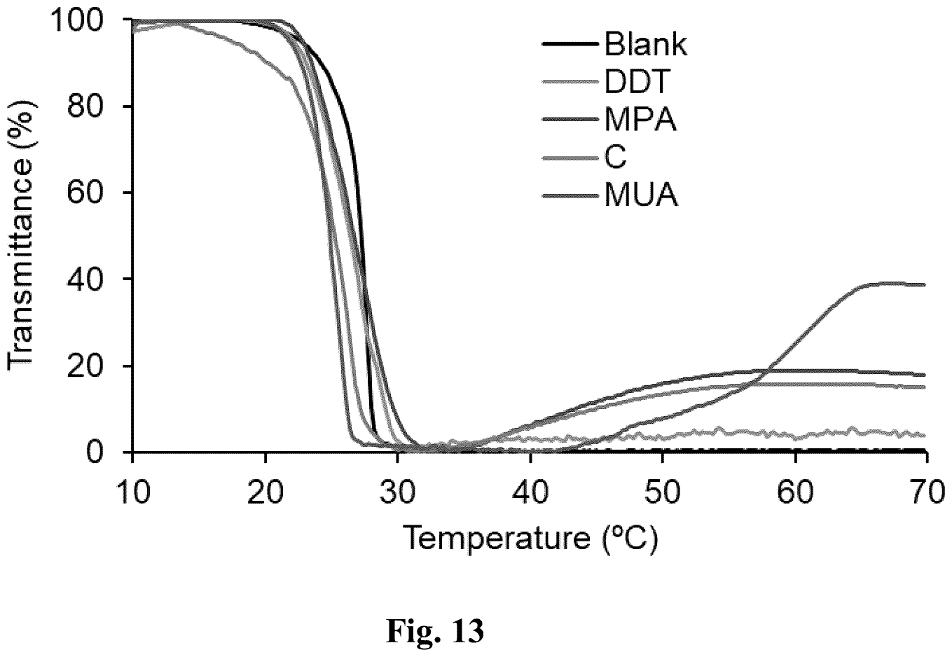

The interfacial interactions between nanoparticles and polymers play a crucial role in the assembly behavior and mechanical properties.⁴⁶ To investigate the role of interfacial interactions, nanoparticles were functionalized with four different ligands: DDT, C, MPA, and MUA (FIG. 4A). Each nanoparticle set (~0.001 wt./v % in the final solution) was combined with PNIPAM of molecular weight 126 kg/mol at a concentration of 5 wt./v %. DDT was a control, whose alkyl chain does not form hydrogen bonding with PNIPAM, whereas C, MPA, and MUA contain end moieties that form hydrogen bonding with PNIPAM with varying strength. The incorporation of nanoparticles affects T_{cp}. Inclusion of nanoparticles lowers T_{cp}, which can be attributed to a lower energetic barrier for the coil-to-globule transition in the presence of a heterogeneous phase, such as nanoparticles.⁴⁷ In addition to T_{cp}, turbidity variations (i.e., solution cloudiness resulting from light scattering by polymer particles) can be quantitatively assessed by spectroscopic measurements of transmittance changes during a controlled temperature sweep. The increase in transmittance is due to flocculation and subsequent sedimentation that occurs after phase separation (FIG. 13). Our results demonstrate that the interfacial interactions dictate the flocculation behavior above T_{cp}. A sample containing non-interacting nanoparticles (i.e., DDT-functionalized) exhibits a similar transmittance change as the control with no nanoparticles (~0%), which is consistent with the rheology data (FIG. 4B and FIG. 12D). On the other hand, with increasing cooperative interfacial bond strength (C<MPA<MUA), larger transmittance changes from 16 to 50% were observed (FIG. 4B). This result indicates that with sufficiently large interfacial interactions between nanoparticle and PNIPAM, an extended network of gels could form below the inherent entanglement concentration of PNIPAM (8 wt./v %). The color of the phase-separated structures is light brown, a characteristic color of AuNRs, indicating that these structures contain AuNRs and polymers. More importantly, the hydrogen bonding at the interface improves the storage moduli of nanocomposite gels (i.e., stiffness) (FIG. 3C, FIG. 14A-14B). These results highlight the role of polymer-nanoparticle interactions in thermally induced self-assembly and mechanical properties.

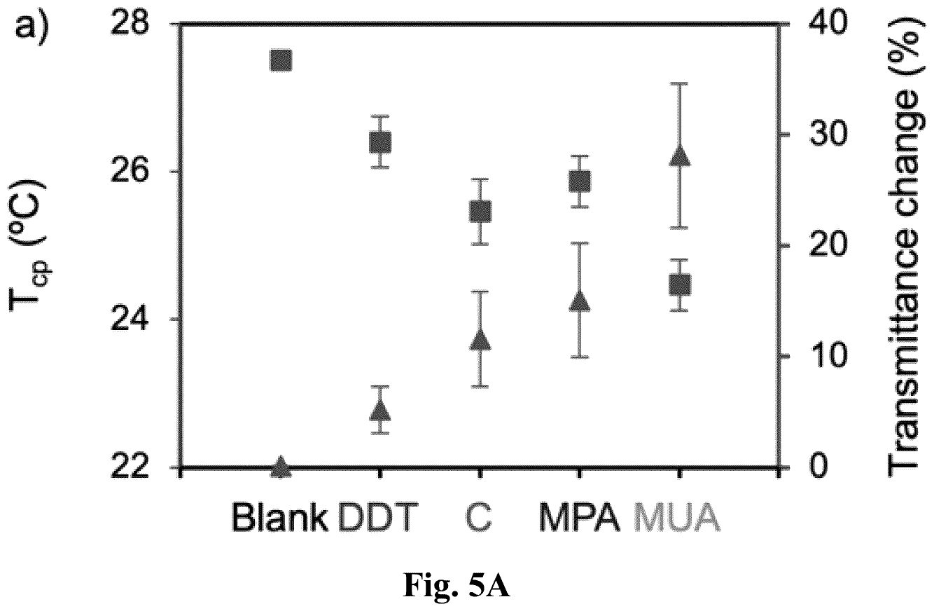

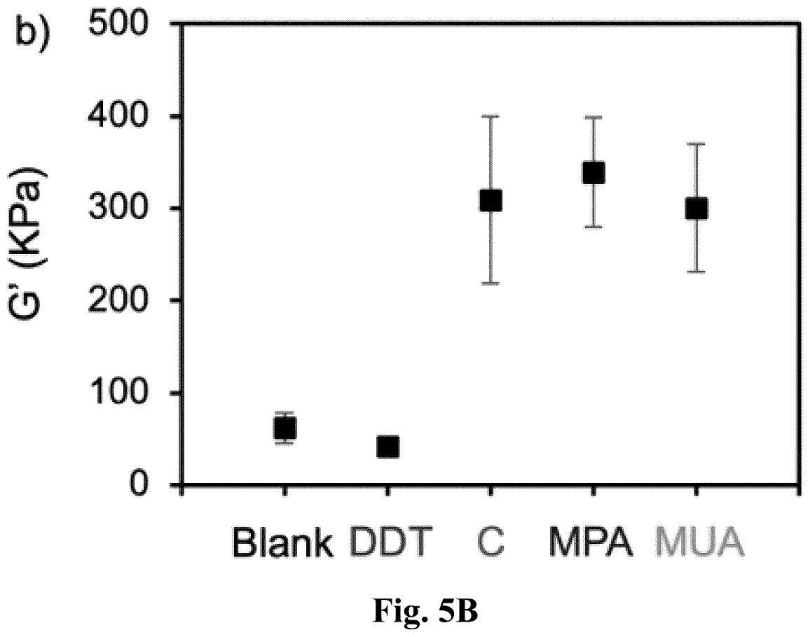

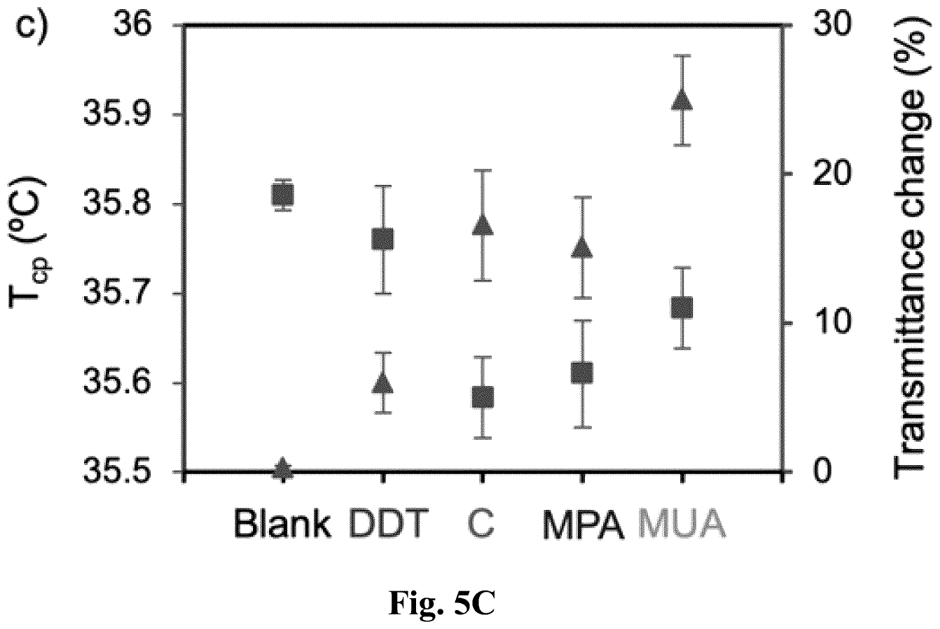

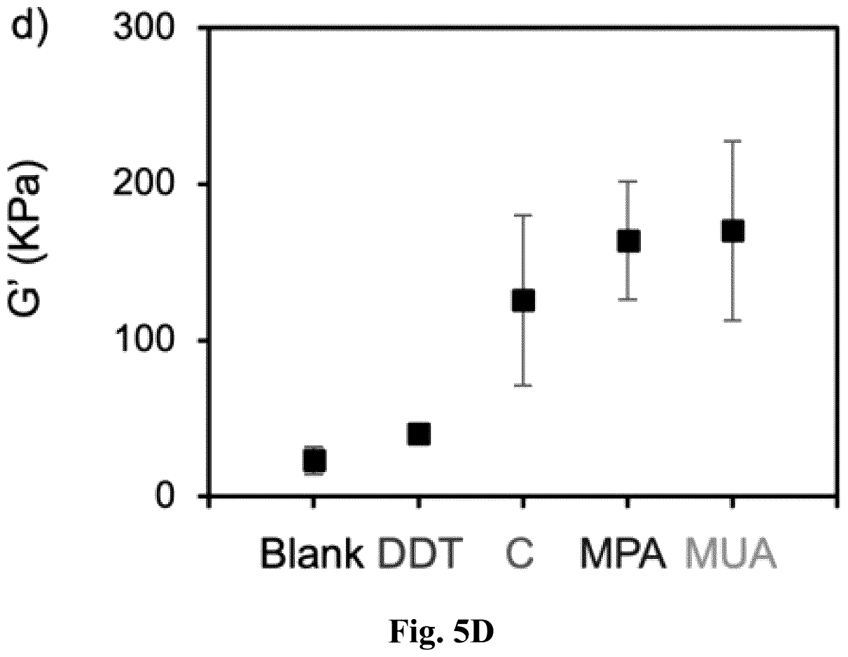

More detailed investigations into the polymer composition and surface ligand identity were conducted to better understand how these variables alter the thermally induced self-assembly behavior and the final mechanical properties of the gels. Consistently, T_{cp} is lowered in the presence of AuNRs relative to neat random copolymers (FIG. 5A and FIG. 5C). At 5 wt./v % of copolymer concentrations, minimal flocculation was observed above T_{cp}, consistent with the observation of neat PNIPAM (FIG. 4B, FIG. 5A, and FIG. 5C). Greater transmittance changes were measured for samples containing hydrogen-bonding inducing AuNRs (FIG. 5A and FIG. 5C). No significant differences in storage moduli are observed between PNIPAM homopolymers and BA-containing copolymers (FIG. 4C and FIG. 5B). Replacing thermoresponsive NIPAM units with BA introduces a competitive effect between the increased hydrophobic content, which may promote water expulsion and mesoglobule reinforcement, and the reduced number of amide groups capable of intermolecular hydrogen bonding, which may weaken the network structure. The reduction in storage moduli in copolymers containing DMA relative to those of PNIPAM and its nanocomposites is attributed to the higher hydrophilicity of DMA, which exerts a plasticizing effect (FIG. 5D). Nonetheless, hydrogen-bonding-forming AuNRs consistently improve the mechanical property of gels relative to neat polymer systems.

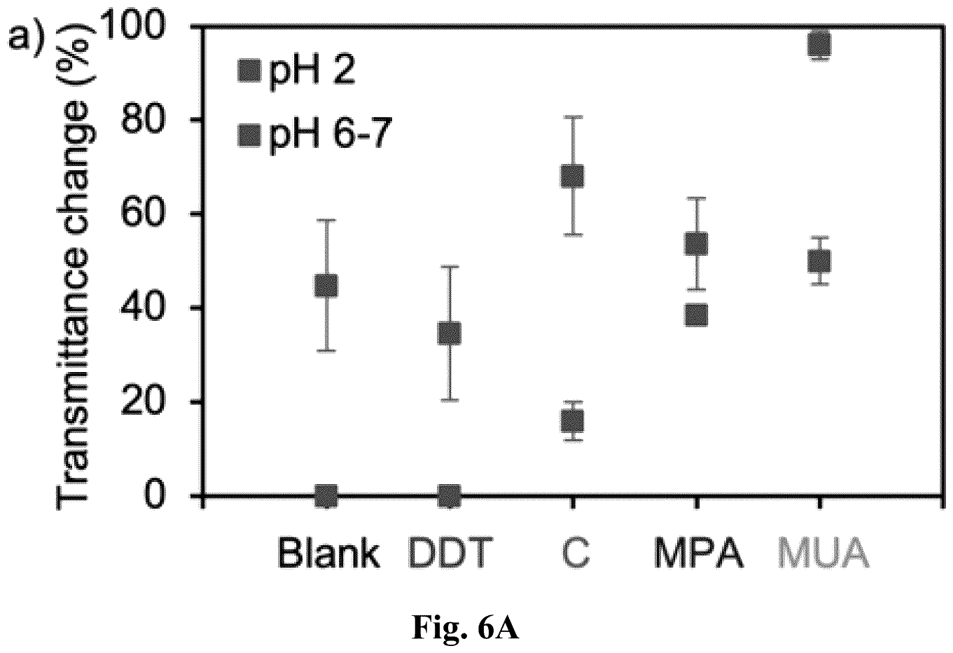

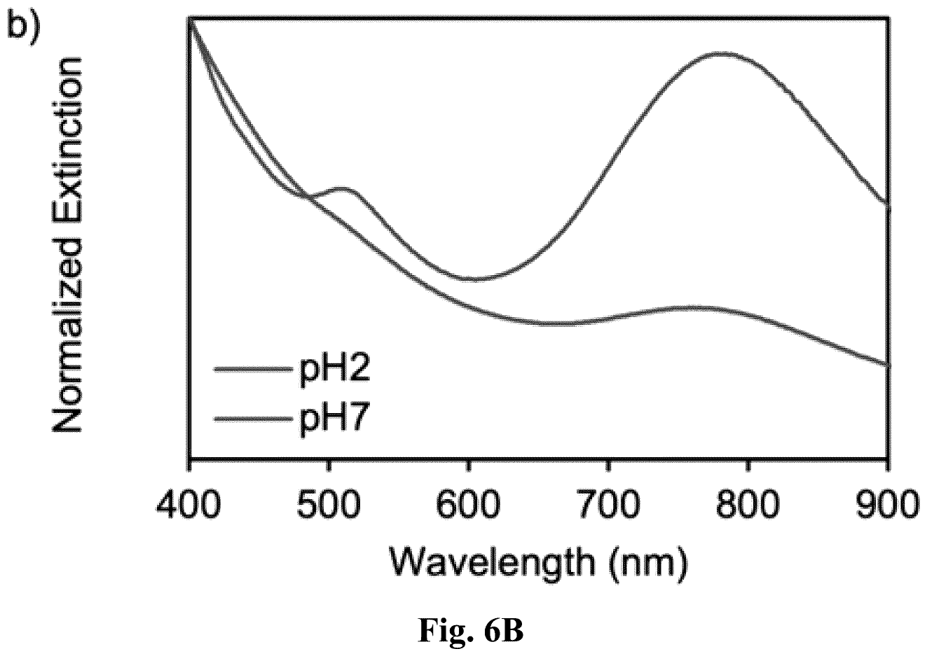

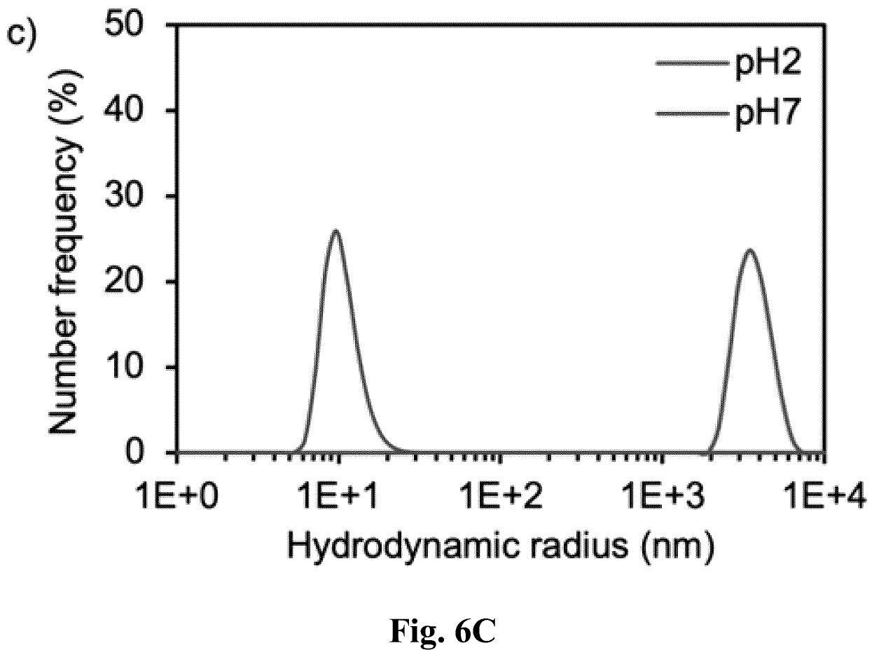

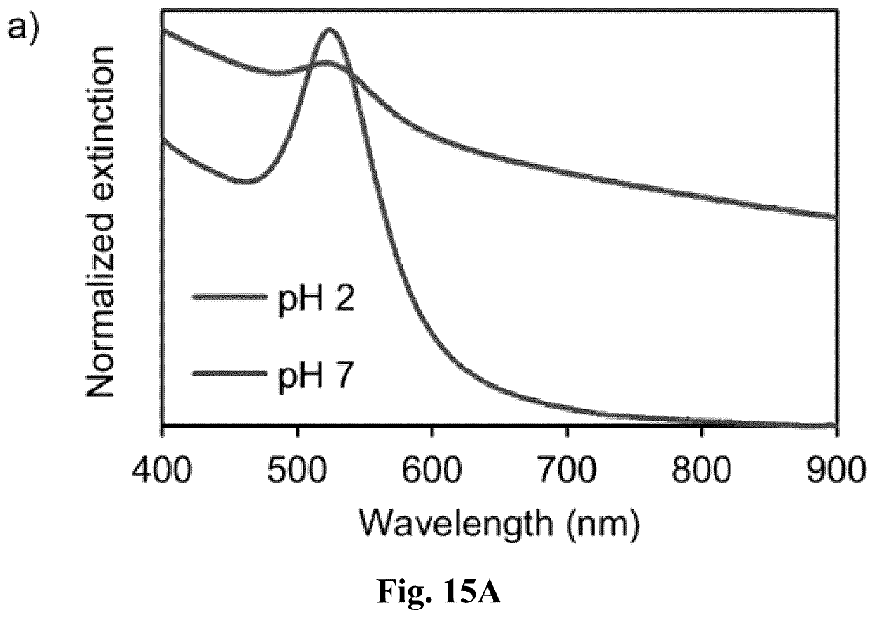

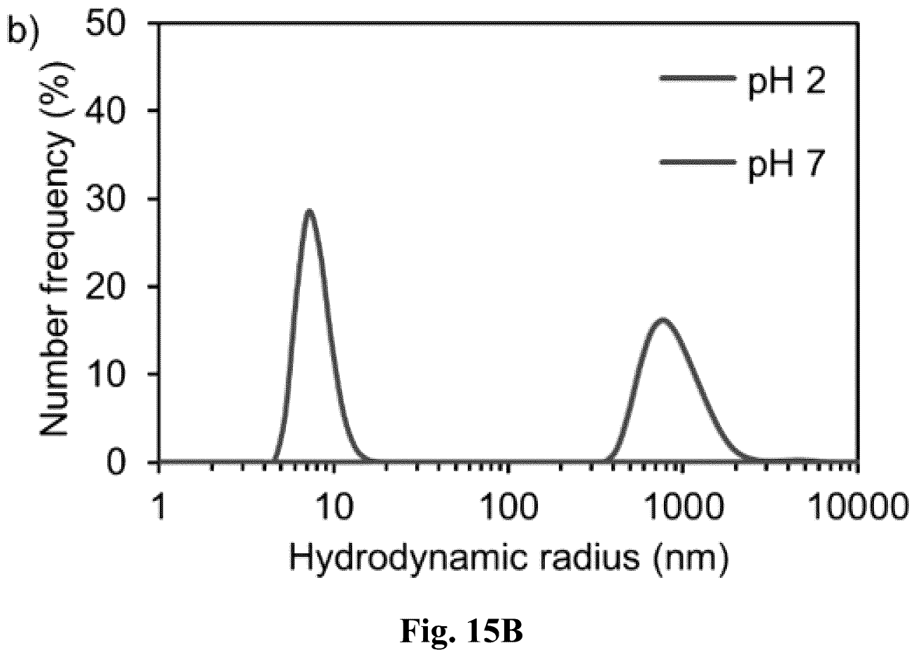

The assembly of mesoglobules from PNIPAM and AuNRs is tunable by altering the solution pH due to pH-responsive carboxylic acids on the chain ends of PNIPAM (the chain transfer agent used in PET-RAFT polymerization) and surface ligands around nanoparticles. MPA and MUA have pKa values around 4.^{48,49} PNIPAM without the chain transfer agent is non-pH-responsive. However, BTPA at the chain terminal ends introduces a pH-responsive site that undergoes protonation and deprotonation depending on the solution pH. At lower pH, carboxylic acids are protonated, and the extent of flocculation increases due to hydrogen-bonding interactions between polymers and between polymers and AuNRs, which is evident from the transmittance values of control samples containing PNIPAM with no AuNRs (0 to 45%) and PNIPAM with non-interacting DDT-functionalized AuNRs (0 to 35%) (FIG. 6A). At a lower pH, these hydrogen-bonding interactions are greater and lead to self-assembly of PNIPAM and AuNRs below the LCST of PNIPAM, which were characterized using UV-Vis and DLS at room temperature (FIG. 6B and FIG. 6C). At room temperature, no flocculation was observed. However, there is an increase in turbidity due to the formation of polymer-AuNR clusters as the interactions between AuNRs and PNIPAM are enhanced (FIG. 6B).⁵⁰⁻⁵² The formation of such clusters can compromise the solubility, resulting in optically active aggregates. Furthermore, this complexation at pH=2 results in an increased transverse surface plasmon resonance (TSPR) peak (λ=517 nm) relative to the longitudinal surface plasmon resonance (LSPR) peak (λ=785 nm) of AuNRs, suggesting that pH can be used to tailor the maximum peak position and operational wavelength for the thermoplasmonic effect. DLS measurements confirmed the formation of multi-particle aggregates at lower pH, as indicated by the change in hydrodynamic radius from 10 to 3500 nm (FIG. 6C). Similar results are obtained with different-shaped nanoparticles (i.e., spherical nanoparticles), indicating that nanoparticle shape does not influence the assembly behavior (FIG. 15A-15B).

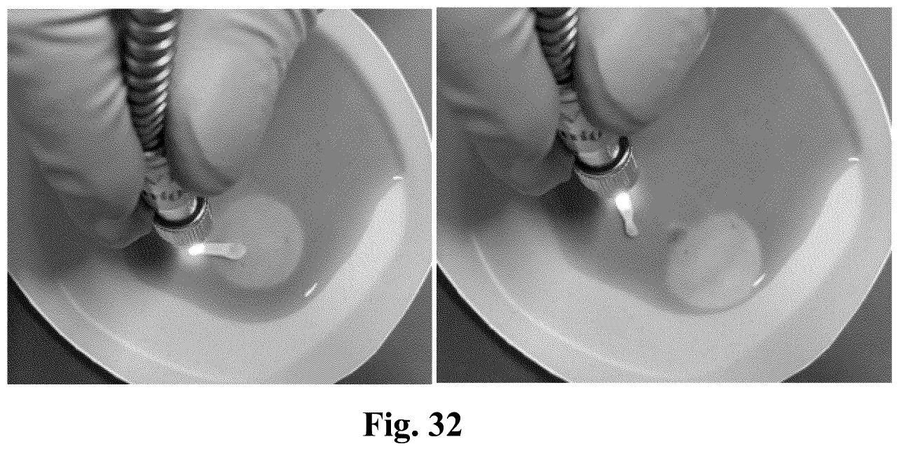

To test the feasibility of this system for self-assembly-driven microlithography, we prepared a solution containing 10 wt./v % PNIPAM (126 kg/mol) and 0.002 wt./v % surface-functionalized AuNRs in a petri dish. Upon irradiation with an 808 nm laser, the solution rapidly separated within seconds (FIG. 32. However, because these phase-separated structures revert to the solution phase upon cooling, 10 wt./v % of poly(ethylene glycol dimethacrylate) (PEGDMA with a molecular weight of 550 Da) and potassium persulfate were incorporated as a crosslinking agent and radical thermal initiator (FIG. 7A). Our studies demonstrate that potassium persulfate can be activated at a temperature as low as 40 °C in the presence of ascorbic acid. The living chain ends of PNIPAM enable these chains to be crosslinked with PEGDMA above the activation temperature, following phase separation upon irradiation. The final concentrations of components in the resin were 10 wt./v % PNIPAM, 0.002 wt./v % AuNR, 10 wt./v % PEGDMA, 0.021 wt./v % potassium persulfate, and 0.035 wt./v % ascorbic acid.

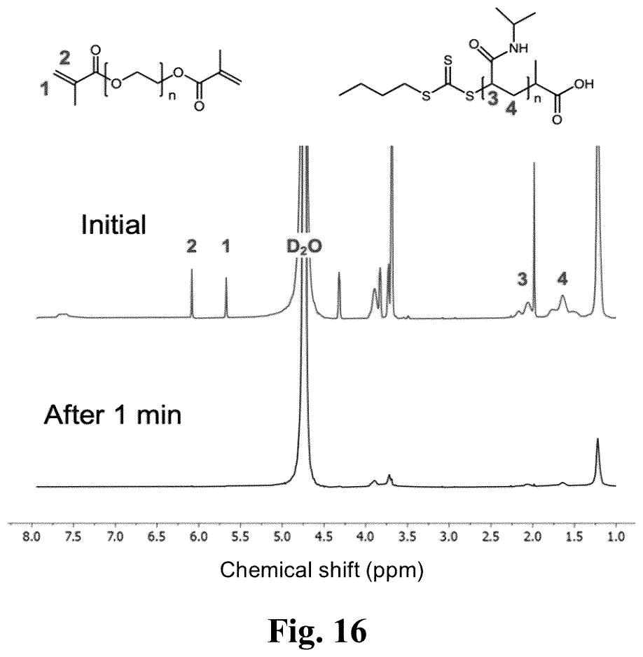

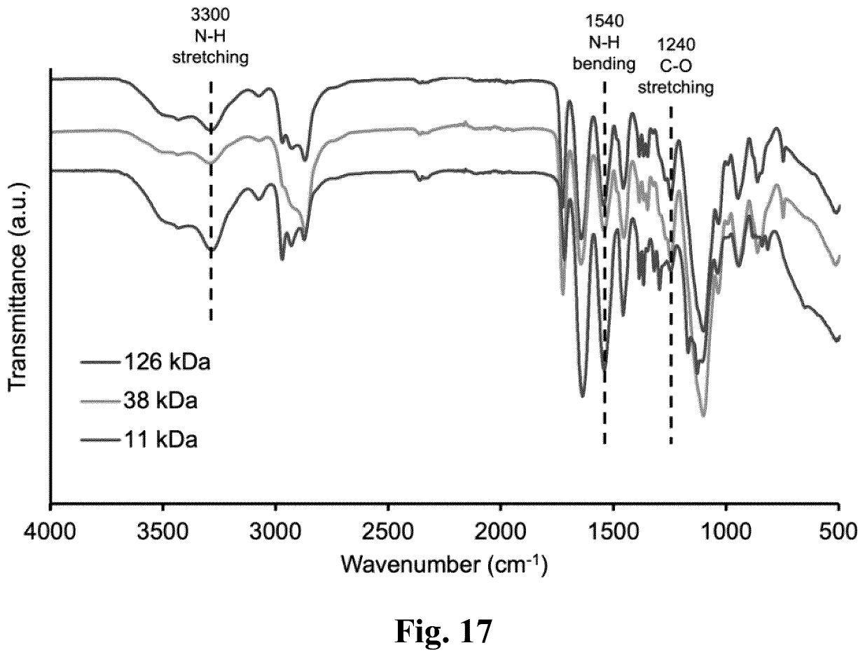

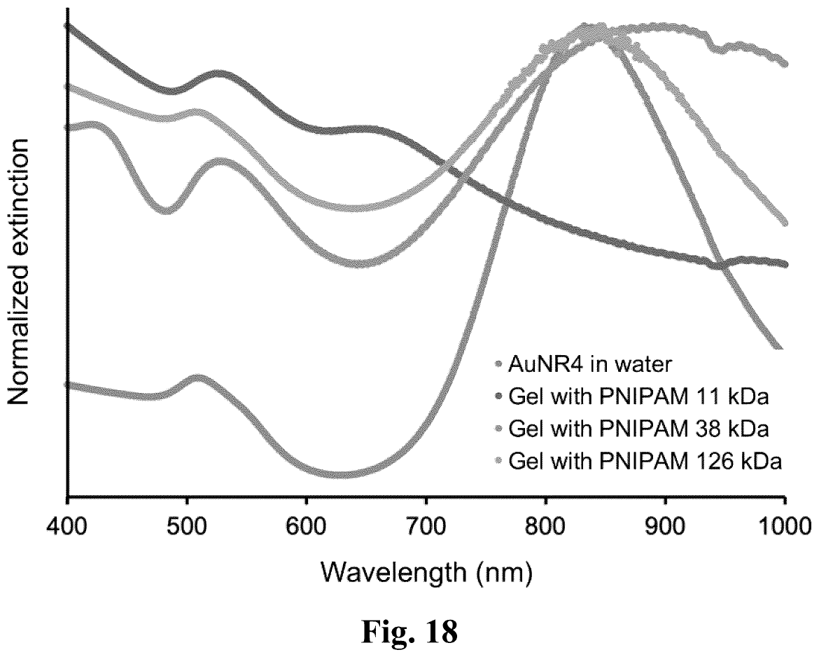

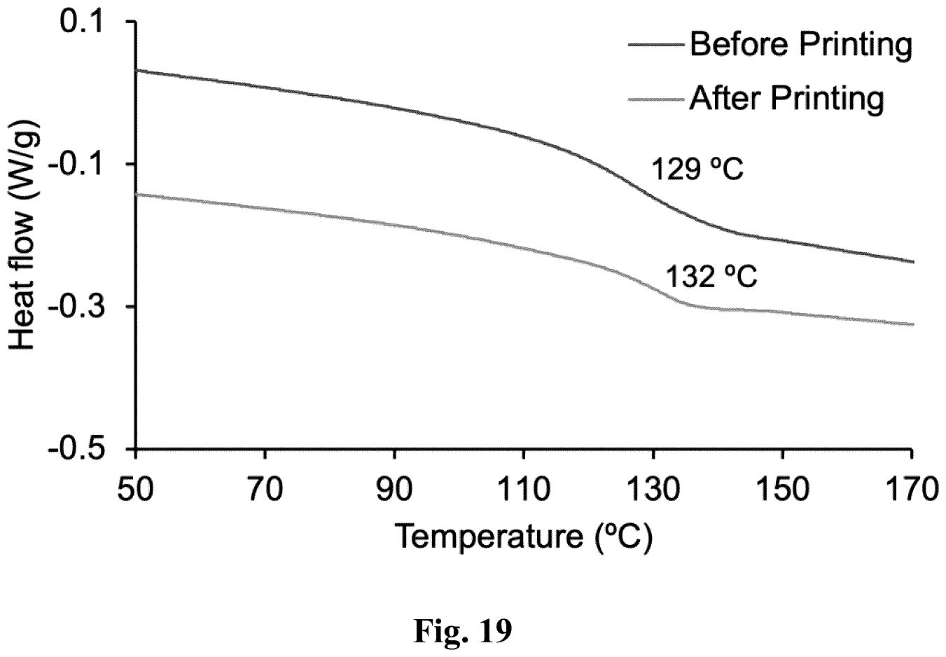

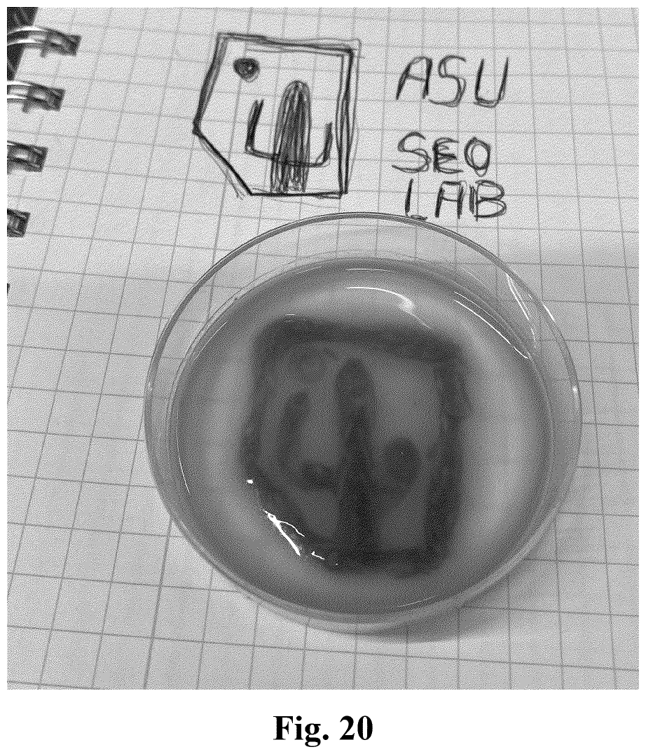

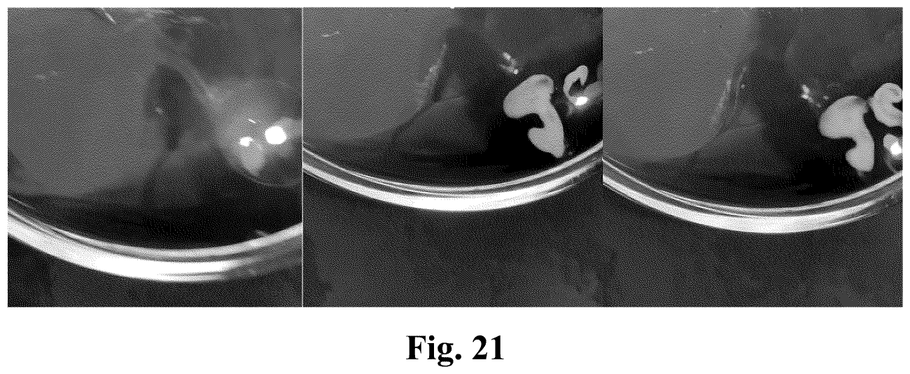

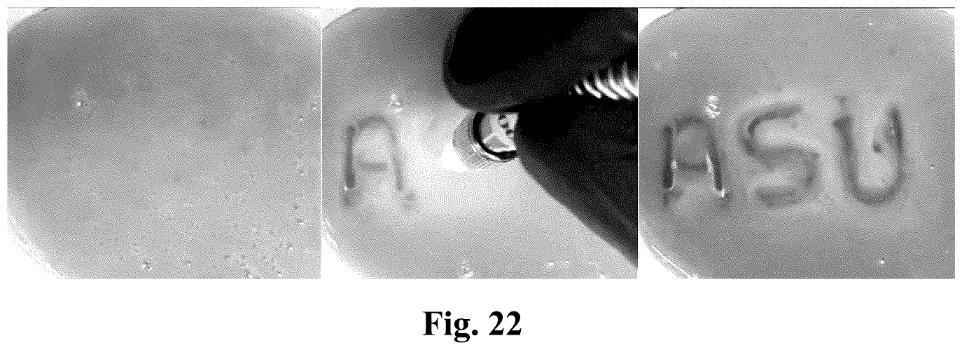

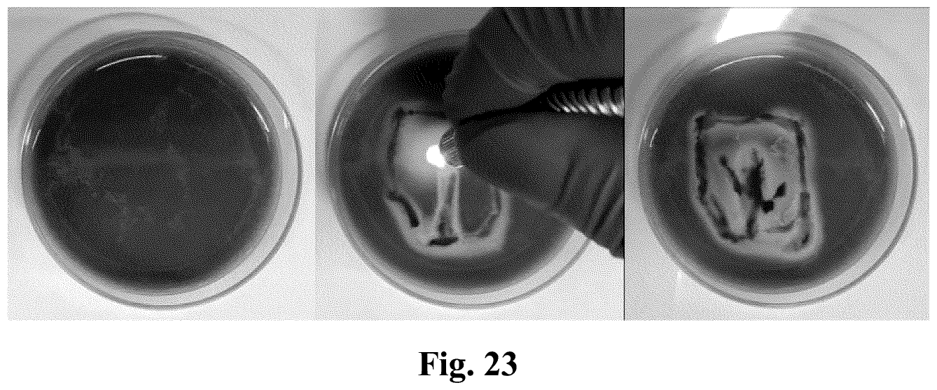

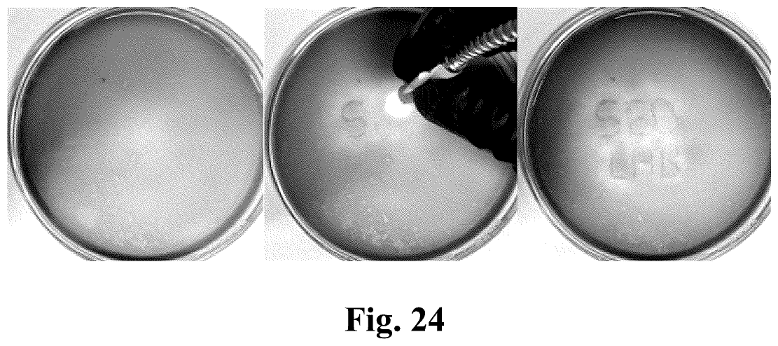

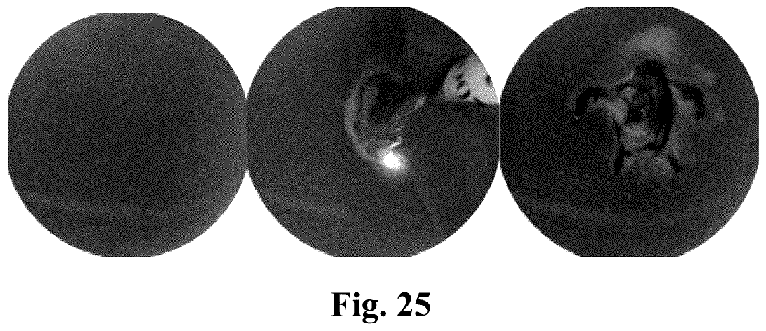

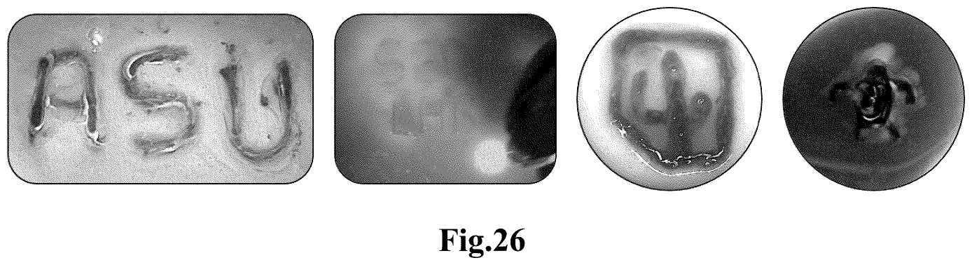

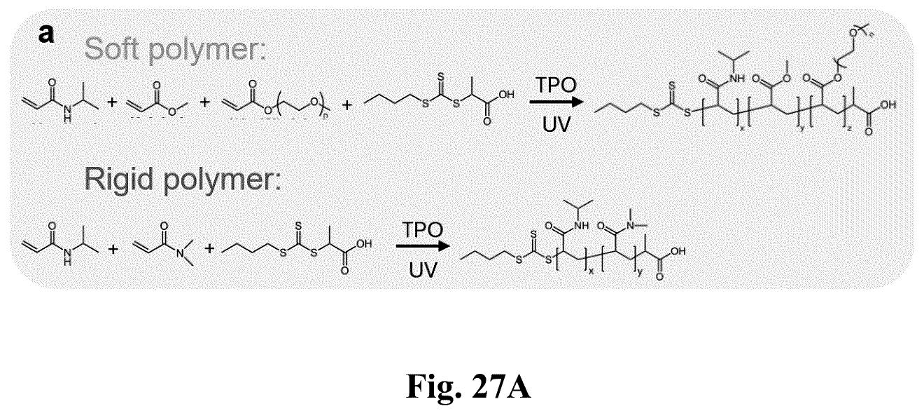

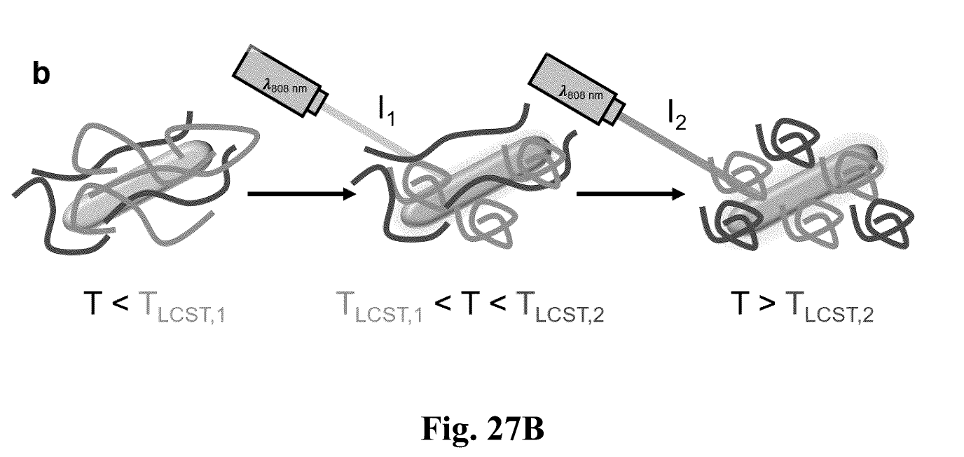

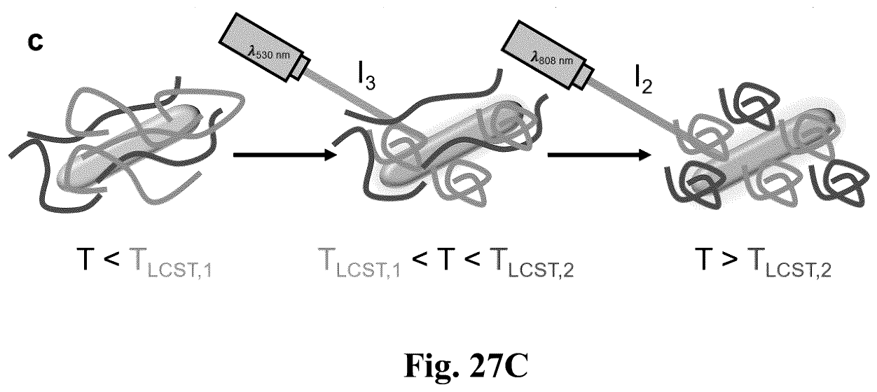

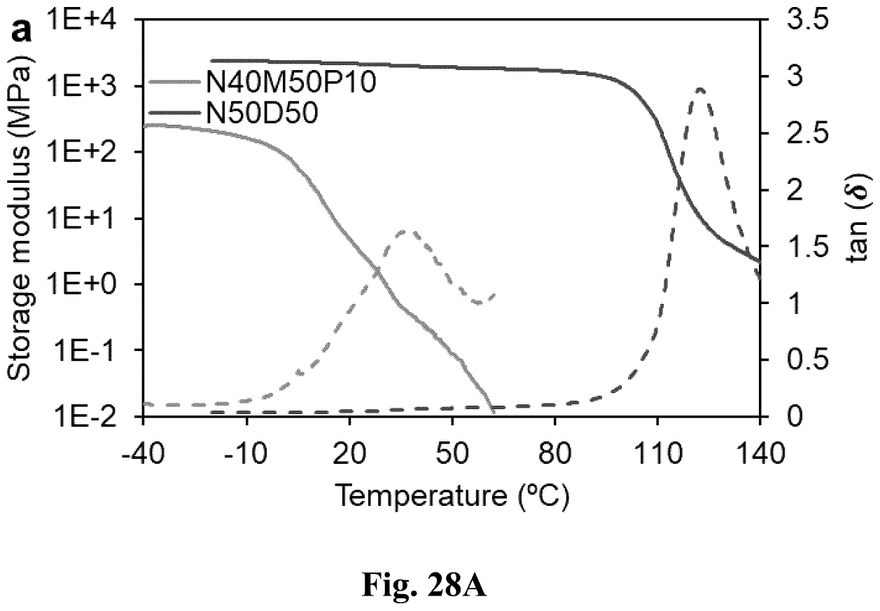

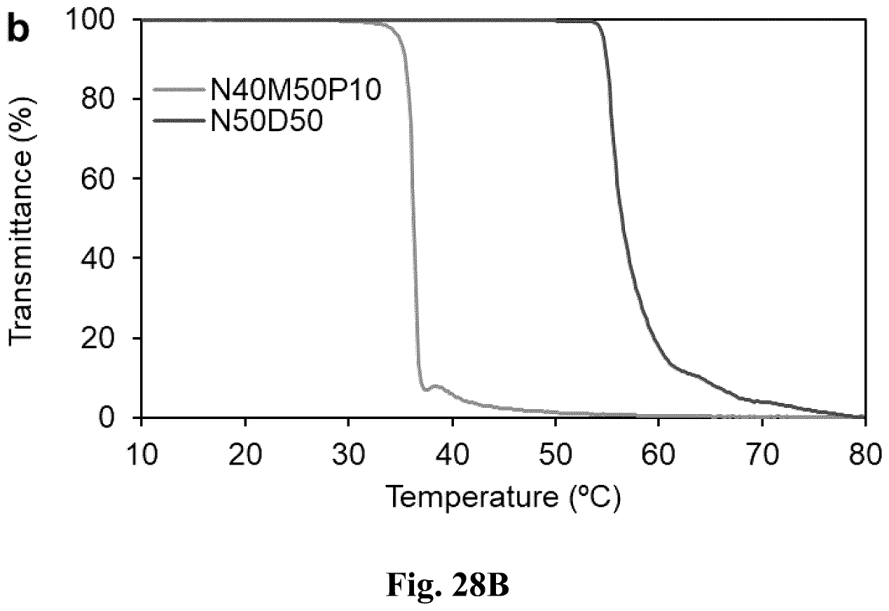

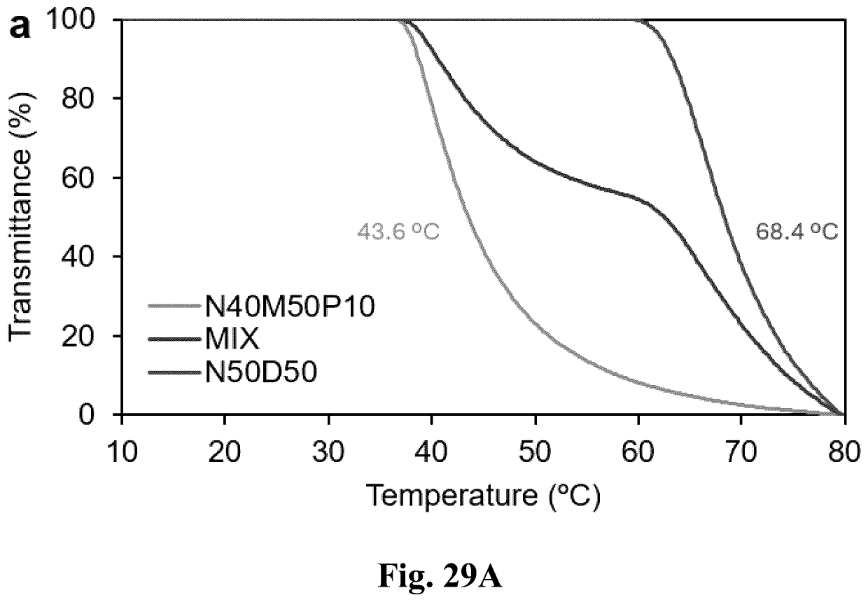

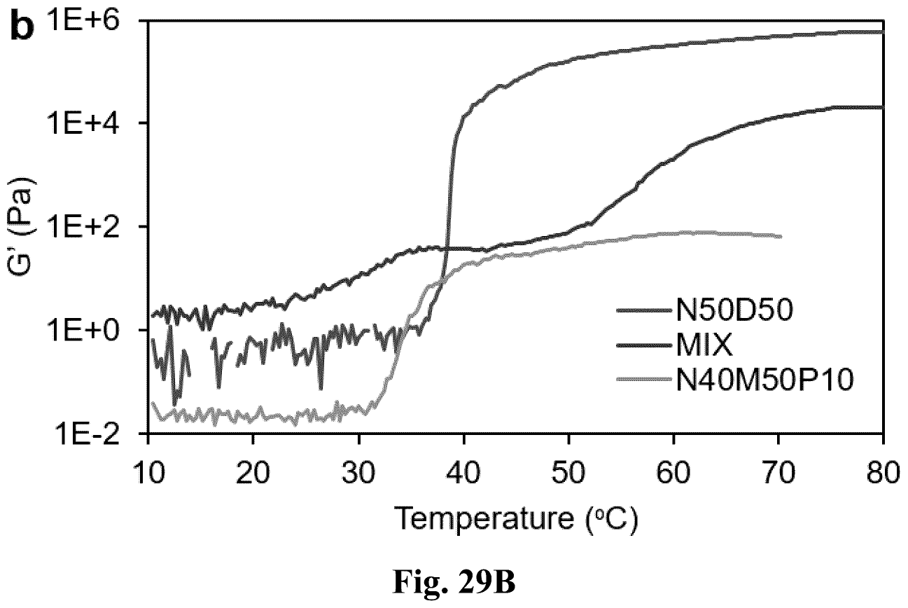

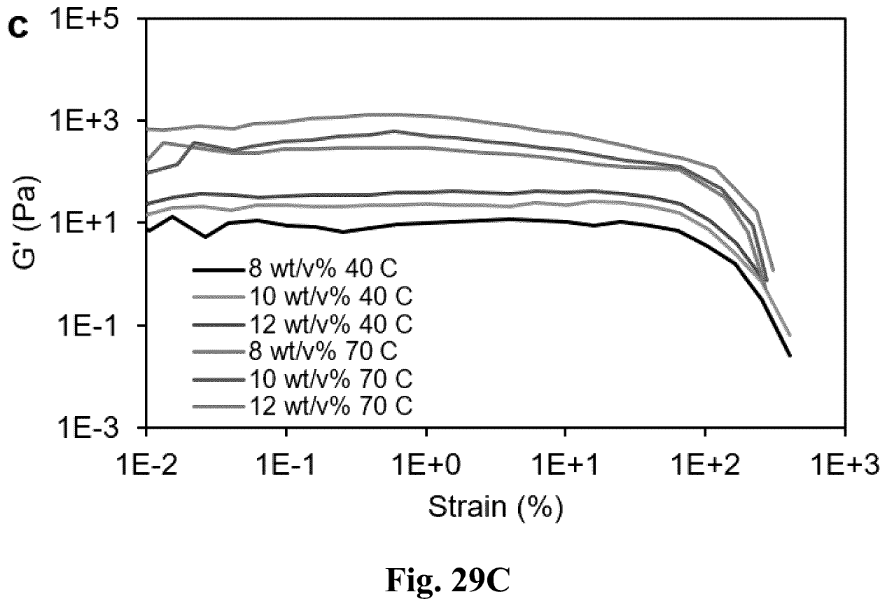

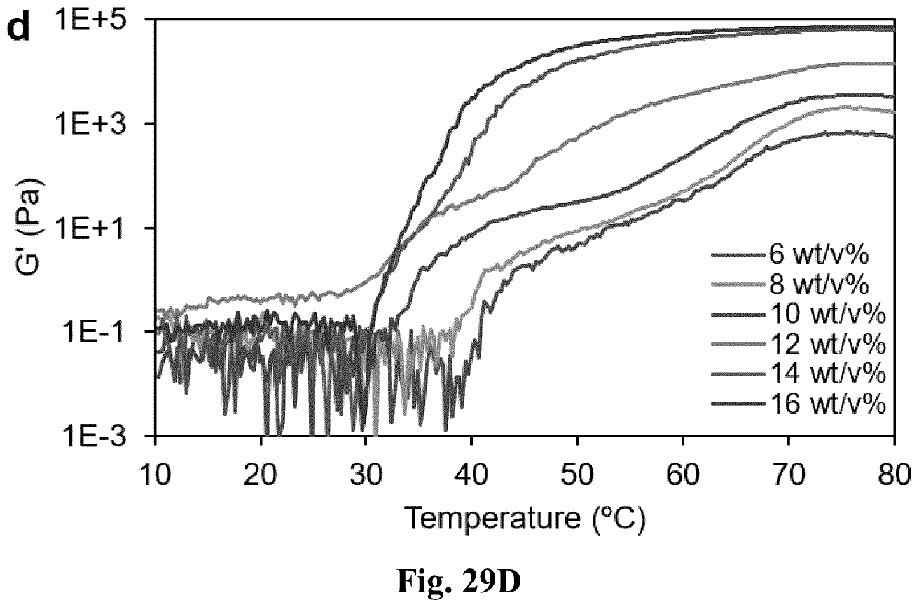

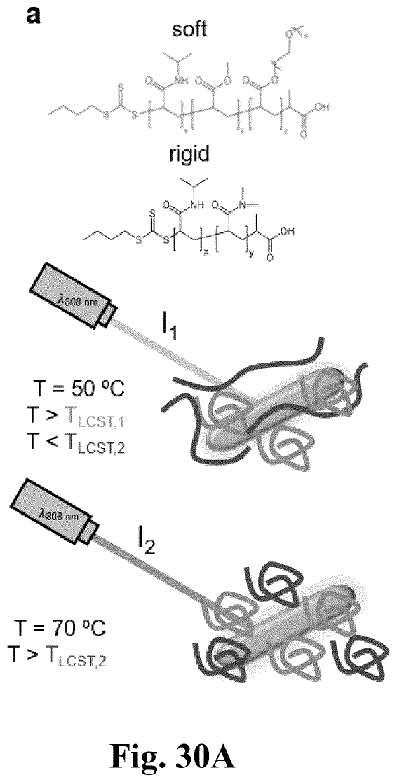

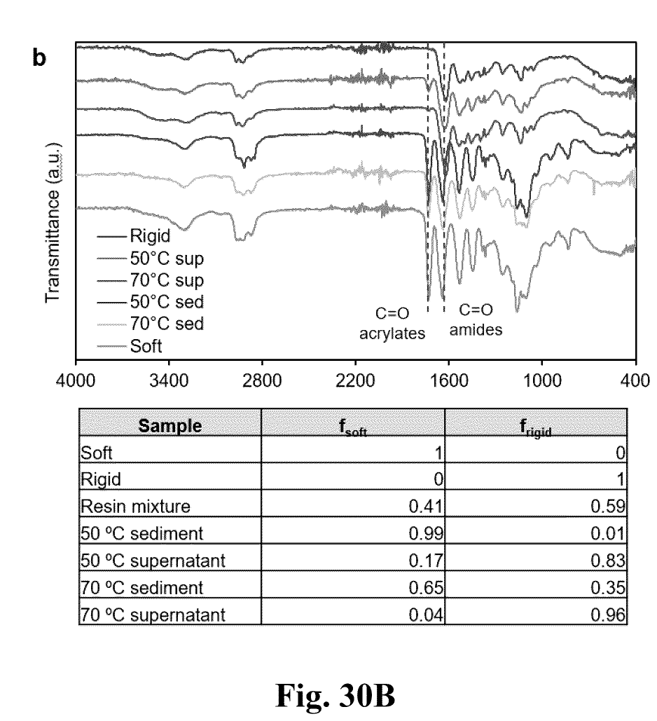

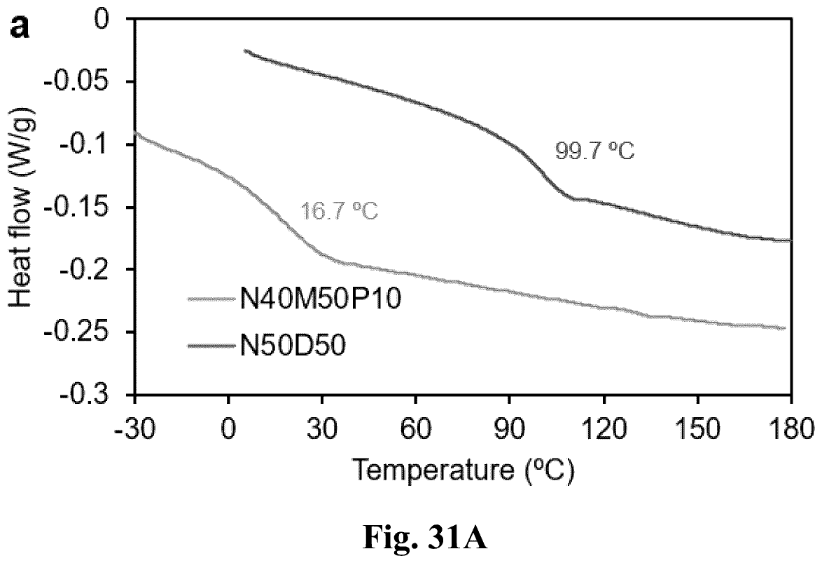

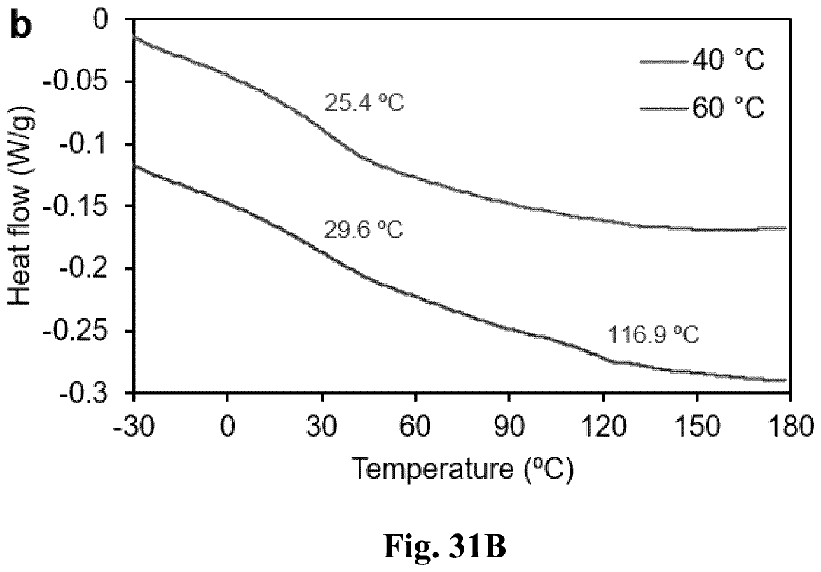

To understand the kinetics of the chemical crosslinking reaction, we first screened conditions for our resin system in a vial using a controlled thermal bath at 50 °C. Upon heating, PNIPAM and AuNRs phase separate and form crosslinked networks, leaving unreacted components in the aqueous phase. Gelation occurred within a minute under these conditions, and aliquots of the unreacted phase before and after gelation were analyzed using NMR, tracking the vinyl peaks of the unreacted crosslinkers (FIG. 16). As expected from our kinetic studies, polymer nanocomposites of permanent structures can be printed using this resin system with fast assembly kinetics (FIG. 7B, FIG. 22, FIG. 23). The gel composition was characterized by FTIR spectroscopy (FIG. 17). This characterization was carried out to confirm that the resulting material contains both PNIPAM and PEGDMA. The presence of peaks corresponding to NH stretching and NH bending at 3300 and 1540 cm-1 indicates the presence of PNIPAM in the material, while the presence of a peak at 1240 cm-1 corresponding to C—O stretching suggests the presence of PEGDMA. The molecular weight of PNIPAM is essential when designing a resin system using this platform. First, the molecular weight of PNIPAM influences nanoparticle stability during chemical crosslinking. It has been shown that polymers can sterically stabilize nanoparticles in solution.⁴² When the crosslinking is performed in the presence of low molecular weight PNIPAMs (11 kg/mol), the LSPR peak of AuNRs blue shifts to 600 nm, and its intensity decreases below the TSPR peak, potentially from particle aggregation, plasmon coupling, or deformation (FIG. 18).⁵³⁻⁵⁵ Using a higher molecular weight PNIPAM (126 kg/mol), the shift in UV-Vis-NIR spectrum was minimal. Additionally, thermal properties such as the glass transition temperature (T_{g}) remain largely unchanged after printing in the PNIPAM polymer, which can be attributed to the relatively low crosslinking density of the final material (FIG. 19).

### CONCLUSIONS

Photothermally induced self-assembly can be harnessed for NIR-activated microlithography of polymer nanocomposites by combining thermally responsive polymers with thermoplasmonic nanoparticles that generate localized heat upon irradiation with NIR light. Several key variables, including polymer composition, molecular weight, interfacial interactions, and pH, are used to tailor the reversible assembly behavior of these systems. The addition of a small amount of crosslinkers leads to irreversible self-assembly, locking the structure after phase separation. This proof-of-concept demonstration of self-assembly driven microlithography using thermoplasmonic nanoparticles lay the groundwork for photopatterning strategies that circumvent key drawbacks of most photocurable resin systems with deeply penetrating NIR light, thereby broadening the toolkit for photopatterning polymer nanocomposites under mild conditions and highlighting its potential for VP using non-conventional wavelengths and multicomponent architectures. This platform is well-suited for diverse applications, including soft actuators, sensors, in vivo bioprinting, and multi-material 3D printing.

### Experimental Section

### Materials

N-Isopropylacrylamide (NIPAM, Tokyo Chemical Industry, 98%), N,N-dimethylacrylamide (DMA, Sigma Aldrich, 99%), butyl acrylate (BA, Sigma Aldrich, 99%), Poly (ethylene glycol) dimethacrylate 550 g mol⁻¹ (PEGDMA, Sigma Aldrich), diphenyl(2,4,6-trimethylbenzoyl)phosphine oxide (TPO, Tokyo Chemical Industry, 98%), ethanol anhydrous (Fisher Scientific, 99.5%), diethyl ether (Fisher Scientific, 99%), gold (III) chloride trihydrate (Sigma Aldrich, 99.9%), hexadecyltrimethylammonium bromide (CTAB, Fisher Scientific, 99%), sodium borohydride (Sigma Aldrich, 98%), L-ascorbic acid (Sigma Aldrich, 99%), 11-mercaptoundecanoic acid (MUA, Fisher Scientific, 97%), 1-dodecanethiol (DDT, Fisher Scientific, 98%), 3-mercaptopropionic acid (MPA, Sigma Aldrich, 99%), cysteamine hydrochloride (Sigma Aldrich, 98%), chloroform (Sigma Aldrich, 99.8%), deuterium chloroform (Sigma Aldrich), deuterium oxide (Sigma Aldrich), carbon disulfide (≥99.9%, Sigma Aldrich), 1-butanethiol (99%, Sigma Aldrich), 2-bromopropionic acid (99%, Sigma Aldrich), sodium hydroxide (anhydrous, ≥98%, Sigma Aldrich), hydrochloric acid (37% aqueous, 12 M, Sigma Aldrich) are used as received. 2-(n-butyltrithio-carbonate) propionic acid (BTPA) is synthesized following the method reported in the literature.⁵⁶ The thermal camera used to measure the solution temperature is Thermal Imaging Camera 256 by 192 IR Resolution Pocket Infrared Thermal Imager with WiFi, 25 Hz Refresh Rate Thermal from Home Depot. A laser diode (808 nm Collimated Diode Laser System) used for all photo-measurements in this study was purchased from Artkis Laser. The laser power was calibrated using an optical power meter (PM400, Thorlabs) equipped with a thermal sensor.

### Synthesis of Poly N-Isopropylacrylamide and its Copolymers

Poly(N-isopropylacrylamide) (PNIPAM) was synthesized via photoinduced electron/energy transfer-reversible addition-fragmentation chain transfer (PET-RAFT) polymerization, using NIPAM as the monomer, BTPA as the chain transfer agent, and TPO as the photoinitiator. Prior to polymerization, the NIPAM monomer was passed through a column of basic alumina to remove inhibitors. The amounts used depend on the desired molecular weight of the polymer. For example, to obtain a polymer with a molecular weight of 100 kg/mol, a molar ratio of NIPAM to BTPA of 884:1 is used. In a typical synthesis, a mixture containing 10 ml of NIPAM (5 M), 4.49 mL of BTPA (12.6 mM), and 0.283 mL of TPO (20 mM) in ethanol was prepared. The solution was degassed under nitrogen for 10 min and subsequently irradiated under UV light for 2 h under ambient condition (i.e., room temperature with no external temperature control). The UV light used for PET-RAFT polymerization had a wavelength of 365 nm and a power density of 1.3 mW cm-2. After polymerization, the reaction mixture was precipitated in diethyl ether to isolate PNIPAM and remove residual reagents. In the case of PNIPAM-based copolymers, the other monomers are added according to the desired composition. The resulting polymers were characterized by nuclear magnetic resonance (NMR) spectroscopy (Bruker 500 MHz) and size exclusion chromatography (SEC).

### ¹H NMR Analysis of Polymers

Proton nuclear magnetic resonance (¹H NMR) spectra were acquired to characterize the chemical structure of the polymer samples. For each measurement, 50 μl of the sample was collected and diluted in 500 μl of deuterated chloroform (CDCl₃). The mixture was transferred to a 5-mm NMR tube and homogenized to ensure complete dissolution of the components. All spectra were recorded on a Bruker 500 MHz NMR spectrometer operating at room temperature.

### Size Exclusion Chromatography (SEC)

The Tosoh HLC-8420 GPC system and the LenS3 multi-angle light scattering detector are used to characterize the average molecular weight and its molecular weight distribution (dispersity) of the purified PDMA. A solution of 10 mM lithium bromide in dimethyl formamide is the mobile phase. The data is acquired by EcoSEC Elite and SECView software. The samples are run at a flow rate of 1.0 ml/min, with the system temperature set to 40 °C.

### Synthesis of Gold Nanorods/Nanospheres

The synthesis proceeded using a seed-mediated growth procedure reported in the literature.⁵⁷ For the seeds, 0.25 ml of HAuCl₄ (0.01 M) was mixed with 9.75 ml of CTAB (0.1 M). 0.6 mL of ice-cold and fresh NaBH₄ (0.01 M) was quickly added. After 10 min of vigorous stirring, the solution was allowed to age unstirred at 25 °C for 1.5 h. For the growth solution, 0.5 mL of HAuCl₄ (0.01 M) and 8.0 ml of CTAB (0.1 M) were mixed. 30 μL of AgNO₃ (0.01 M) was added to the growth solutions for aspect ratios of two, and 100 μl for aspect ratios of four. 0.2 mL of HCl (1 M), 80 μl of ascorbic acid (0.1 M), and 2.0 ml of the seed solution were added in that order. Finally, the solutions were left unstirred for 16 h at room temperature and purified via centrifugation at 10,000 rpm for 30 min. For the synthesis of nanospheres, the same procedure was followed, without the addition of AgNO₃.

### Transmission Electron Microscopy Characterization of AuNR

TEM samples were prepared by depositing 10 μl of a 1 nM AuNR suspension onto Lacey Formvar/carbon-coated copper grids (200 mesh, hole size 97 μm). The suspension was applied to the grid using a micropipette and allowed to air-dry for 10 min at room temperature. This deposition—drying cycle was repeated three times to increase particle density on the grid. After the final application, the grids were allowed to dry overnight under vacuum to ensure complete removal of residual solvent. TEM imaging was performed using a Philips CM200 transmission electron microscope operated at an accelerating voltage of 200 kV.

### UV-Vis-NIR Spectroscopy and Estimation of AuNR Concentrations

The concentration of AuNRs in aqueous suspension was determined using the Beer-Lambert law, based on the molar extinction coefficients reported by Orendorff and Murphy.² In that work, the extinction coefficient (a) associated with the longitudinal surface plasmon resonance (LSPR) band was experimentally determined for AuNRs with different aspect ratios and corresponding plasmon peak wavelengths (ALSPR). For each sample, the ALSPR was obtained from the UV-Vis-NIR absorption spectrum, and the corresponding e value was estimated by linear interpolation between the tabulated data. The absorbance (A) at ALSPR was then used to calculate the molar concentration (c) of nanorods according to the Beer-Lambert equation:

A=εcl

where A is the measured absorbance, ε is the molar extinction coefficient (M⁻¹ cm⁻¹), l is the optical path length (1 cm), and c is the molar concentration (M). Additionally, the molar concentration can be converted to weight percent (wt. %) by estimating the mass of a single nanorod from its geometric dimensions, as determined by transmission electron microscopy (TEM). Assuming a cylindrical shape with hemispherical ends, the nanorod volume (V_{NR}) can be approximated as:

$${V}_{NR} = π {r}^{2} L + \frac{4}{3} π {r}^{3}$$

where r and L correspond to the nanorod radius and cylindrical length, respectively. The total gold mass per nanorod was then calculated using the density of bulk gold (19.3 g cm⁻³) and multiplied by the particle concentration. The resulting mass of gold per volume of solution was finally expressed as weight percent relative to the total dispersion.

### Preparation of Polymer Nanocomposite Solutions

Polymer nanocomposites were prepared in solution by dissolving both the polymer of interest and the AuNRs, ensuring that the AuNR concentration was defined relative to the polymer content. Starting from a 10 wt./v % polymer solution in water (100 mg mL-1), a concentrated AuNR dispersion was added to reach a final AuNR concentration of 0.02 wt. %, corresponding to 0.02 mg of gold per mL. The total surface area of AuNRs was estimated from their TEM-derived geometric dimensions, and the desired ligand (cysteamine or 3-mercaptopropionic acid) was added to achieve a surface density coverage of 4.7 ligands nm-2. For hydrophobic ligands such as MUA and DDT, which are not water-soluble, two additional steps were required. First, the polymer-AuNR mixtures were dried, redissolved in chloroform, and functionalized with MUA or DDT to reach the same surface coverage. Then, the samples were dried again and redispersed in water. To avoid partially unfunctionalized AuNR surfaces, a 20-fold excess of ligand relative to the minimum required amount was used, and the excess ligand was removed by contacting the aqueous phase with hexane.

pH Control

Low pH solutions were achieved by adding drops of 1 M hydrochloric acid solution to reach 0.01 M hydrochloric acid (pH=2). The measurements for neutral pH were performed as the components are combined (i.e., no pH adjustment, pH=6-7). Solution pHs were quantified using pH paper and pH meter.

### Dynamic Light Scattering

A Malvern Zetasizer Pro was used to characterize the size distribution, via dynamic light scattering, and zeta potential of gold nanoparticles. CTAB-stabilized gold nanoparticles were washed three times and redispersed in fresh Milli-Q water before measurement. Initial measurements were performed at neutral pH, after which the pH was adjusted to 2 using a 0.2 M hydrochloric acid solution and pH paper.

### Photothermal Conversion Experiments

Near-infrared (NIR) irradiation experiments were performed using a laser diode (808 nm Collimated Diode Laser System, Artkis Laser) to evaluate the photothermal conversion of composite solutions containing 10 wt./v % PNIPAM and varying concentrations of AuNR4. The laser beam was directed at the stationary samples at various power intensities, maintaining a fixed distance of 1 cm between the laser source and the resin surface. The laser power was calibrated prior to the experiments using an optical power meter (PM400, Thorlabs) equipped with a thermal sensor. At a distance of 1 cm between the laser tip and the resin surface, the laser spot area was approximately 0.2 cm². For photothermal conversion measurements, the samples were irradiated for 5 min, during which the temperature increase was monitored using a thermal camera. After turning off the laser, the cooling profile was recorded for an additional 5 min to assess thermal dissipation.

### Turbidity Tests

The phase transition behavior of the polymer solutions was analyzed by monitoring turbidity using a UV-Vis spectrophotometer equipped with a temperature-controlled heating system (Cary 3500 Multicell UV-Vis spectrophotometer, Agilent Technologies, Inc., CA, USA). A single polymer concentration of 5 wt./v % was tested. Measurements were performed at a fixed wavelength of 400 nm to minimize the contribution of gold nanoparticles to the overall absorbance of the composite solutions. Various heating rates, ranging from 0.5 C/min to 5 C/min, were applied. Milli-Q water was used as the reference in all transmittance measurements.

### Rheology Tests

The rheological behavior of the polymer solutions was characterized using a rheometer (Discovery Hybrid Rheometer HR30, TA Instruments) equipped with a 20 mm parallel plate geometry. To determine the linear viscoelastic region (LVR), amplitude sweeps were performed over a strain range of 0.01% to 100% at a constant frequency of 1 Hz. Temperature sweeps were conducted at a fixed strain of 0.1% and a frequency of 1 Hz. Frequency sweeps were performed above the gelation temperature (50 °C) at a fixed strain of 0.1%.

### Stereolithography Using NIR Light

To prepare 1 ml of resin, 100 mg of PNIPAM with a molecular weight of 126 kDa were first combined with water. A concentrated solution of AuNR was then added. To this solution, MPA was added for functionalization (see Preparation of Polymer Nanocomposite Solution section for more details). Following this step, 90 μL of PEGDMA, 20 μL of potassium persulfate (0.04 M), and 20 μL of ascorbic acid (0.1 M) were added to the mixture. Ascorbic acid is added to lower the activation temperature of potassium persulfate.⁵⁸ Finally, the pH was adjusted to 2 using a few drops of 1 M hydrochloric acid, and water was added to reach a total volume of 1 mL. The final concentrations of components in the resin were 10 wt./v % PNIPAM, 0.002 wt./v % AuNR, 10 wt./v % PEGDMA, 0.021 wt./v % potassium persulfate, and 0.035 wt./v % ascorbic acid. The regions for printing exhibited a temperature of approximately 50 °C using the laser at high power (300 mW), measured by a thermal camera. The spot size is approximately 0.2 cm². Each region scanned by the beam was exposed manually for about 5 S.

### ABBREVIATIONS

NIPAM, N-isopropylacrylamide; CTAB, cetrimonium bromide; BA, butyl acrylate; DMA, N, N-dimethylacrylamide; BTPA, 2-(n-butyltrithiocarbonate) propionic acid; TPO, diphenyl(2,4,6-trimethylbenzoyl)phosphine oxide; DDT, dodecanethiol; MPA, 3-mercaptopropionic acid; MUA, 11-mercaptoundecanoic acid; AuNR, gold nanorods with an aspect ratio of 4.

### REFERENCES

1. Jung, K.; Corrigan, N.; Ciftci, M.; Xu, J.; Seo, S. E.; Hawker, C. J.; Boyer, C. Designing with Light: Advanced 2D, 3D, and 4D Materials. Adv. Mater. 2020, 32 (18), 1903850.
2. Imrie, P.; Jin, J. Harnessing Near-Infrared Light for Advanced 3D Printing. RSC Appl. Polym. 2025, 3, 793-810.
3. Bagheri, A.; Jin, J. Photopolymerization in 3D Printing. ACS Appl. Polym. Mater. 2019, 1 (4), 593-611.
4. Seo, S. E.; Kwon, Y.; Dolinski, N. D.; Sample, C. S.; Self, J. L.; Bates, C. M.; Valentine, M. T.; Hawker, C. J. Three-Dimensional Photochemical Printing of Thermally Activated Polymer Foams. ACS Appl. Polym. Mater. 2021, 3 (10), 4984-4991.
5. Gonzalez Calvo, T.; Hawkins, K. D.; Seo, S. E. Rapid, Visible Light-Controlled Cationic Polymerization of Vinyl Ethers for 3D Printing of Chemically Reprocessable Networks under Ambient Conditions. J. Polym. Sci. 2024, 62 (12), 2630-2638.
6. Futscher, M. H.; Philipp, M.; Müller-Buschbaum, P.; Schulte, A. The Role of Backbone Hydration of Poly(N-Isopropyl Acrylamide) Across the Volume Phase Transition Compared to Its Monomer. Sci. Rep. 2017, 7 (1), 17012.
7. Mohan, A.; Santhamoorthy, M.; Phan, T. T. V.; Kim, S.-C. pNIPAm-Based pH and Thermoresponsive Copolymer Hydrogel for Hydrophobic and Hydrophilic Drug Delivery. Gels 2024, 10 (3), 184.
8. Li, Z.; Sun, D.; Yang, J.; Shang, S.; Wang, L.; Li, H.; Zhang, H.; Wang, R.; Lan, H.; Zhu, X. 3D Printed Heterogeneous Bilayer Temperature-Responsive Hydrogel with Multi-Curvature Deformation. Polymer 2024, 296, 126701.
9. Wu, K.; Hu, Y.; Feng, H. Investigation of 3D-Printed PNIPAM-Based Constructs for Tissue Engineering Applications: A Review. J. Mater. Sci. 2023, 58 (47), 17727-17750.
10. Yamamoto, Y.; Kanao, K.; Arie, T.; Akita, S.; Takei, K. Air Ambient-Operated pNIPAM-Based Flexible Actuators Stimulated by Human Body Temperature and Sunlight. ACS Appl. Mater. Interfaces 2015, 7 (20), 11002-11006.
11. Guan, Z.; Katla, S. K.; Dahanayake, V.; Bae, J. 3D Printable Poly(N-Isopropylacrylamide) Microgel Suspensions with Temperature-Dependent Rheological Responses. ACS Appl. Polym. Mater. 2024, 6 (23), 14095-14105.
12. Ji, D.; Liu, J.; Zhao, J.; Li, M.; Rho, Y.; Shin, H.; Han, T. H.; Bae, J. Sustainable 3D Printing by Reversible Salting-out Effects with Aqueous Salt Solutions. Nat. Commun. 2024, 15 (1), 3925.
13. Kailash; Verma, S. S. Quantifying the Optical and Thermoplasmonic Properties of Some Bimetallic Alloy Nanospheres. J. Quant. Spectrosc. Radiat. Transf. 2023, 309, 108707.
14. Sun, Y.; Xia, Y. Gold and Silver Nanoparticles: A Class of Chromophores with Colors Tunable in the Range from 400 to 750 nm. Analyst 2003, 128, 686-691.
15. Sukmanee, T.; Szuster, M.; Gorski, A.; Hołdyński, M.; Gawinkowski, S. Tunable-Wavelength Nanosecond Laser Tailoring of Plasmon Resonance Spectra of Gold Nanoparticle Colloids. Nanoscale Adv. 2023, 5 (14), 3697-3704.
16. Ameer, F. S.; Varahagiri, S.; Benza, D. W.; Willett, D. R.; Wen, Y.; Wang, F.; Chumanov, G.; Anker, J. N. Tuning Localized Surface Plasmon Resonance Wavelengths of Silver Nanoparticles by Mechanical Deformation. J. Phys. Chem. C Nanomater. Interfaces 2016, 120 (37), 20886-20895.
17. Chen, Y.-S.; Frey, W.; Kim, S.; Kruizinga, P.; Homan, K.; Emelianov, S. Silica-Coated Gold Nanorods as Photoacoustic Signal Nano-Amplifiers. Nano Lett. 2011, 11 (2), 348-354.
18. Ruhoff, V. T.; Arastoo, M. R.; Moreno-Pescador, G.; Bendix, P. M. Biological Applications of Thermoplasmonics. Nano Lett. 2024, 24 (3), 777-789.
19. Virk, M.; Xiong, K.; Svedendahl, M.; Kall, M.; Dahlin, A. B. A Thermal Plasmonic Sensor Platform: Resistive Heating of Nanohole Arrays. Nano Lett. 2014, 14 (6), 3544-3549.
20. Chehadi, Z.; Girardon, J.-S.; Capron, M.; Dumeignil, F.; Jradi, S. Thermoplasmonic-Induced Energy-Efficient Catalytic Oxidation of Glycerol over Gold Supported Catalysts Using Visible Light at Ambient Temperature. Appl. Catal. Gen. 2019, 572, 9-14.
21. Powell, A. W.; Stavrinadis, A.; de Miguel, I.; Konstantatos, G.; Quidant, R. White and Brightly Colored 3D Printing Based on Resonant Photothermal Sensitizers. Nano Lett. 2018, 18 (11), 6660-6664.
22. Baffou, G.; Quidant, R. Thermo-Plasmonics: Using Metallic Nanostructures as Nano-Sources of Heat. Laser Photonics Rev. 2013, 7 (2), 171-187.
23. Lee, C.-U.; Chin, K. C. H.; Boydston, A. J. Additive Manufacturing by Heating at a Patterned Photothermal Interface. ACS Appl. Mater. Interfaces 2023, 15 (12), 16072-16078.
24. Kam, D.; Rulf, O.; Reisinger, A.; Lieberman, R.; Magdassi, S. 3D Printing by Stereolithography Using Thermal Initiators. Nat. Commun. 2024, 15, 2285.
25. Schwartz, J. J.; Additive Manufacturing: Frameworks for Chemical Understanding and Advancement in Vat Photopolymerization. MRS Bull. 2022, 47, 628-641.
26. Fortenbaugh, R. J.; Lear, B. J. On-Demand Curing of Polydimethylsiloxane (PDMS) Using the Photothermal Effect of Gold Nanoparticles. Nanoscale 2017, 9 (25), 8555-8559.
27. Zhu, J.; Zhang, Q.; Yang, T.; Liu, Y.; Liu, R. 3D Printing of Multi-Scalable Structures via High Penetration near-Infrared Photopolymerization. Nat. Commun. 2020, 11 (1), 3462.
28. Mackey, M. A.; Ali, M. R. K.; Austin, L. A.; Near, R. D.; El-Sayed, M. A. The Most Effective Gold Nanorod Size for Plasmonic Photothermal Therapy: Theory and In Vitro Experiments. J. Phys. Chem. B. 2014, 118, 1319-1326.
29. Jain, P.; Huang, X.; El-Sayed, I.; El-Sayed, M. Review of Some interesting Surface Plasmon Resonance-enhanced Properties of Noble Metal Nanoparticles and Their Applications to Biosystems. Plasmonics 2007, 2, 107-118.
30. Scarabelli, L.; Sánchez-Iglesias, A.; Pérez-Juste, J.; Liz-Marzan, L. M. A “Tips and Tricks” Practical Guide to the Synthesis of Gold Nanorods. J. Phys. Chem. Lett. 2015, 6 (21), 4270-4279.
31. Su, W.; Yang, M.; Zhao, K.; Ngai, T. Influence of Charged Groups on the Structure of Microgel and Volume Phase Transition by Dielectric Analysis. Macromolecules 2016, 49 (20), 7997-8008.
32. Pasparakis, G.; Tsitsilianis, C. LCST Polymers: Thermoresponsive Nanostructured Assemblies towards Bioapplications. Polymer 2020, 211, 123146.
33. Raghuwanshi, V. S.; Joram Mendoza, D.; Browne, C.; Ayurini, M.; Gervinskas, G.; Hooper, J. F.; Mata, J.; Wu, C.-M.; Simon, G. P.; Garnier, G. Effect of Temperature on the Conformation and Functionality of Poly(N-Isopropylacrylamide) (PNIPAM)-Grafted Nanocellulose Hydrogels. J. Colloid Interface Sci. 2023, 652, 1609-1619.
34. Gao, Y.; Yang, J.; Ding, Y.; Ye, X. Effect of Urea on Phase Transition of Poly(N-Isopropylacrylamide) Investigated by Differential Scanning calorimetry. J. Phys. Chem. B 2014, 118 (31), 9460-9466.
35. Minami, S.; Watanabe, T.; Suzuki, D.; Urayama, K. Rheological Properties of Suspensions of Thermo-Responsive Poly(N-Isopropylacrylamide) Microgels Undergoing Volume Phase Transition. Polym. J. 2016, 48 (11), 1079-1086.
36. Voudouris, P.; Florea, D.; Schoot, P. van der; Wyss, H. M. Micromechanics of Temperature Sensitive Microgels: Dip in the Poisson Ratio near the LCST. Soft Matter 2013, 9 (29), 7158-7166.
37. Grau-Carbonell, A.; Hagemans, F.; Bransen, M.; Elbers, N. A.; van Dijk-Moes, R. J. A.; Sadighikia, S.; Welling, T. A. J.; van Blaaderen, A.; van Huis, M. A. In Situ Single Particle Characterization of the Themoresponsive and Co-Nonsolvent Behavior of PNIPAM Microgels and silica@PNIPAM Core-Shell Colloids. J. Colloid Interface Sci. 2023, 635, 552-561.
38. Pawlak, A.; Krajenta, J. Entanglements of Macromolecules and Their Influence on Rheological and Mechanical Properties of Polymers. Molecules 2024, 29 (14), 3410.
39. Orlishausen, M.; Kohler, W. Forced Phase Separation by Laser-Heated Gold Nanoparticles in Thermoresponsive Aqueous PNIPAM Polymer Solutions. J. Phys. Chem. B 2015, 119 (25), 8217-8222.
40. Aibara, I.; Chikazawa, J.; Uwada, T.; Hashimoto, S. Localized Phase Separation of Thermoresponsive Polymers Induced by Plasmonic Heating. J. Phys. Chem. C 2017, 121 (40), 22496-22507.
41. Aibara, I.; Mukai, S.; Hashimoto, S. Plasmonic-Heating-Induced Nanoscale Phase Separation of Free Poly(N-Isopropylacrylamide) Molecules. J. Phys. Chem. C 2016, 120 (31), 17745-17752.
42. Shrestha, S.; Hag, L. van't; Haritos, V.; Dhital, S. Rheological and Textural Properties of Heat-Induced Gels from Pulse Protein Isolates: Lentil, Mungbean and Yellow Pea. Food Hydrocoll. 2023, 143, 108904.
43. Biswas, C. S.; Wu, Y.; Wang, Q.; Du, L.; Mitra, K.; Ray, B.; Yan, Z.-C.; Du, B.; Stadler, F. J. Effect of Tacticity and Molecular Weight on the Rheological Properties of Poly(N-Isopropylacrylamide) Gels in Benzyl Alcohol. J. Rheol. 2017, 61 (6), 1345-1357.
44. Chuang, Y.-C.; Chang, Y.-C.; Tsai, M.-T.; Yang, T.-W.; Huang, M.-T.; Wu, S.-H.; Wang, C. Electrospinning of Aqueous Solutions of Atactic Poly(N-Isopropylacrylamide) with Physical Gelation. Gels 2022, 8 (11), 716.
45. Wang, C.; Hashimoto, T.; Chuang, Y.-C.; Tanaka, K.; Chang, Y.-P.; Yang, T.-W.; Huang, M.-T. Physical Gelation of Aqueous Solutions of Atactic Poly(N-Isopropylacrylamide). Macromolecules 2022, 55 (20), 9152-9167.
46. Yu, J.-C.; Browne, R. A.; Seo, S. E. Mechanically Robust, Self-Healing Polymer Nanocomposites with Tailorable Nanoparticle-Based Bonds. Macromolecules 2024, 57 (19), 9059-9066.
47. Denmark, D. J.; Bradley, J.; Mukherjee, D.; Alonso, J.; Shakespeare, S.; Bernal, N.; Phan, M. H.; Srikanth, H.; Witanachchi, S.; Mukherjee, P. Remote Triggering of Thermoresponsive PNIPAM by Iron Oxide Nanoparticles. RSC Adv. 2016, 6 (7), 5641-5652.
48. Shambetova, N.; Chen, Y.; Xu, H.; Li, L.; Solandt, J.; Zhou, Y.; Wang, J.; Su, H.; Brismar, H.; Fu, Y. Acid Dissociation of 3-Mercaptopropionic Acid Coated CdSe—CdS/Cd0.5Zn0.5S/ZnS Core—Multishell Quantum Dot and Strong lonic Interaction with Ca2+ Ion. J. Phys. Chem. C 2016, 120 (6), 3519-3529.
49. Ansar, S. M.; Chakraborty, S.; Kitchens, C. L. pH-Responsive Mercaptoundecanoic Acid Functionalized Gold Nanoparticles and Applications in Catalysis. Nanomaterials 2018, 8 (5), 339.
50. Torii, Y.; Sugimura, N.; Mitomo, H.; Niikura, K.; ljiro, K. pH-Responsive Coassembly of Oligo (Ethylene Glycol)-Coated Gold Nanoparticles with External Anionic Polymers via Hydrogen Bonding. Langmuir 2017, 33 (22), 5537-5544.
51. Nayak, S.; Horst, N.; Zhang, H.; Wang, W.; Mallapragada, S.; Travesset, A.; Vaknin, D. Interpolymer Complexation as a Strategy for Nanoparticle Assembly and Crystallization. J. Phys. Chem. C 2019, 123 (1), 836-840.
52. Bogen, M. P.; Swofford, W. M.; Chittari, S. S.; Knight, A. S. Structure-Function Relationships in Sequence-Controlled Copolymers for Rare Earth Element Chelation. J. Am. Chem. Soc. 2025, 147 (34), 30885-30896.
53. Pratap, D.; Vikas; Gautam, R.; Shaw, A. K.; Soni, S. Photothermal Properties of Stable Aggregates of Gold Nanorods. Colloids Surf. Physicochem. Eng. Asp. 2022, 635, 128054.
54. Kumar, J.; Wei, X.; Barrow, S.; Funston, A. M.; Thomas, K. G.; Mulvaney, P. Surface Plasmon Coupling in End-to-End Linked Gold Nanorod Dimers and Trimers. Phys. Chem. Chem. Phys. 2013, 15 (12), 4258-4264.
55. Uusitalo, M.; Strach, M.; Eriksson, G.; Dmytrenko, T.; Andersson, J.; Dahlin, A.; Hulander, M.; Andersson, M. Photothermal Properties of Solid-Supported Gold Nanorods. Nano Lett. 2024, 24 (40), 12529-12535
56. Ferguson, C. J.; Hughes, R. J.; Nguyen, D.; Pham, B. T. T.; Gilbert, R. G.; Serelis, A. K.; Such, C. H. Hawkett, B. S. Ab Intro Emulsion Polymerization by RAFT-Controlled Self-Assembly. Macromolecules 2005, 38, 2191-2204.
57. Chang, H.; Murphy, C. J. Mini Gold Nanorods with Tunable Plasmonic Peaks Beyond 1000 nm. Chem. Mater. 2018, 30, 1427-1435.
58. Nagaraja, G. K.; Demappa, T.; Mahadevaiah, D. Polymerization Kinetics of Acrylonitrile by Oxidation: Reduction System Using Potassium Persulfate/Ascorbic Acid in Aqueous Medium. J. Appl. Polym. Sci. 2011, 121, 1299-1303.

### Example 4

### General Procedure for Synthesis of NIPAM-Based Thermoresponsive Polymers

Thermoresponsive copolymers can be synthesized via photoinduced electron/energy transfer-reversible addition-fragmentation chain transfer (PET-RAFT) polymerization. In a typical procedure, one thermoresponsive vinyl monomer is copolymerized with one or more hydrophilic or hydrophobic comonomers in the presence of a RAFT chain transfer agent and a suitable photoinitiator. Prior to polymerization, monomers may be purified, for example by passing through a column of basic alumina, to remove inhibitors. The monomers are dissolved in a suitable solvent, such as alcohols, or another organic solvent system, together with the chain transfer agent and photoinitiator. The relative molar ratios of monomers and chain transfer agents may be adjusted to control the molecular weight and composition of the resulting copolymer. In some embodiments, the fraction of comonomer may vary depending on the desired material properties, such as cloud point temperature (T_{cp}) and glass transition temperature (T_{g}). More hydrophobic monomers decrease the T_{cp} (33 °C for pure PNIPAM), whereas more hydrophilic monomers increase it. Regarding the T_{g}, which determines the properties of the solid polymer, the Fox equation can be used to estimate how the incorporation of other monomers modifies the T_{g} of pure PNIPAM (135 °C). When hydrophobic comonomers are incorporated, their proportion can be limited to maintain aqueous solubility of the resulting copolymer. The reaction mixture is typically degassed using an inert gas (e.g., nitrogen) to remove dissolved oxygen and subsequently irradiated with ultraviolet or visible light to initiate polymerization. Irradiation wavelengths in the range of approximately 300-530 nm may be used depending on the photoinitiator. Polymerization may be conducted at ambient temperature or under controlled temperature conditions for a period ranging from minutes to several hours. Following polymerization, the copolymer may be isolated by precipitation in a non-solvent or other purification methods to remove unreacted monomers and small molecules. The resulting polymers may be characterized using standard techniques such as nuclear magnetic resonance (NMR) spectroscopy, size exclusion chromatography (SEC), differential scanning calorimetry (DSC), among others.

### Example Synthesis Procedures: Poly (N-Isopropylacrylamide)

Poly(N-isopropylacrylamide) (PNIPAM) was synthesized via photoinduced electron/energy transfer-reversible addition-fragmentation chain transfer (PET-RAFT) polymerization, using NIPAM as the monomer, BTPA as the chain transfer agent, and TPO as the photoinitiator. Prior to polymerization, the NIPAM monomer was passed through a column of basic alumina to remove inhibitors. The amounts used depend on the desired molecular weight of the polymer. For example, to obtain a polymer with a molecular weight of 100 kg/mol, a molar ratio of NIPAM to BTPA of 884:1 is used. In a typical synthesis, a mixture containing 10 mL of NIPAM (5 M), 4.49 mL of BTPA (12.6 mM), and 0.283 mL of TPO (20 mM) in ethanol was prepared. The solution was degassed under nitrogen for 10 min and subsequently irradiated under UV light for 2 h under ambient condition (i.e., room temperature with no external temperature control). The UV light used for PET-RAFT polymerization had a wavelength of 365 nm and a power density of 1.3 mW cm-2. After polymerization, the reaction mixture was precipitated in diethyl ether to isolate PNIPAM and remove residual reagents. The resulting polymers were characterized by nuclear magnetic resonance (NMR) spectroscopy (Bruker 500 MHz) and size exclusion chromatography (SEC). An exemplary synthesis of PNIPAM is shown in Scheme 1.

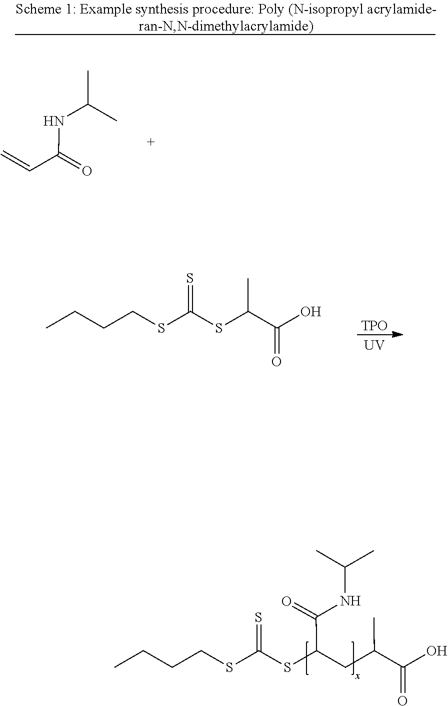

Poly (N-isopropylacrylamide-ran-N,N dimethylacrylamide) was synthesized via photoinduced electron/energy transfer-reversible addition-fragmentation chain transfer (PET-RAFT) polymerization, using NIPAM and N,N dimethylacrylamide as the monomers, BTPA as the chain transfer agent, and TPO as the photoinitiator. Prior to polymerization, both NIPAM and N,N-dimethylacrylamide monomers were passed through a column of basic alumina to remove inhibitors. The amounts used depend on the desired molecular weight and composition of the copolymer. For example, to obtain a copolymer with a molecular weight around 100 kg/mol and a mole content of 10 mol % of N,N-dimethylacrylamide, a molar ratio of NIPAM to N,N-dimethyl acrylamide to BTPA of 805:90:1 is used. In a typical synthesis, a mixture containing 10 mL of NIPAM (5 M), 0.576 mL of N,N-dimethylacrylamide, 4.93 ml of BTPA (12.6 mM), and 0.31 mL of TPO (20 mM) in ethanol was prepared. The solution was degassed under nitrogen for 10 min and subsequently irradiated under UV light for 2 h under ambient condition (i.e., room temperature with no external temperature control). The UV light used for PET-RAFT polymerization had a wavelength of 365 nm and a power density of 1.3 mW cm-2. After polymerization, the reaction mixture was precipitated in diethyl ether to isolate the copolymer and remove residual reagents. The resulting polymers were characterized by nuclear magnetic resonance (NMR) spectroscopy (Bruker 500 MHz) and size exclusion chromatography (SEC). Scheme 2 shows exemplary reaction mechanism.

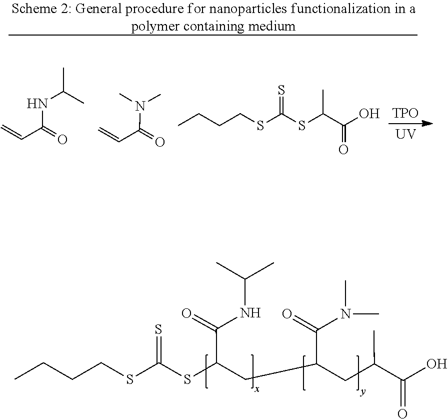

Nanoparticles can be functionalized by dispersing a polymeric matrix and metallic nanoparticles in a suitable solvent to obtain a homogeneous dispersion. In some embodiments, the polymer concentration may range from about 1 to about 20 wt./v % in a solvent such as water, or another compatible medium where LCST behavior is observed. The surface area of the nanoparticles may be estimated from geometric dimensions obtained from microscopy or other characterization methods, and a surface-active ligand may be added in an amount sufficient to provide a complete surface coverage of the nanoparticles. In some embodiments, the ligand may be selected from thiol-containing molecules or other surface-binding species capable of interacting with the nanoparticle surface. The ligand may be added in an amount corresponding to a predetermined surface coverage, using an excess of ligand relative to the theoretical surface coverage required to ensure substantially complete functionalization of the nanoparticle surface. For ligands that are not soluble in the initial solvent system, the polymer-nanoparticle mixture may be dried and subsequently redissolved in an alternative solvent compatible with the ligand. Ligand functionalization may then be carried out in the alternative solvent, followed by removal of the solvent and redispersion of the functionalized nanocomposite in a desired medium. Excess ligand may be removed using purification techniques such as solvent extraction, dialysis, or combinations thereof

### Example Synthesis Procedure: Functionalized Gold Nanorods

Polymer nanocomposites were prepared in solution by dissolving both the polymer of interest and the AuNRs, ensuring that the AuNR concentration was defined relative to the polymer content. Starting from a 10 wt./v % polymer solution in water (100 mg mL-1), a concentrated AuNR dispersion was added to reach a final AuNR concentration of 0.02 wt. %, corresponding to 0.02 mg of gold per mL. The total surface area of AuNRs was estimated from their TEM-derived geometric dimensions, and the desired ligand (cysteamine or 3-mercaptopropionic acid) was added to achieve a surface density coverage of 4.7 ligands nm-2. For hydrophobic ligands such as MUA and DDT, which are not water-soluble, two additional steps were required. First, the polymer-AuNR mixtures were dried, redissolved in chloroform, and functionalized with MUA or DDT to reach the same surface coverage. Then, the samples were dried again and redispersed in water. To avoid partially unfunctionalized AuNR surfaces, a 20-fold excess of ligand relative to the minimum required amount was used, and the excess ligand was removed by contacting the aqueous phase with hexane.

### Exemplary Photothermal Particles

For this project, gold nanoparticles with different geometries (spheres and nanorods with different aspect ratios) were initially considered. Gold nanospheres make the system operatives using green light (λ=530 nm), while gold nanorods are highly customizable (λ=from 530 to >1000 nm). However, without wishing to be bound by theory, the system can be compatible with other nanoparticles that are stable in aqueous media (or another solvent where LCST behavior of the polymer is observed) and whose surface functionalization chemistry does not compromise that stability.

### EQUIVALENTS

Those skilled in the art will recognize, or be able to ascertain, using no more than routine experimentation, numerous equivalents to the specific substances and procedures described herein. Such equivalents are considered to be within the scope of this invention and are covered by the following claims.

We claim:

1. A self-assembly, near-infrared (NIR) resin comprising:
a plurality of thermoplasmonic nanoparticles, wherein the nanoparticles comprise at least one hydrogen-bond-forming ligand; and
a polymer solution comprising at least one thermoresponsive polymer with a lower critical solution temperature (LCST) of about 20 °C to about 65 °C.

2. The resin of claim 1, wherein the thermoplasmonic nanoparticle has a photothermal conversion efficiency of at least 60%.

3. The resin of claim 1, wherein the thermoplasmonic nanoparticle has a localized surface plasmon resonance (LSPR) peak at about 700 nm to about 2500 nm.

4. The resin of claim 1, further comprising a crosslinker, a thermal initiator, a co-initiator, or any combination thereof.

5. The resin of claim 1, wherein:
the thermoresponsive polymer is present in about 8 wt./v % to about 30.0 wt./v % of the resin;
the thermoplasmonic nanoparticle is present in a concentration of about 0.0005 wt./v % to about 0.01 wt./v %; or
a combination thereof.

6. The resin of claim 4, wherein:
the crosslinker is selected from the group consisting of poly(ethylene glycol) dimethacrylate, poly(ethylene diacrylate (PEGDA), N,N′-glycol) methylenebisacrylamide (MBAA), ethylene glycol dimethacrylate (EGDMA), di(ethylene glycol) diacrylate (DEGDA), or a combination thereof;
the crosslinker is present in a concentration of about 8 wt./v % to about 20 wt./v %; or
any combination thereof.

7. The resin of claim 1, wherein the thermoresponsive polymer comprises at least one monomer residue selected from the group consisting of a poly(N-isopropyl acrylamide) (PNIPAM) residue, a butyl acrylate residue, an N,N-dimethylacrylamide residue, a poly(N-vinylcaprolactan) (PNVCL) residue, a poly(2-(diethylamine)ethyl methacrylate) (PDMAEMA) residue, a poly(vinyl methyl ether) residue, a poly(propylene glycol) (PPG) residue, a methyl acrylate residue, a poly(ethylene glycol) methyl ether acrylate (PEGMEA) residue, a gelatin monomer, a hydroxypropyl cellulose residue, or a copolymer thereof.

8. The resin of claim 7, wherein the thermoresponsive polymer is selected from a poly(N-isopropyl acrylamide) (PNIPAM) homopolymer or a copolymer of a PNIPAM monomer residue and at least one comonomer residue, wherein the copolymer comprises the PNIPAM monomer residue in about 10 mol. % to about 90 mol. % of the thermoresponsive polymer.

9. The resin of claim 8, wherein the thermoresponsive polymer is poly(N-isopropylacrylamide-ran-butyl acrylate) or poly(N-isopropylacrylamide-ran-N,N-dimethylacrylamide).

10. The resin of claim 1, wherein the polymer solution further comprises at least one additional thermoresponsive polymer, wherein the additional thermoresponsive polymer has an LCST greater than or less than the LCST of the first thermoresponsive polymer.

11. The resin of claim 1, wherein the thermoplasmonic nanoparticle:
comprises a material selected from the group consisting of a metal, a metal oxide, a metal alloy, a metal oxide alloy, or a combination thereof;
has a nanostructure selected from the group consisting of a nanorod, a core-shell, a nanodisk, a nanocage, a nanostar, a nanosphere, or a triangular nanoprism;
is about 5 nm to about 100 nm; or
any combination thereof.

12. The resin of claim 11, wherein the thermoplasmonic nanoparticle is a gold nanorod.

13. The resin of claim 1, wherein the at least one hydrogen-bond-forming ligand:
is present in a surface density of about 1 ligand/mm² to about 10 ligand/mm²;
comprises a terminal moiety selected from the group consisting of a carboxylic acid, an amine, an amide, or an alcohol; or
a combination thereof.

14. A near-infrared material fabrication method comprising:
exposing a self-assembly resin to near-infrared (NIR) irradiation for a period of time, thereby producing a cured resin, wherein the self-assembly resin comprises:
a plurality of thermoplasmonic nanoparticles, wherein the nanoparticles comprise at least one hydrogen-bond-forming ligand; and
a polymer solution comprising at least one thermoresponsive polymer with a lower critical solution temperature (LCST) of about 20 °C to about 65 °C.

15. The method of claim 14, wherein:
the exposure to NIR light comprises a continuous light application, a pulsed light application, or a combination thereof;
the material fabrication method is an additive manufacturing method or a photolithography method;
the period of time comprises about 1 second to about 45 minutes; or
any combination thereof.

16. The method of claim 14, wherein:
the thermoresponsive polymer is present in about 8 wt./v % to about 30.0 wt./v % of the resin;
the thermoplasmonic nanoparticle is present in a concentration of about 0.0005 wt./v % to about 0.01 wt./v %; or
a combination thereof.

17. The method of claim 14, further comprising a crosslinker, a thermal initiator, a co-initiator, or any combination thereof.

18. The method of claim 14, wherein the thermoresponsive polymer comprises at least one monomer residue selected from the group consisting of a poly(N-isopropyl acrylamide) (PNIPAM) residue, a butyl acrylate residue, an N,N-dimethylacrylamide residue, a poly(N-vinylcaprolactan) (PNVCL) residue, a poly(2-(diethylamine)ethyl methacrylate) (PDMAEMA) residue, a poly(vinyl methyl ether) residue, a poly(propylene glycol) (PPG) residue, a methyl acrylate residue, a poly(ethylene glycol) methyl ether acrylate (PEGMEA) residue, a gelatin monomer, a hydroxypropyl cellulose residue, or a copolymer thereof.

19. The method of claim 14, wherein the polymer solution further comprises at least one additional thermoresponsive polymer, wherein the additional thermoresponsive polymer has an LCST greater than or less than the LCST of the first thermoresponsive polymer.

20. A composite material produced by the method of claim 14.
